(19) United States
(12) Patent Application Publication
(10) Pub. No.: US 2025/0294748 A1
(43) Pub. Date: Sep. 18, 2025

(54) MEMORY DEVICE CONTAINING NON-INTEGER AVERAGE NUMBER OF MEMORY OPENING FILL STRUCTURES PER COLUMN

(71) Applicant: SANDISK TECHNOLOGIES LLC, ADDISON, TX (US)

(72) Inventors: Kota FUNAYAMA, Yokkaichi (JP); Ryo NAKAMURA, Yokkaichi (JP)

(21) Appl. No.: 18/909,251

(22) Filed: Oct. 8, 2024

Related U.S. Application Data
(63) Continuation-in-part of application No. 18/602,790, filed on Mar. 12, 2024.

(51) Int. Cl. H10B 43/27; H01L 23/00; H01L 25/00; H01L 25/065; H01L 25/18; H10B 41/27; H10B 41/35; H10B 43/35; H10B 80/00

(52) U.S. Cl. CPC H10B 43/27; H01L 24/08; H01L 24/80; H01L 25/0657; H01L 25/18; H01L 25/50; H10B 41/27; H10B 41/35; H10B 43/35; H10B 80/00; H01L 2224/08145; H01L 2224/80006; H01L 2224/80895; H01L 2224/80896; H01L 2924/1431; H01L 2924/14511

(57) ABSTRACT

A memory device includes an alternating stack of insulating layers and electrically conductive layers which extends along a first horizontal direction, and memory opening fill structures vertically extending through the alternating stack. Each of the memory opening fill structures includes a vertical stack of memory elements and a vertical semiconductor channel. The memory opening fill structures are arranged in columns which extend along a second horizontal direction perpendicular to the first horizontal direction, and an average number of the memory opening fill structures per column is a non-integer number greater than zero.

### RELATED APPLICATIONS

This application is a continuation-in-part (CIP) application of U.S. application Ser. No. 18/602,790 filed on Mar. 12, 2024, the entire contents of which are incorporated herein by reference.

### FIELD

The present disclosure relates generally to the field of semiconductor devices, and particularly to a memory device containing a non-integer average number of memory opening fill structures per column and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device comprises: an alternating stack of insulating layers and electrically conductive layers which extends along a first horizontal direction; and memory opening fill structures vertically extending through the alternating stack, wherein each of the memory opening fill structures comprises a vertical stack of memory elements and a vertical semiconductor channel. The memory opening fill structures are arranged in columns which extend along a second horizontal direction perpendicular to the first horizontal direction; and an average number of the memory opening fill structures per column is a non-integer number greater than zero.

According to another aspect of the present disclosure, a method of forming a memory device comprises: forming a vertically alternating sequence of continuous insulating layers and continuous sacrificial material layers over a substrate; forming memory openings and isolation openings through the alternating stack; forming memory opening fill structures in the memory openings, wherein each of the memory opening fill structures comprises a respective vertical stack of memory elements and a vertical semiconductor channel; forming lateral isolation trenches that generally extend along a first horizontal direction, wherein the memory opening fill structures are arranged in columns which extend along a second horizontal direction perpendicular to the first horizontal direction between each neighboring pair of the lateral isolation trenches, and wherein an average number of the memory opening fill structures per column between each neighboring pair of the lateral isolation trenches is a non-integer number greater than zero; and replacing remaining portions of the continuous sacrificial material layers with electrically conductive layers through the lateral isolation trenches.

According to an aspect of the present disclosure, a memory device includes an alternating stack of insulating layers and electrically conductive layers which extends along a first horizontal direction, where the electrically conductive layers include word lines and drain-side select gate electrodes overlying the word lines, and memory opening fill structures vertically extending through the alternating stack. Each of the memory opening fill structures includes a vertical stack of memory elements and a vertical semiconductor channel. The memory opening fill structures are arranged in columns which extend along a second horizontal direction perpendicular to the first horizontal direction. An average number of the memory opening fill structures per column that extend through each of the drain-side select gate electrodes is a non-integer number greater than zero.

According to another aspect of the present disclosure, a memory device includes an alternating stack of insulating layers and electrically conductive layers, wherein the alternating stack is located between a first lateral isolation trench fill structure and a second lateral isolation trench fill structure that laterally extend along a first horizontal direction and are laterally spaced from each other along a second horizontal direction, wherein the electrically conductive layers comprise word lines that laterally extend contiguously from the first lateral isolation trench fill structure to the second lateral isolation trench fill structure, and further comprise drain-side select gate electrodes overlying the word lines, wherein each of the drain-side select gate electrodes comprises a respective plurality of drain-side select gate electrodes that are laterally spaced among one another along the second horizontal direction by at least one drain-select-level dielectric isolation structure that generally extends along the first horizontal direction; memory openings vertically extending through the alternating stack and arranged in multiple rows such that each of the multiple rows is arranged along the first horizontal direction and neighboring rows among the multiple rows are laterally spaced from each other along the second horizontal direction; and memory opening fill structures located in the memory openings, wherein each set of memory opening fill structures that vertically extends between a respective neighboring pair of isolation structures that are selected from the first lateral isolation trench fill structure, the second lateral isolation trench fill structure, and the at least one drain-select-level dielectric isolation structure defines a memory string group, and each memory string group includes all memory opening fill structures within a respective set of rows of memory opening fill structures and includes a non-zero fraction of memory opening fill structures within a respective additional row of memory opening fill structures, the non-zero fraction being less than an entirety of the memory opening fill structures within the respective additional row.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to an embodiment of the present disclosure.

FIG. 2 is a schematic vertical cross-sectional view of the first exemplary structure after formation of stepped surfaces and a stepped dielectric material portion according to an embodiment of the present disclosure.

FIG. 3A is a schematic vertical cross-sectional view of the first exemplary structure after formation of memory openings and support openings according to an embodiment of the present disclosure.

FIG. 3B is a top-down view of the first exemplary structure of FIG. 3A. The hinged vertical cross-sectional plane A-A′ is the cut plane of the vertical cross-sectional view of FIG. 3A.

FIGS. 3C-3G are top-down views of alternative configurations of the first exemplary structure at the processing steps of FIGS. 3A and 3B.

FIG. 4 is a schematic vertical cross-sectional view of the first exemplary structure after formation of sacrificial opening fill structures according to an embodiment of the present disclosure.

FIG. 5 is a vertical cross-sectional view of the first exemplary structure after formation of support pillar structures according to an embodiment of the present disclosure.

FIG. 6 is a schematic vertical cross-sectional view of the first exemplary structure after removal of sacrificial memory opening fill structures according to an embodiment of the present disclosure.

FIGS. 7A-7F are sequential vertical cross-sectional views of a memory opening during formation of a memory opening fill structure according to an embodiments of the present disclosure.

FIG. 8A is a schematic vertical cross-sectional view of the first exemplary structure after formation of memory opening fill structures according to an embodiment of the present disclosure.

FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of lateral isolation trenches according to an embodiment of the present disclosure.

FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to an embodiment of the present disclosure.

FIG. 11 is a schematic vertical cross-sectional view of the first exemplary structure after formation of electrically conductive layers according to an embodiment of the present disclosure.

FIG. 12A is a vertical cross-sectional view of the first exemplary structure after formation of lateral isolation trench fill structures and drain-select-level dielectric isolation structures according to an embodiment of the present disclosure.

FIG. 12B is a top-down view of the first exemplary structure of FIG. 12A. The vertical plane A-A is the cut plane of the vertical cross-sectional view of FIG. 12A.

FIGS. 12C-12G are top-down views of alternative configurations of the first exemplary structure at the processing steps of FIGS. 12A and 12B.

FIG. 13A is a vertical cross-sectional view of the first exemplary structure after formation of layer contact via structures and drain contact via structures according to an embodiment of the present disclosure.

FIG. 13B is a top-down view of the first exemplary structure of FIG. 13A. The vertical plane A-A is the cut plane of the vertical cross-sectional view of FIG. 13A.

FIGS. 13C-13G are top-down views of alternative configurations of the first exemplary structure at the processing steps of FIGS. 13A and 13B.

FIG. 14A is a vertical cross-sectional view of the first exemplary structure after formation of connection via structures and bit lines according to an embodiment of the present disclosure.

FIG. 14B is a top-down view of the first exemplary structure of FIG. 14A. The vertical plane A-A is the cut plane of the vertical cross-sectional view of FIG. 14A.

FIGS. 14C-14G are top-down views of alternative configurations of the first exemplary structure at the processing steps of FIGS. 14A and 14B.

FIG. 15 is a vertical cross-sectional view of the first exemplary structure after formation of a memory die according to an embodiment of the present disclosure.

FIG. 16 is a vertical cross-sectional view of the first exemplary structure after attaching a logic die to the memory die according to an embodiment of the present disclosure.

FIG. 17A is a vertical cross-sectional view of the first exemplary structure after removal of the carrier substrate according to an embodiment of the present disclosure.

FIG. 17B is a magnified view of a region of the first exemplary structure of FIG. 17A.

FIG. 18 is a vertical cross-sectional view of a region of the first exemplary structure around an end portion of a memory stack structure according to an embodiment of the present disclosure.

FIG. 19A is a vertical cross-sectional view of the first exemplary structure after formation of a source contact structure according to an embodiment of the present disclosure.

FIG. 19B is a magnified view of a region of the first exemplary structure of FIG. 19A.

FIG. 20A is a vertical cross-sectional view of a second exemplary structure after formation of memory openings, support openings, and isolation openings according to an embodiment of the present disclosure.

FIG. 20B is a top-down view of the first exemplary structure of FIG. 20A. The vertical plane A-A is the cut plane of the vertical cross-sectional view of FIG. 20A.

FIG. 21A is a schematic vertical cross-sectional view of the second exemplary structure after formation of sacrificial opening fill structures according to an embodiment of the present disclosure.

FIG. 21B is a top-down view of the second exemplary structure of FIG. 21A. The vertical plane A-A is the cut plane of the vertical cross-sectional view of FIG. 21A.

FIG. 22A is a schematic vertical cross-sectional view of the second exemplary structure after removal of sacrificial support opening fill structures according to an embodiment of the present disclosure.

FIG. 22B is a top-down view of the second exemplary structure of FIG. 22A. The vertical plane A-A is the cut plane of the vertical cross-sectional view of FIG. 22A.

FIG. 23A is a vertical cross-sectional view of the second exemplary structure after formation of support pillar structures according to an embodiment of the present disclosure.

FIG. 23B is a top-down view of the second exemplary structure of FIG. 23A. The vertical plane A-A is the cut plane of the vertical cross-sectional view of FIG. 23A.

FIG. 23C is a top-down view of an alternative configuration of the second exemplary structure. The vertical plane A-A is the cut plane of the vertical cross-sectional view of FIG. 23A.

FIG. 24A is a schematic vertical cross-sectional view of the second exemplary structure after removal of sacrificial memory opening fill structures according to an embodiment of the present disclosure.

FIG. 24B is a top-down view of the second exemplary structure of FIG. 24A. The vertical plane A-A is the cut plane of the vertical cross-sectional view of FIG. 24A.

FIG. 25A is a schematic vertical cross-sectional view of the second exemplary structure after formation of memory opening fill structures according to an embodiment of the present disclosure.

FIG. 25B is a top-down view of the second exemplary structure of FIG. 25A. The vertical plane A-A is the cut plane of the vertical cross-sectional view of FIG. 25A.

FIG. 25C is a top-down view of an alternative configuration of the second exemplary structure. The vertical plane A-A is the cut plane of the vertical cross-sectional view of FIG. 25A.

FIG. 26A is a schematic vertical cross-sectional view of the second exemplary structure after removal of sacrificial isolation opening fill structures according to an embodiment of the present disclosure.

FIG. 26B is a top-down view of the second exemplary structure of FIG. 26A. The vertical plane A-A is the cut plane of the vertical cross-sectional view of FIG. 26A.

FIG. 27A is a vertical cross-sectional view of the second exemplary structure after formation of lateral isolation trenches according to an embodiment of the present disclosure.

FIG. 27B is a top-down view of the second exemplary structure of FIG. 27A. The vertical plane A-A is the cut plane of the vertical cross-sectional view of FIG. 27A.

FIG. 27C is a top-down view of an alternative configuration of the second exemplary structure. The vertical plane A-A is the cut plane of the vertical cross-sectional view of FIG. 27A.

FIG. 28A is a vertical cross-sectional view of the second exemplary structure after formation of laterally-extending cavities according to an embodiment of the present disclosure.

FIG. 28B is a top-down view of the second exemplary structure of FIG. 28A. The vertical plane A-A is the cut plane of the vertical cross-sectional view of FIG. 28A.

FIG. 29A is a schematic vertical cross-sectional view of the second exemplary structure after formation of electrically conductive layers according to an embodiment of the present disclosure.

FIG. 29B is a top-down view of the second exemplary structure of FIG. 29A. The vertical plane A-A is the cut plane of the vertical cross-sectional view of FIG. 29A.

FIG. 30A is a vertical cross-sectional view of the second exemplary structure after formation of lateral isolation trench fill structures and a contact-level dielectric layer according to an embodiment of the present disclosure.

FIG. 30B is a top-down view of the second exemplary structure of FIG. 30A. The vertical plane A-A is the cut plane of the vertical cross-sectional view of FIG. 30A.

FIG. 30C is a top-down view of an alternative configuration of the second exemplary structure. The vertical plane A-A is the cut plane of the vertical cross-sectional view of FIG. 30A.

FIG. 31A is a vertical cross-sectional view of the second exemplary structure after formation of drain-select-level dielectric isolation structures according to an embodiment of the present disclosure.

FIG. 31B is a top-down view of the second exemplary structure of FIG. 31A. The vertical plane A-A is the cut plane of the vertical cross-sectional view of FIG. 31A.

FIG. 32A is a vertical cross-sectional view of the second exemplary structure after formation of layer contact via structures and drain contact via structures according to an embodiment of the present disclosure.

FIG. 32B is a top-down view of the second exemplary structure of FIG. 32A. The vertical plane A-A is the cut plane of the vertical cross-sectional view of FIG. 32A.

FIG. 33A is a vertical cross-sectional view of the second exemplary structure after formation of connection via structures and bit lines according to an embodiment of the present disclosure.

FIG. 33B is a top-down view of the second exemplary structure of FIG. 33A. The vertical plane A-A is the cut plane of the vertical cross-sectional view of FIG. 33A.

FIG. 33C is a see-through top-down view of the second exemplary structure of FIGS. 33A and 33B.

FIG. 34 is a vertical cross-sectional view of the second exemplary structure after formation of a memory die according to an embodiment of the present disclosure.

FIG. 35 is a vertical cross-sectional view of the second exemplary structure after removal of the carrier substrate and formation of a source contact structure according to an embodiment of the present disclosure.

### DETAILED DESCRIPTION

As discussed above, the embodiments of the present disclosure are directed to a memory device containing a non-integer average number of memory opening fill structures per column, and methods for forming the same, the various aspects of which are described below. Embodiments of the disclosure can be employed to form various structures including a multilevel memory structure, non-limiting examples of which include three-dimensional memory devices comprising a plurality of memory string groups.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

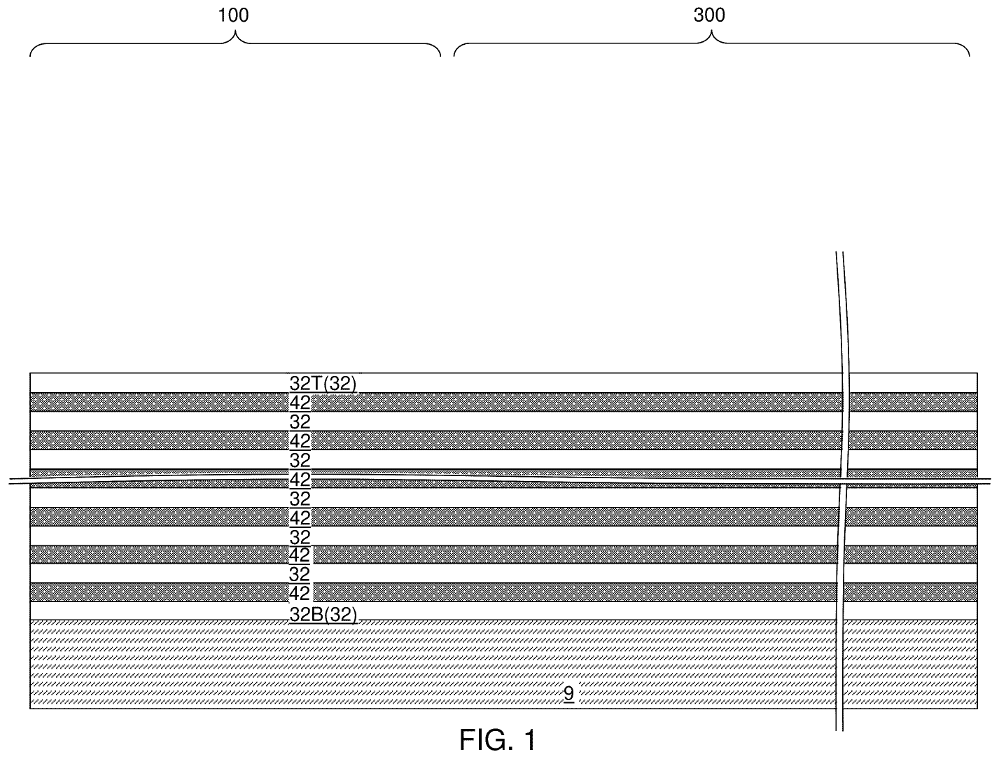

Referring to FIG. 1, a first exemplary structure according to an embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

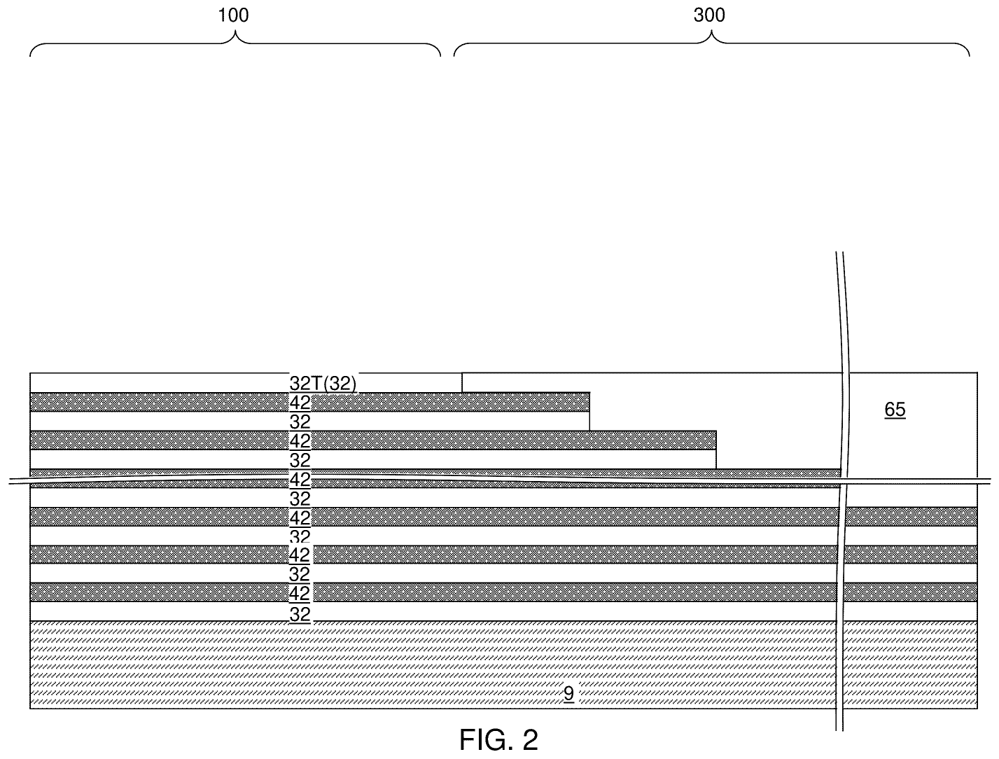

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

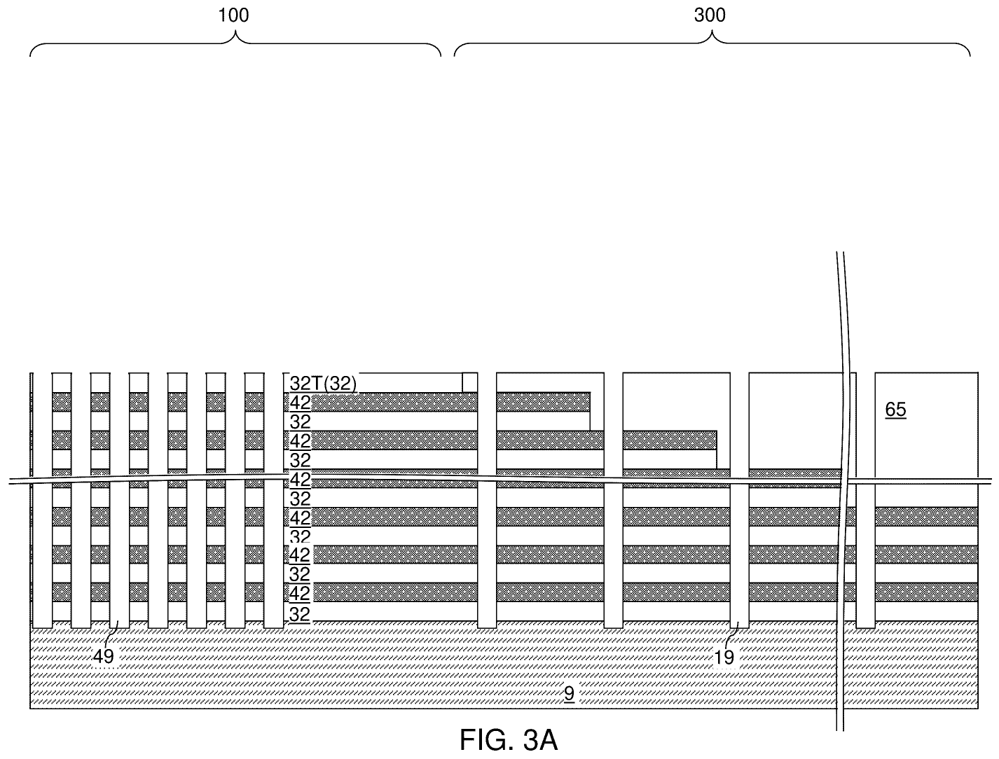

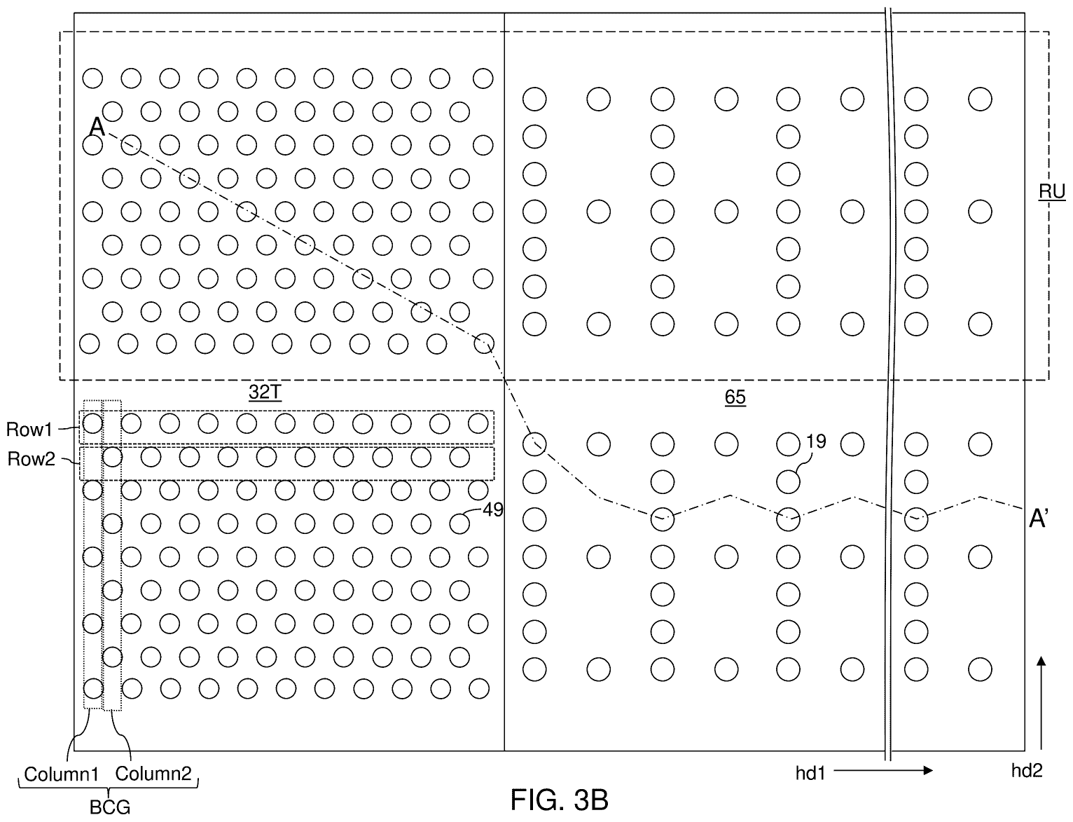

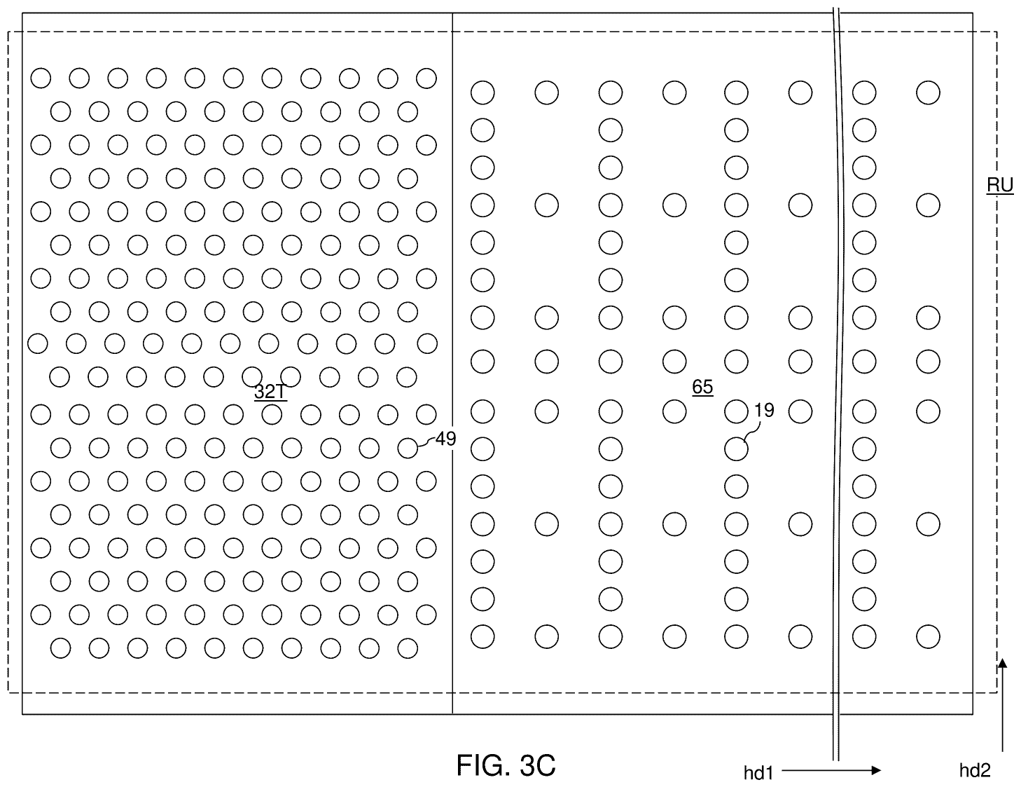

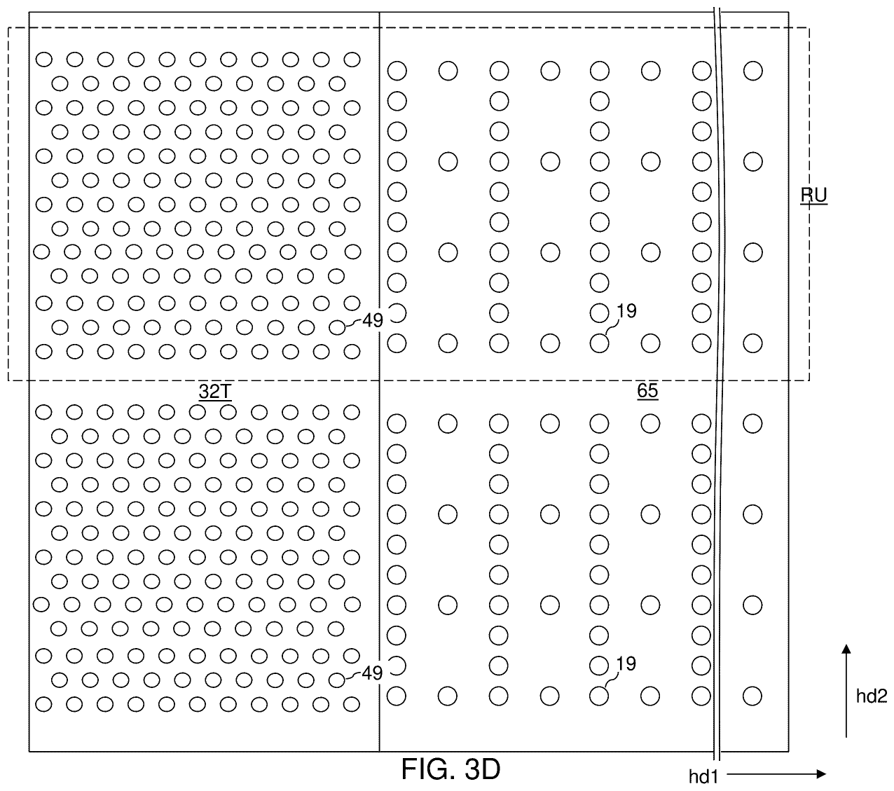

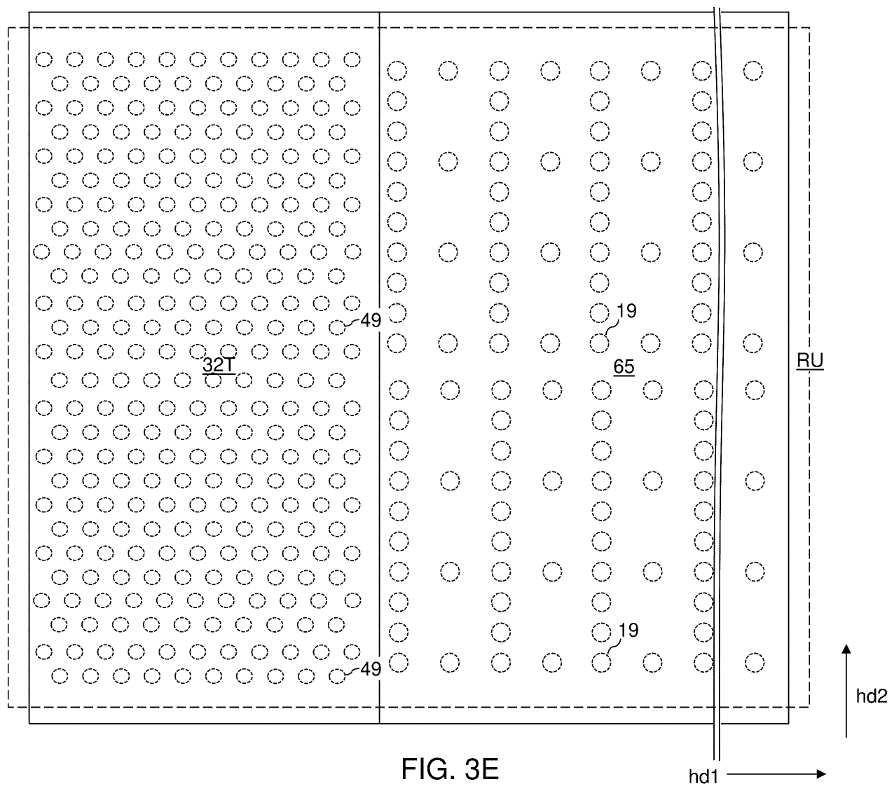

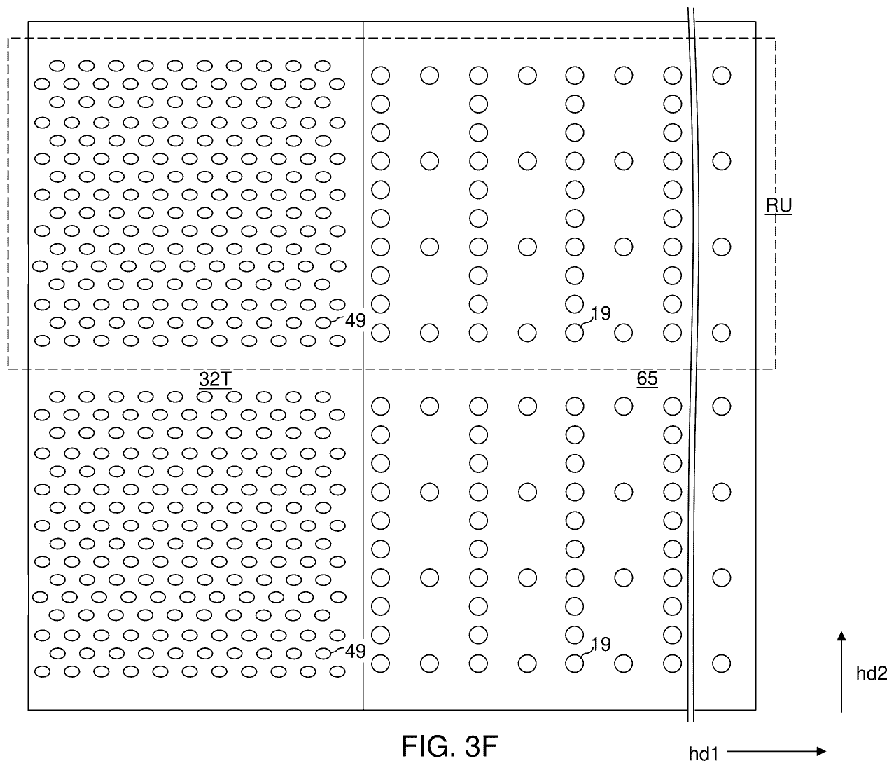

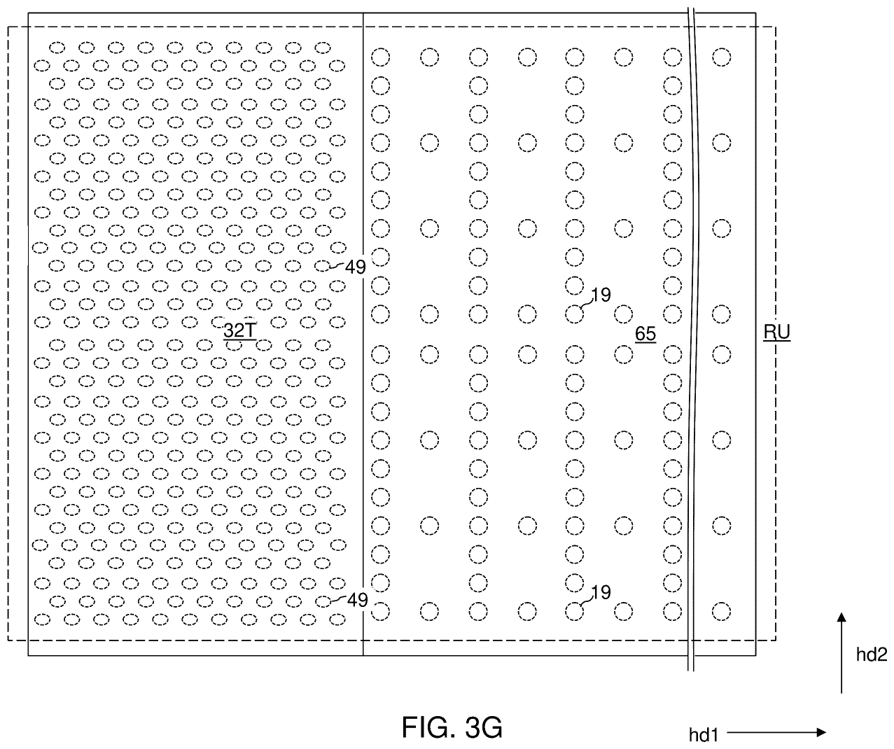

FIG. 3A is a schematic vertical cross-sectional view of the first exemplary structure after formation of memory openings 49 and support openings 19 according to an embodiment of the present disclosure. FIG. 3B is a top-down view of the first exemplary structure of FIG. 3A. The hinged vertical cross-sectional plane A-A′ is the cut plane of the vertical cross-sectional view of FIG. 3A. FIGS. 3C-3G are top-down views of alternative configurations of the first exemplary structure at the processing steps of FIGS. 3A and 3B.

Referring to FIGS. 3A-3G, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend to the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater thicknesses may be employed. The support openings 19 may have a diameter in a range from 60 nm to 400 nm, such as from 120 nm to 300 nm, although lesser and greater thicknesses may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

The pattern of the memory openings 49 and the support openings 19 can be formed with a periodicity along the second horizontal direction hd2. A portion of the first exemplary structure that comprises a unit pattern that is repeated along the second horizontal direction hd2 is herein referred to as a repetition unit RU. The repetition unit may correspond to a memory block. As shown in FIG. 3B, each repetition unit RU comprises multiple rows and columns of memory openings 49. Each column of memory openings 49 is arranged along the second horizontal direction hd2. The columns of memory openings 49 are laterally spaced apart from each other along the first horizontal direction hd1. Each row of memory openings 49 is arranged along the first horizontal direction hd1. The rows of memory openings 49 are laterally spaced apart from each other along the second horizontal direction hd2. In one embodiment, each row of memory openings 49 may comprise Q memory openings 49. The integer Q may be in a range from 2⁴ to 2¹⁶, such as from 2⁶ to 2¹³, although lesser and greater numbers may also be employed.

The memory openings 49 within each repetition unit RU can be arranged as a two-dimensional periodic array, which may be a hexagonal periodic array (i.e., a hexagonal lattice having memory openings at vertices and middle of each unit hexagon). According to an aspect of the present disclosure, each two-dimensional array of memory openings 49 located within a respective repetition unit RU may comprise and/or may consist of BCG=M×P+K block columns groups (“BCG”) of memory openings 49, in which M is an integer greater than 1 and less than 13, P is an integer greater than 1 and less than 9, and K is a positive integer less than M. A block column group is a group of columns of memory openings 49 having a repeating pattern.

In the example illustrated in FIG. 3B, M is 2, P is 4, K is 1 and BCG is 9 (i.e., 2×4+1=9). Column 1 contains five memory openings, column 2 contains four memory openings, column 3 contains five memory openings, column 4 contains four memory openings, and so on. Therefore, every pair of adjacent columns of memory openings 49 in FIG. 3B forms the BCG. For example, there are nine total memory openings 49 in the BCG which includes column 1 and column 2.

In the example illustrated in FIG. 3C, M is 4, P is 4, K is 2 and BCG is 18. In the example illustrated in FIG. 3D, M is 3, P is 4, K is 1 and BCG is 13. In the example illustrated in FIG. 3E, M is 6, P is 4, K is 2 and BCG is 26. In the example illustrated in FIG. 3F, M is 3, P is 5, K is 1 and BCG is 16. In the example illustrated in FIG. 3G, M is 6, P is 5, K is 2 and BCG is 32. While embodiments are described above containing selected examples of integers for M, P, and K, other embodiments are expressly contemplated for all other variations in which M is an integer greater than 1 and less than 13, P is an integer greater than 1 and less than 9, and K is a positive integer less than M. Generally, the lateral spacing between neighboring pairs of memory openings 49 may be uniform or may be varied for the purpose of subsequently forming drain-select-level dielectric isolation structures.

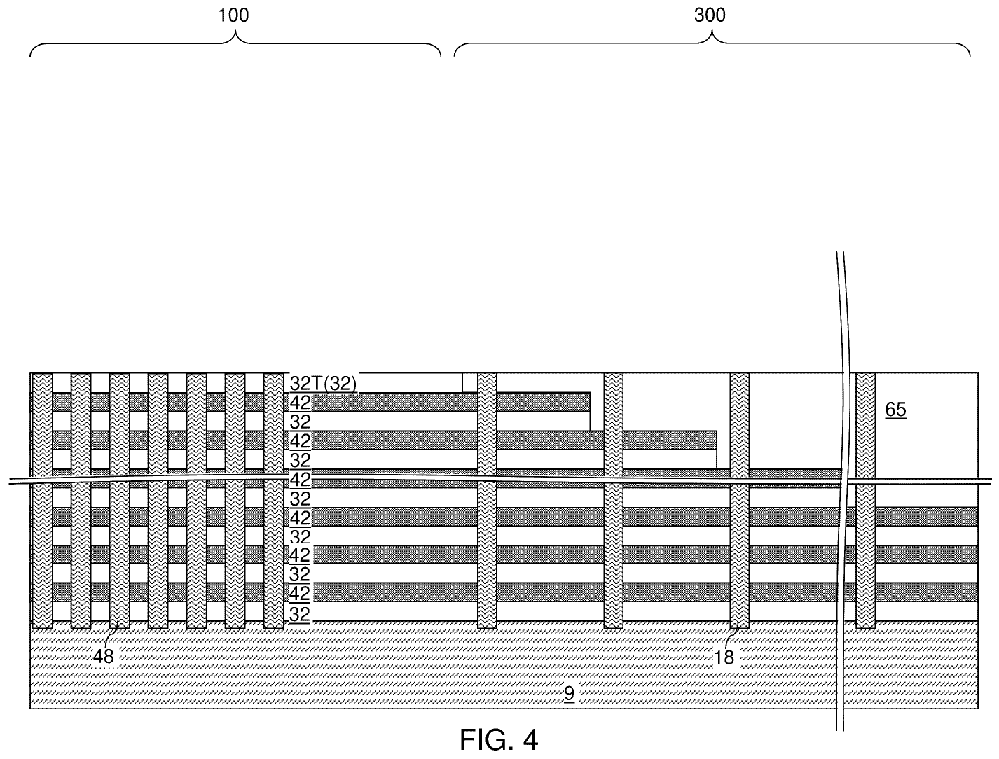

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fill a support opening 19 constitutes a sacrificial support opening fill structure 18.

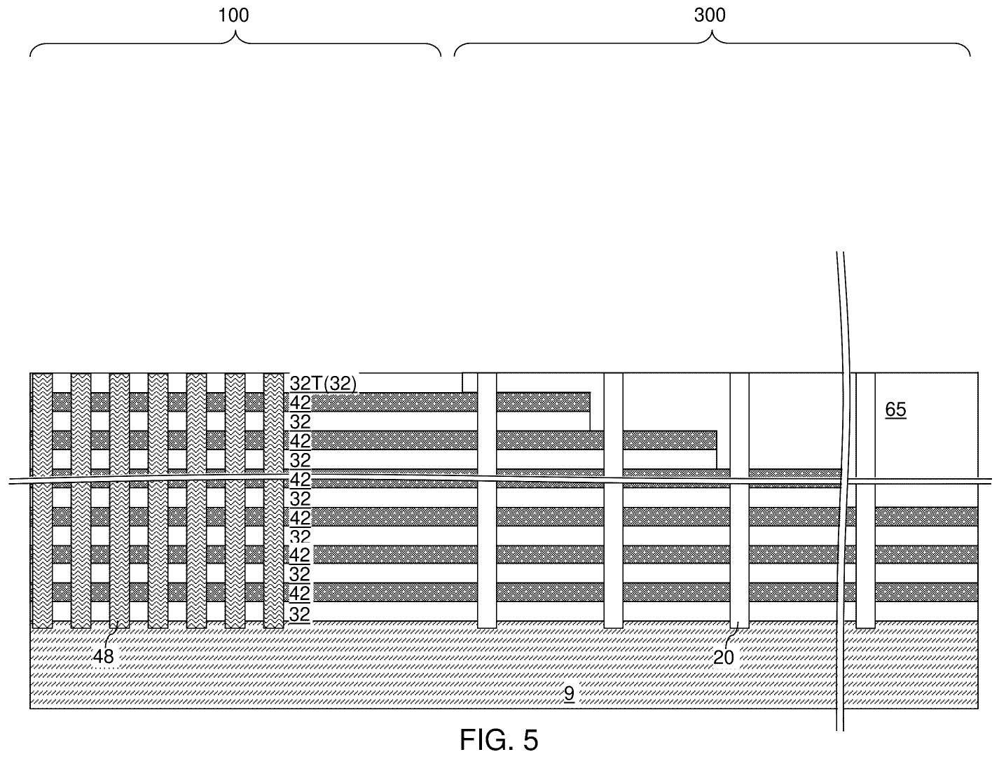

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selectively to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

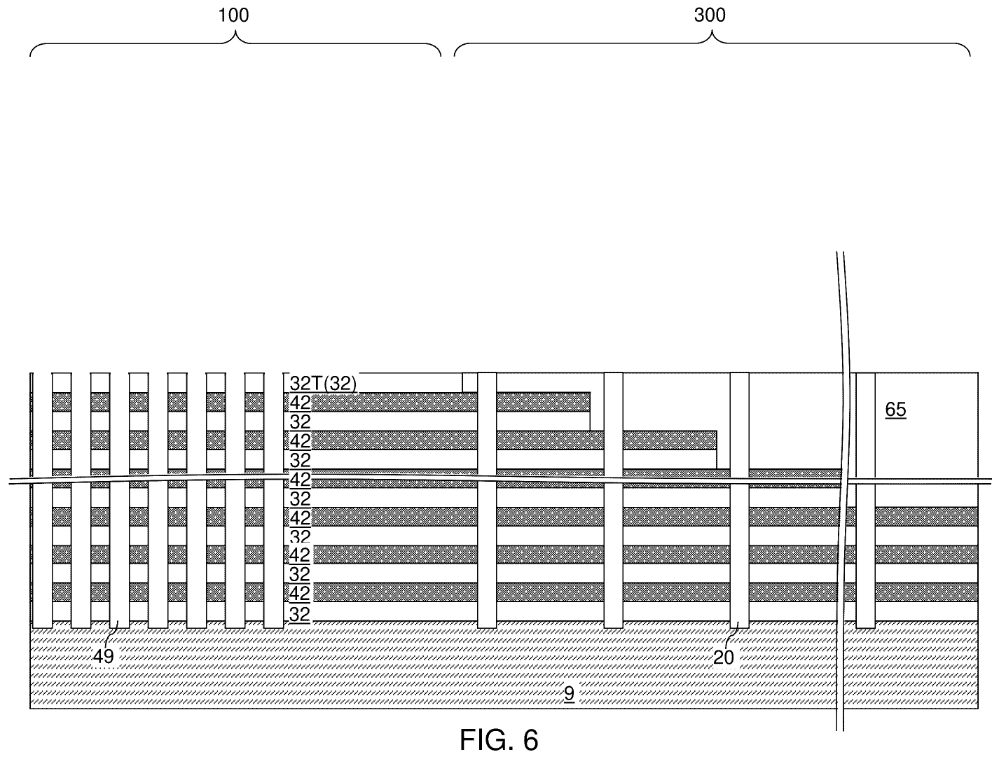

Referring to FIG. 6, sacrificial memory opening fill structures 48 are subsequently removed selectively to the materials of the insulating layers 32, the sacrificial material layers 42, and the carrier substrate 9. Voids are formed in the volumes of the memory openings 49 from which the sacrificial memory opening fill structures 48 are removed.

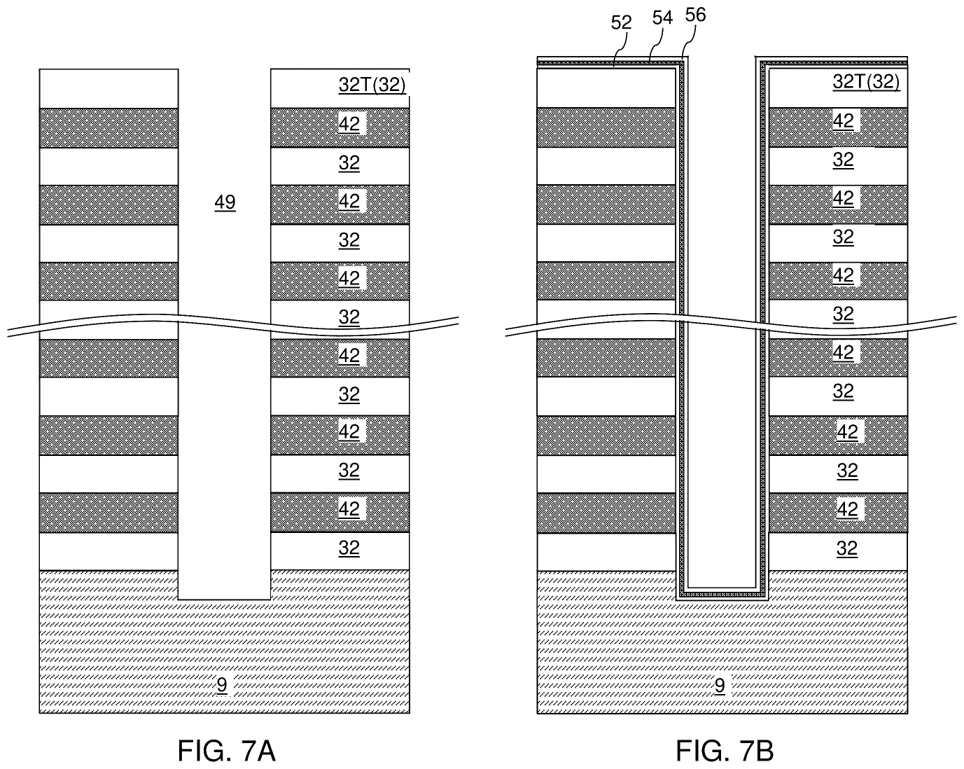

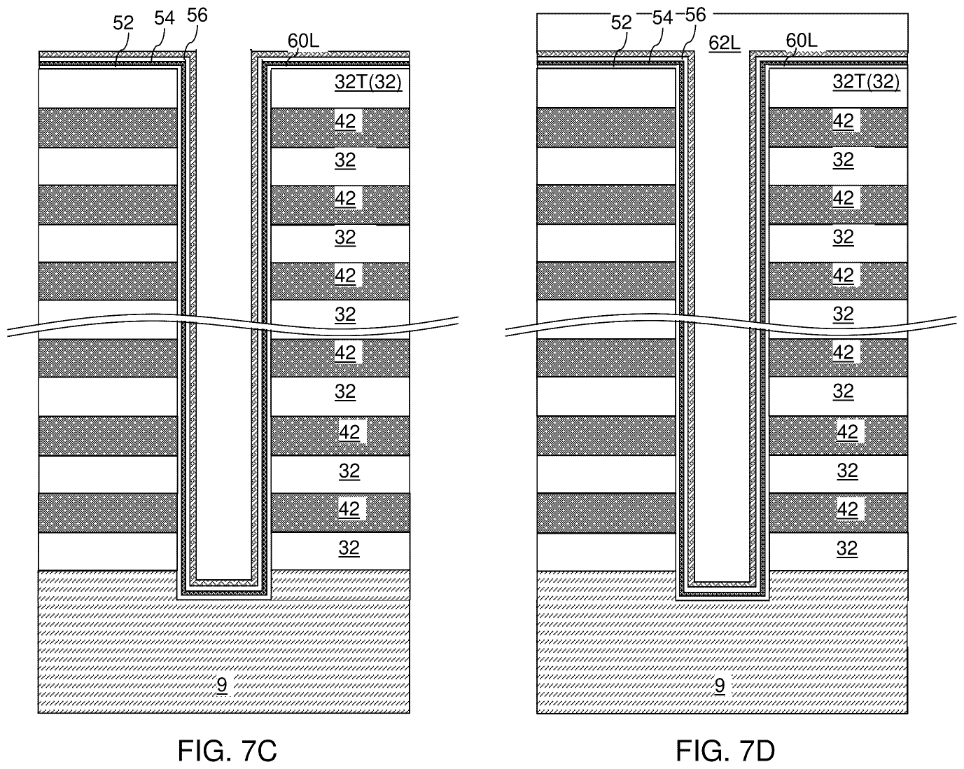

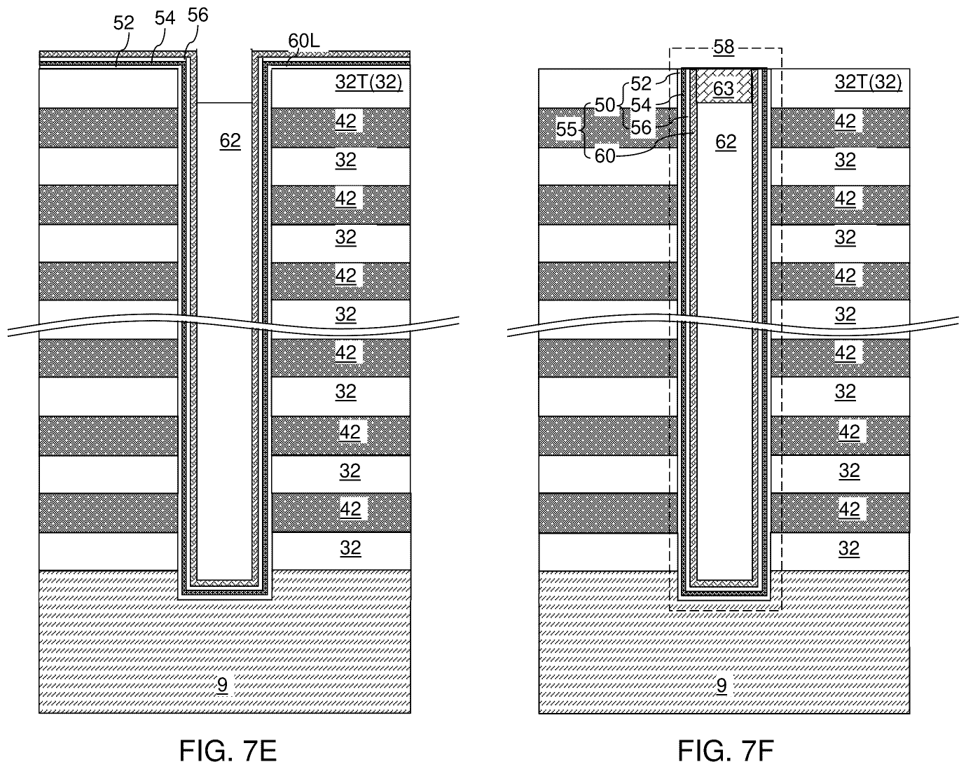

FIGS. 7A-7F are sequential vertical cross-sectional views of a memory opening 49 during formation of a memory opening fill structure 58 according to an embodiments of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extend predominantly along long a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

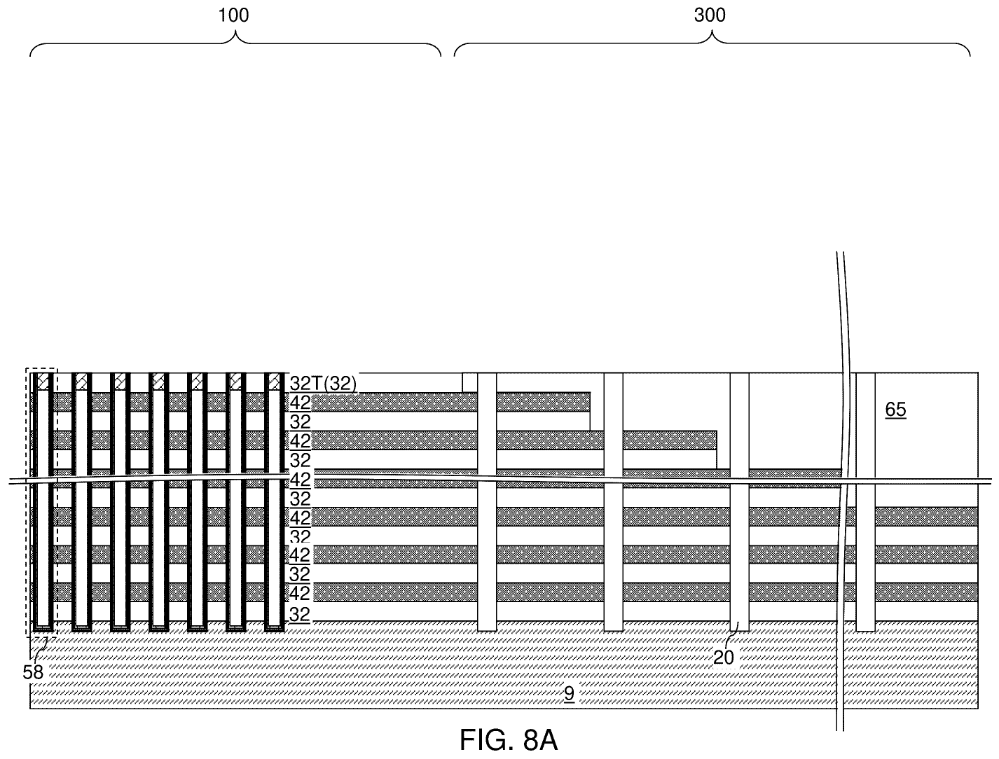

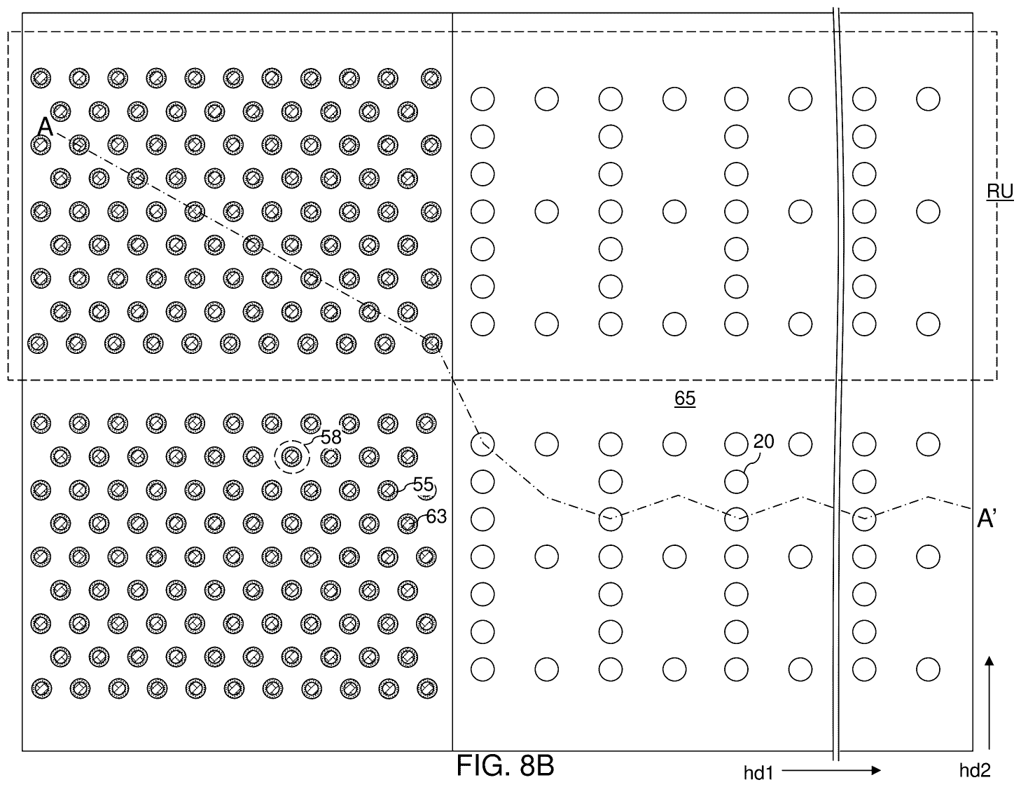

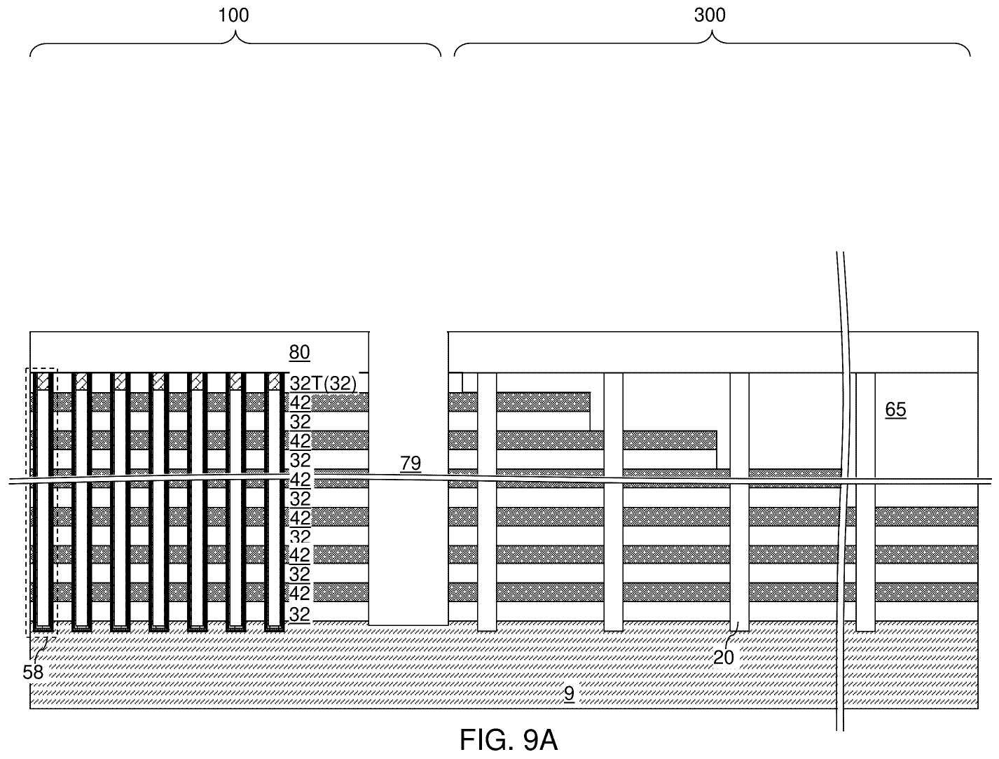

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

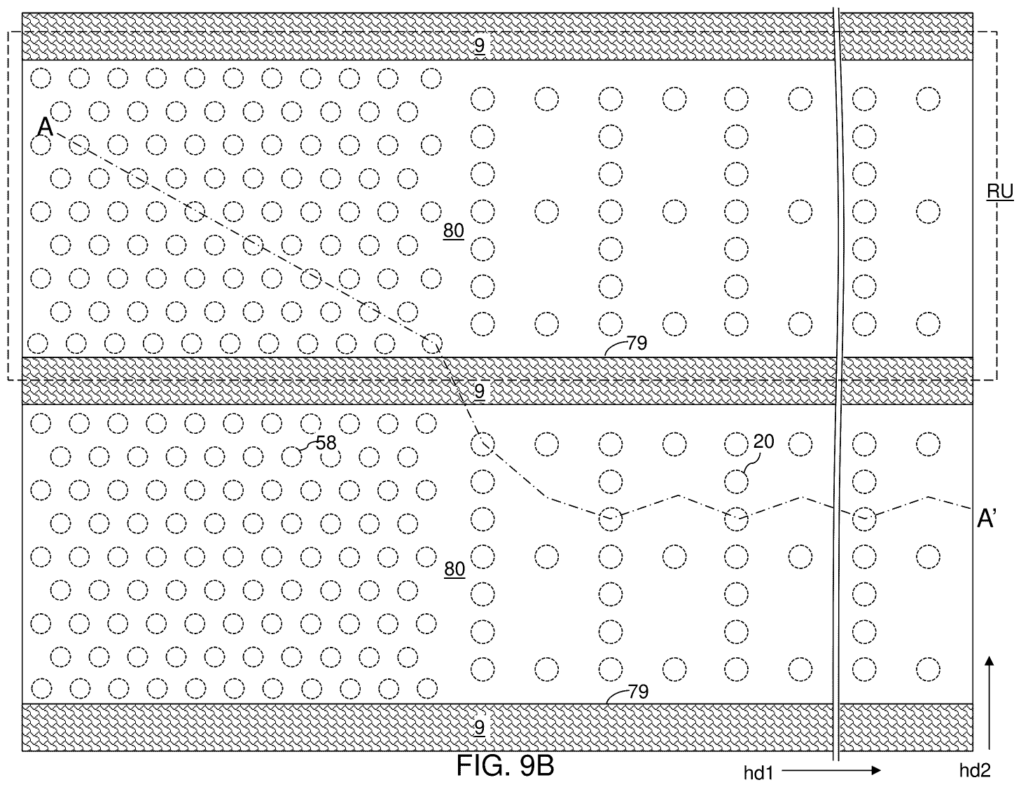

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

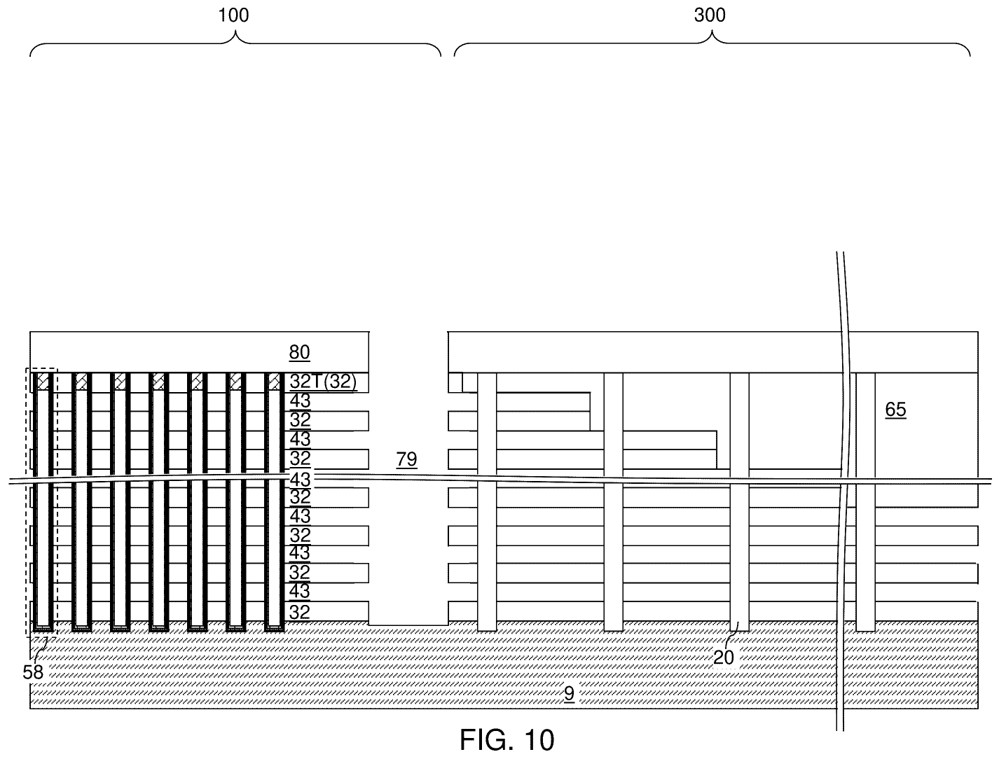

Referring to FIG. 10, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selectively to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast to the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

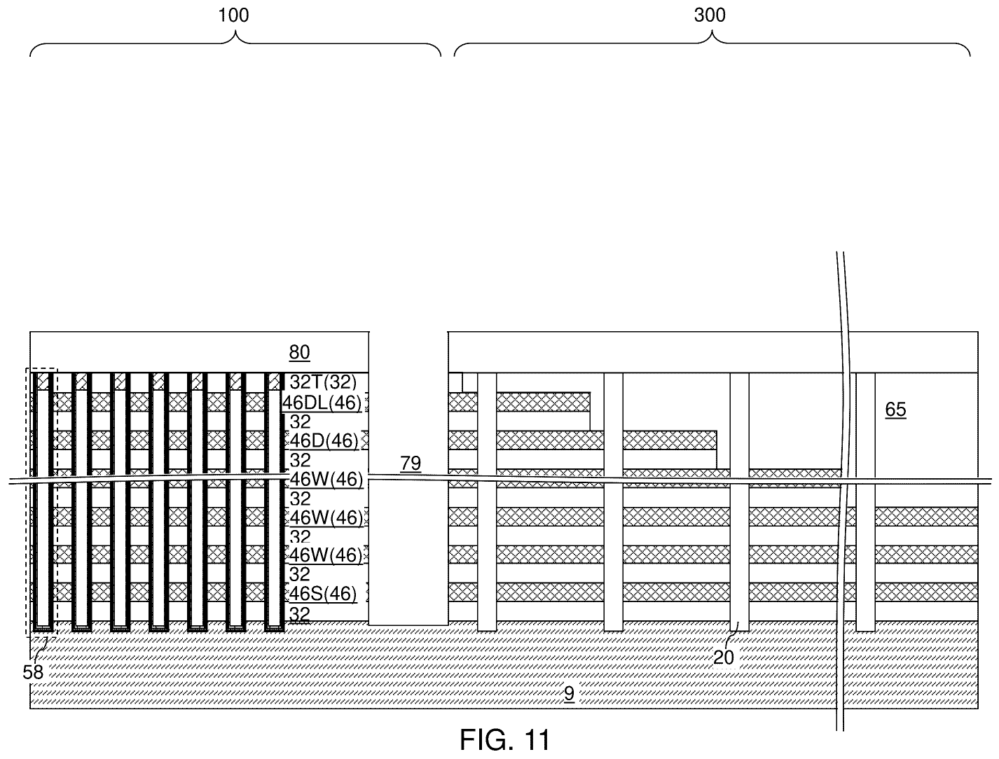

Referring to FIG. 11, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43. At least one uppermost electrically conductive layer 46 may comprise a drain-side select layer 46DL. At least one bottommost electrically conductive layer 46 may comprise a source side select gate electrode 46S. The remaining electrically conductive layers 46 may comprise word lines 46W. Each word line 46W functions as a common control gate electrode for the plurality of vertical NAND strings (e.g., memory opening fill structures 58).

Memory strings are provided in and around the memory opening fill structures 58. Specifically each memory string is provided in and around each memory opening fill structure 58. A “memory string” refers to a set of memory cells that are electrically connected in a series connection. In the first exemplary structure, each memory string comprises a memory stack structure 55 including a respective vertical semiconductor channel 60 and a respective memory film 50, which includes a respective vertical stack of memory elements. Each memory string further comprises proximal portions of the electrically conductive layers 46, which function as control gate electrodes of the NAND memory string.

Typically, in a NAND memory device, memory cells are organized as a set of pages, and each page includes a respective set of memory blocks. The set of all memory strings (e.g., memory opening fill structures 58 and associated select gate electrodes and word lines/control gate electrodes) between a neighboring pair of lateral isolation trenches 79 constitutes a memory block.

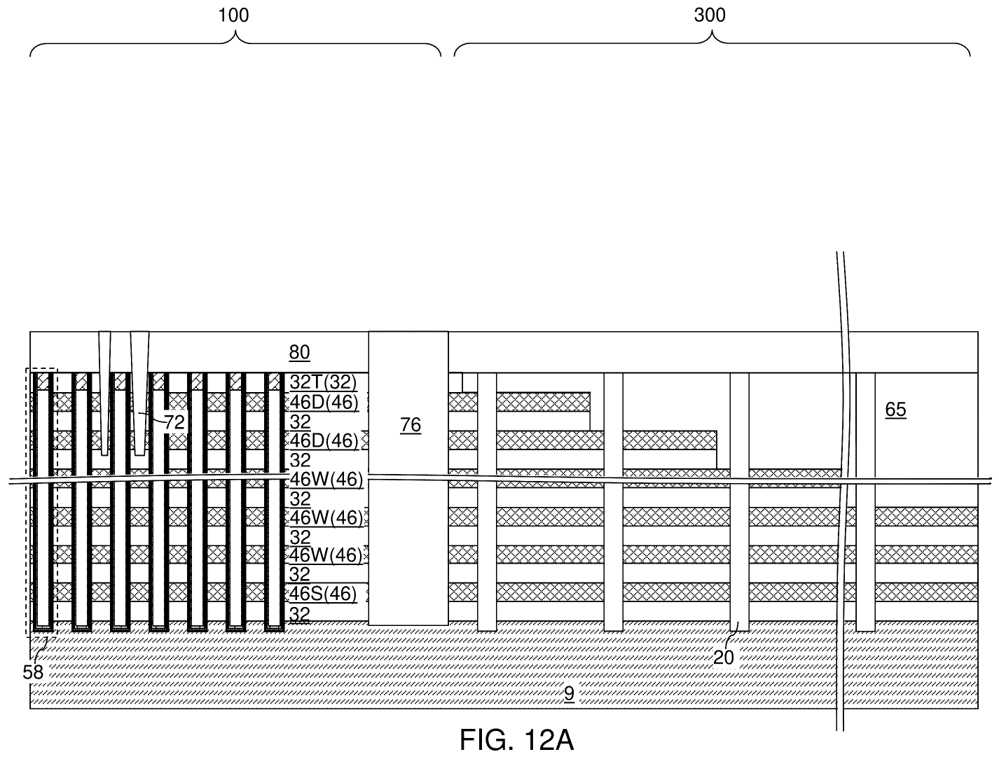

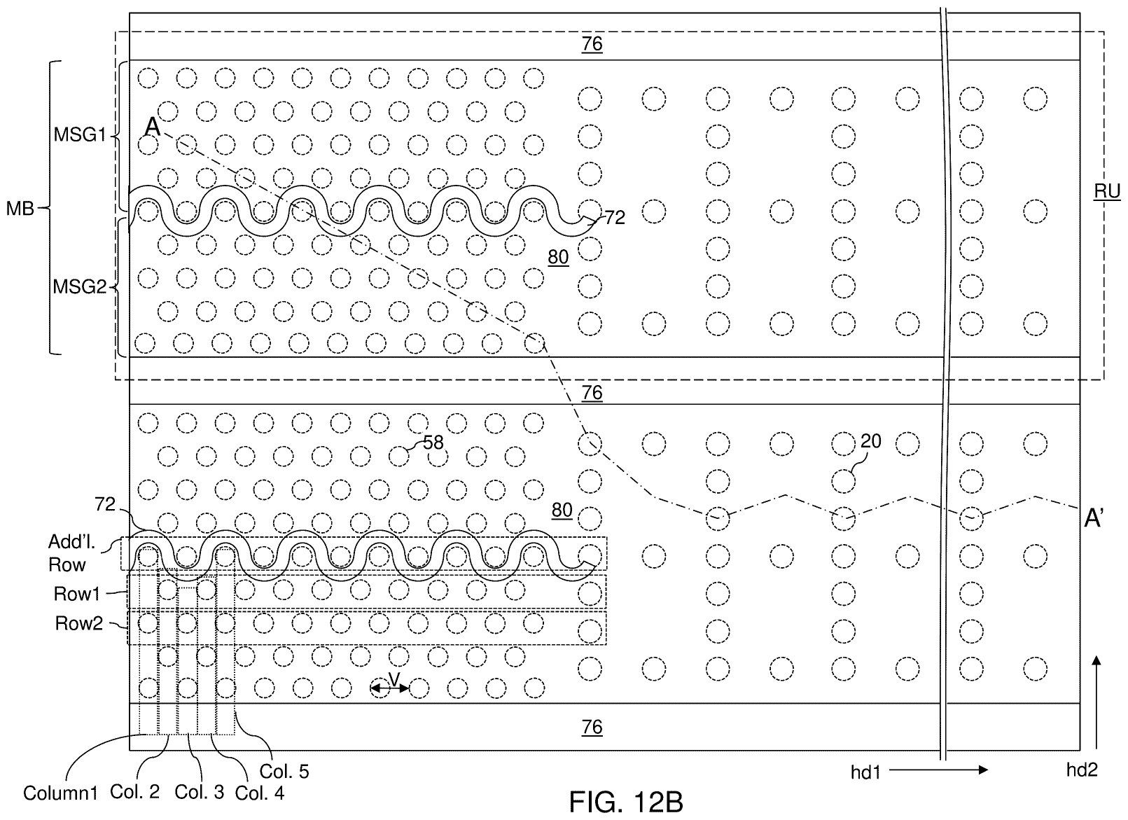

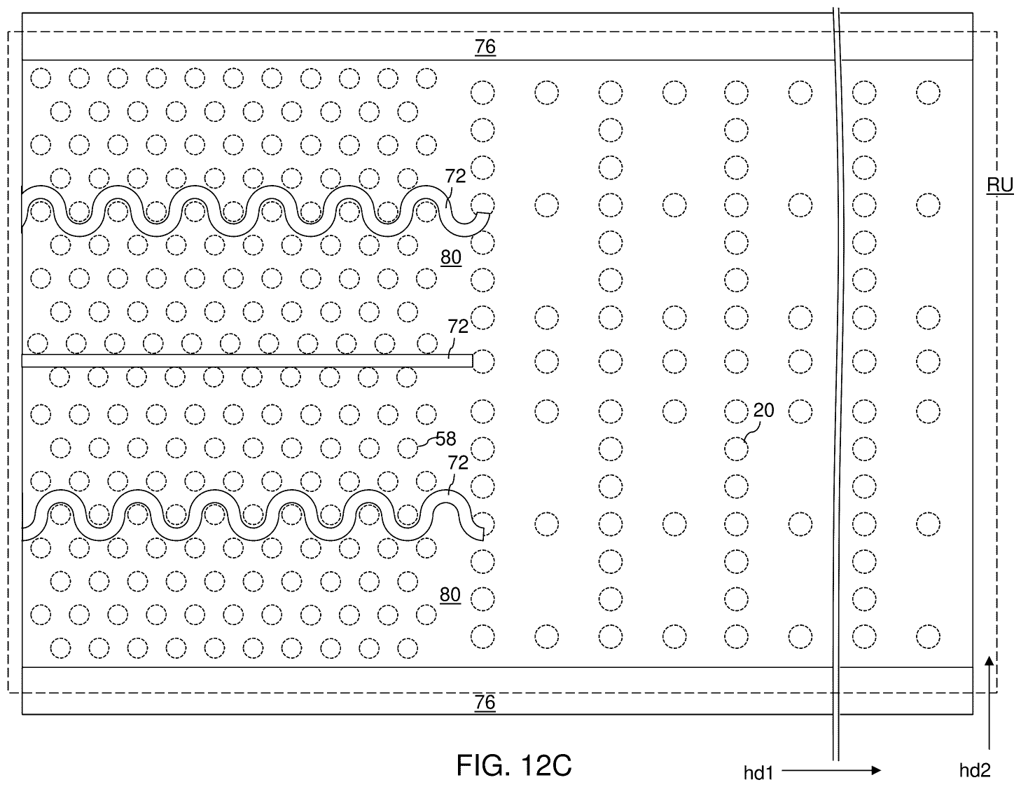

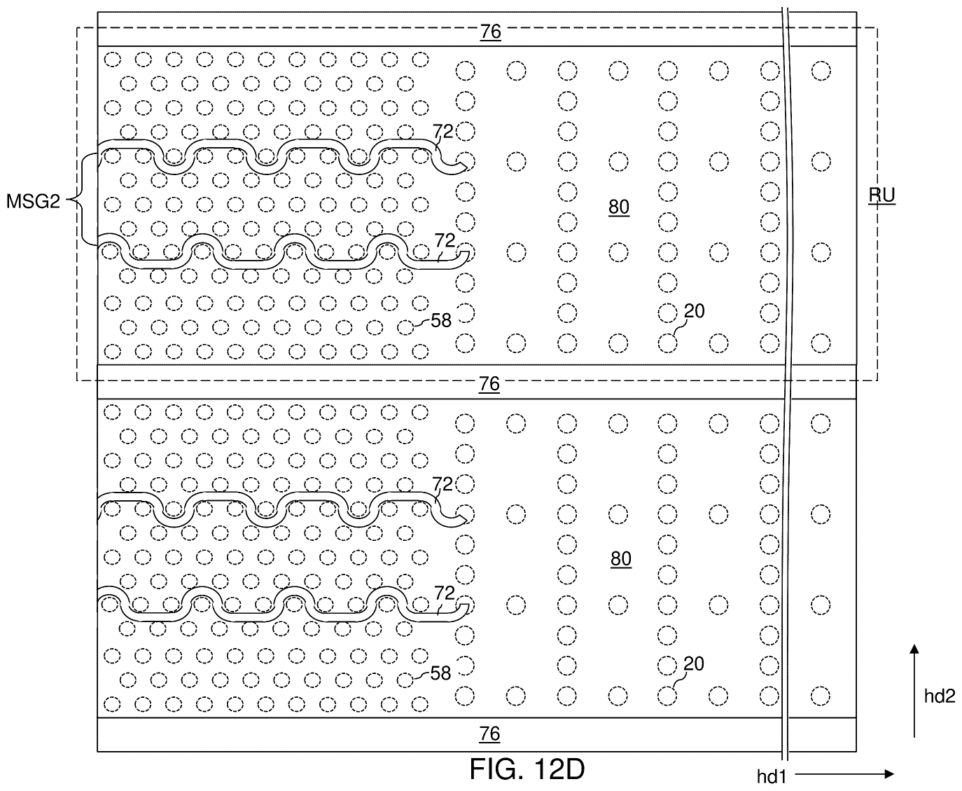

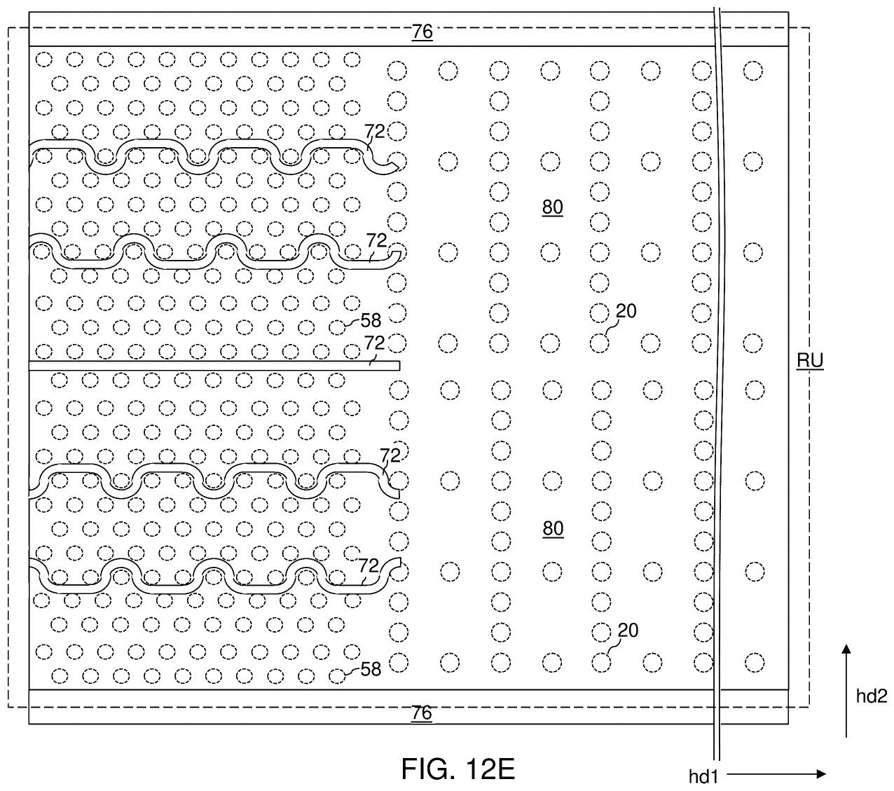

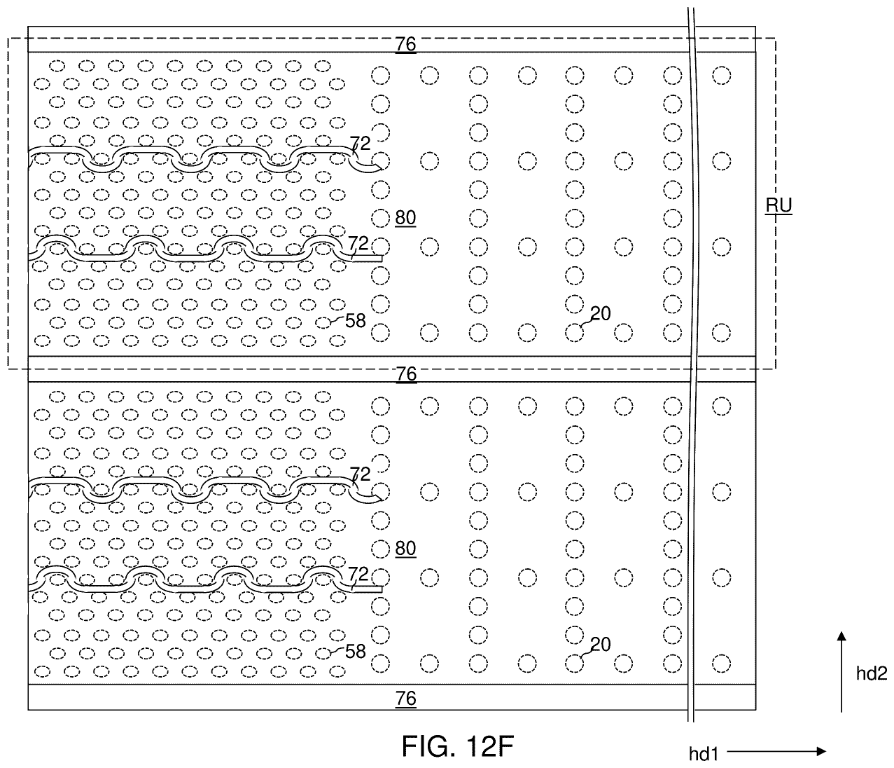

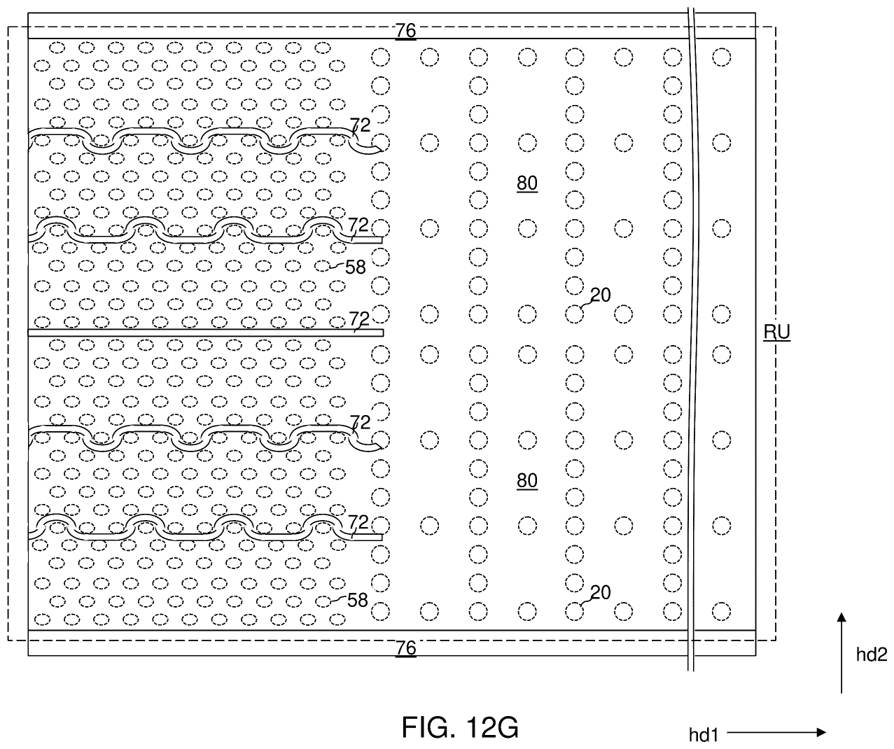

FIG. 12A is a vertical cross-sectional view of the first exemplary structure after formation of lateral isolation trench fill structures 76 and drain-select-level dielectric isolation structures 72 according to an embodiment of the present disclosure. FIG. 12B is a top-down view of the first exemplary structure of FIG. 12A. The vertical plane A-A is the cut plane of the vertical cross-sectional view of FIG. 12A. FIGS. 12C-12G are top-down views of alternative configurations of the first exemplary structure at the processing steps of FIGS. 12A and 12B.

According to an aspect of the present disclosure, each memory block is divided into multiple memory string groups (“MSG”) through formation of drain-select-level dielectric isolation structures 72. Each set of memory strings located between a neighboring pair of drain-select-level isolation structures constitutes a memory string group. Since the drain-select-level isolation structures 72 divide the drain-side select gate electrodes (i.e., uppermost electrically conductive layers 46) but not the underlying word lines or source side select gate electrodes, the area of each drain-side select gate electrode 46D encompasses a respective MSG.

Referring to FIGS. 12A-12G, a photoresist layer (not shown) can be applied over the contact-level dielectric layer 80, and can be lithographically patterned to form openings that generally extend along the first horizontal direction hd1 with lateral undulations along the second horizontal direction hd2 within the area of the memory array region 100. An anisotropic etch process can be performed to transfer the pattern of the openings in the photoresist layer through the contact-level dielectric layer 80 and a subset of electrically conductive layers 46 including at least the topmost electrically conductive layer 46. The anisotropic etch process etches the materials of the contact-level dielectric layer 80 and a subset of layers in the alternating stack (32, 46) to form drain-select-level isolation trenches.

The drain-side select layer(s) 46DL are divided by the lateral isolation trenches are herein referred to as drain-side select gate electrodes 46D, which may be located at a single level or over a plurality of levels (such as 2-10 levels). The subset of the electrically conductive layers 46 that are not divided during the anisotropic etch process and are employed as control gate electrodes of the memory strings are referred to as word lines 46W. A subset of the electrically conductive layers 46 located in proximity to the carrier substrate 9 may be employed as source side select gate electrodes 46S. The photoresist layer can be subsequently removed, for example, by ashing.

A dielectric fill material, such as undoped silicate glass (e.g., silicon oxide) or a doped silicate glass, can be deposited in the lateral isolation trenches 79 and the drain-select-level isolation trenches. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. Each remaining portion of the dielectric fill material that fills a respective one of the drain-select-level isolation trenches constitutes a drain-select-level dielectric isolation structure 72.

In an alternative embodiment, the lateral isolation trench fill structures 76 can be formed during a different processing step than the drain-select-level dielectric isolation structures 72. In this case, the material compositions of the lateral isolation trench fill structures 76 the drain-select-level dielectric isolation structures 72 may be the same or different. For example, the drain-select-level dielectric isolation structures 72 may be formed in an alternating stack of insulating layers 32 and sacrificial material layers 42 before the sacrificial material layers 42 are replaced with the electrically conductive layers 46.

In another alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure. In this case, the drain-select-level isolation trenches and the drain-select-level dielectric isolation structures 72 can be formed before or after formation of the lateral isolation trench fill structures 76.

Generally, each of the lateral isolation trench fill structures 76 comprises a pair of lengthwise dielectric sidewalls that contacts a pair of lengthwise sidewalls of alternating stacks (32, 46). Each drain-select-level dielectric isolation structures 72 has sidewalls contacting a respective pair of divided portions of the at least one drain-select-level electrode layers 46D. Each divided portion of the a drain-side select layer 46DL is referred to as a drain-side select gate electrode 46D.

Generally, each alternating stack (32, 46) of insulating layers 32 and electrically conductive layers 46 can be formed between a neighboring pair of lateral isolation trenches 79, i.e., between a first lateral isolation trench 79 and a second lateral isolation trench 79 (i.e., in each memory block). A first lateral isolation trench fill structure 76 and a second lateral isolation trench fill structure 76 can be formed in the first lateral isolation trench 79 and the second lateral isolation trench 79, respectively. At least one drain-select-level dielectric isolation structure 72 can be formed such that the at least one drain-select-level dielectric isolation structure 72 is present in an upper portion of the alternating stack (32, 46). The word lines 46W laterally extend continuously from the first lateral isolation trench fill structure 76 to the second lateral isolation trench fill structure 76. The drain-side select gate electrodes 46D are laterally spaced from each other along the second horizontal direction hd2 by a respective drain-select-level dielectric isolation structure 72.

Each set of memory opening fill structures 58 located between a respective neighboring pair of isolation structures (72, 76) that are selected from the first or second lateral isolation trench fill structures 76 and the drain-select-level dielectric isolation structure 72 defines a memory string group (MSG). For example, as shown in FIG. 12B, each memory block (MB) contains two MSGs (e.g., MSG1 and MSG2) that are separated from each other by the drain-select-level dielectric isolation structure 72. According to an aspect of the present disclosure, each memory string group MSG includes all memory opening fill structures 58 within a respective set of rows of memory opening fill structures 58 and includes a non-zero fraction of memory opening fill structures 58 within a respective additional row of memory opening fill structures 58. The non-zero fraction of a row is less than an entirety of the row, but greater than no memory opening fill structures 58. In one embodiment, a two-dimensional array of memory strings can be located within each repetition unit RU (e.g., memory block MB) between a neighboring pair of lateral isolation trench fill structures 76. Each memory string comprises a respective memory stack structure 55 and adjacent portions of the electrically conductive layers 46. The two-dimensional array of memory strings may comprise and/or may consist of a plurality of block string groups (BSG), where each BSG=M×P+K, as described above.

According to an aspect of the present disclosure shown in FIG. 12B, (M-1) drain-select-level dielectric isolation structures 72 can be provided in each memory block MB between the first lateral isolation trench fill structure 76 and the second lateral isolation trench fill structure 76, and M memory string groups MSG can be provided in each memory block MB between the first lateral isolation trench fill structure 76 and the second lateral isolation trench fill structure 76. For at least two of the M memory string groups, the non-zero fraction of a row is given by K/M, in which M is an integer greater than 1 and less than 13 and equals to the number of MSGs, and K is a positive integer less than M. In one embodiment, each memory string group MSG may comprise P+K/M rows of memory strings, i.e., may comprise P rows of entire memory strings and a fractional row of memory strings (which is a K/M row of memory strings). A fractional row of memory strings is defined as a subset or portion of an entire row of memory strings that is less than the entirety of the row of memory strings. In the example illustrated in FIG. 12B, M is 2 (i.e., there are 2 MSGs), M-1 is 1 (i.e., there is one isolation structure 72 per memory block MB), P is 4 (i.e., there are four entire rows of memory strings (e.g., memory opening fill structures 58) per MSG), and K is 1 there is one fractional row of memory strings). Since K/M equals to ½ in the example of FIG. 12B, each fractional row contains one half of one the entire row. In the example illustrated in FIG. 12C, M is 4, P is 4, and K is 2. In the example illustrated in FIG. 12D, M is 3, P is 4, and K is 1 (i.e., the fractional row contains K/M=⅓ of an entire row, while the complementary part of the fractional row contains ⅔ of the entire row, where the two complementary parts of the fractional rows in the second MSG2 may be considered to be a row). In the example illustrated in FIG. 12E, M is 6, P is 4, and K is 2. In the example illustrated in FIG. 12F, M is 3, P is 5, and K is 1. In the example illustrated in FIG. 12G, M is 6, P is 5, and K is 2.

In one embodiment, at least one drain-select-level dielectric isolation structure 72 is formed with a lateral undulation along the second horizontal direction hd2. In one embodiment, the drain-select-level dielectric isolation structure 72 is formed between a neighboring pair of memory string groups including a first memory string group and a second memory string group. In one embodiment, the drain-select-level dielectric isolation structure 72 meanders around a row of memory opening fill structures 58 such that a first subset of the memory opening fill structures 58 within the row of memory opening fill structures 58 belongs to the first memory string group, and a second subset of the memory opening fill structures 58 belongs to the second memory string group. In one embodiment, the drain-select-level dielectric isolation structure 72 does not cut through any of the memory opening fill structures 58, such that all of the memory opening fill structures 58 in each memory string group are “whole” memory opening fill structures 58 that do not contain any cut off portions or flat vertical sidewalls. In one embodiment, each whole memory opening fill structure 58 has a circular or substantially circular horizontal cross-sectional shape. A substantially circular shape may occur due to unintentional variations in photolithography and etching of the memory openings 49, which results in slight deviation from an exact circular shape.

In one embodiment, the alternating stack (32, 46) of insulating layers 32 and electrically conductive layers 46 extends along the first horizontal direction hd1. The electrically conductive layers 46 include word lines 46W and drain-side select gate electrodes 46D overlying the word lines 46. Memory opening fill structures 58 vertically extend through the alternating stack (32, 46). Each of the memory opening fill structures 58 includes a vertical stack of memory elements (e.g., portions of the memory film 50 or floating gates) and a vertical semiconductor channel 60. As shown in FIG. 12B, the memory opening fill structures 58 are arranged in columns which extend along a second horizontal direction hd2 perpendicular to the first horizontal direction hd1. An average number of the memory opening fill structures 58 per column that extend through each of the drain-side select gate electrodes 46D is a non-integer number greater than zero.

The columns of memory opening fill structures 58 have a pitch “V” along the first horizontal direction, as shown in FIG. 12B. In one embodiment, the alternating stack (32, 46) comprises a memory block MB and there are at least two drain-side select gate electrodes 46D at each vertical level in the memory block MB.

In one embodiment shown in FIG. 12B, a pair of adjacent ones of the drain-side select electrodes 46D (which are located in adjacent MSGs, such as in MSG1 and MSG2) are laterally separated from each other along the second horizontal direction hd2 by a drain-select-level dielectric isolation structure 72. An average number of whole ones of the memory opening fill structures 58 (that are not cut by the drain-select-level dielectric isolation structure 72) per column that extend through each of the drain-side select gate electrode 46D is the non-integer number greater than zero.

In one embodiment, the columns comprise a repeating set of x columns that contain C memory opening fill structures 58 followed by Y columns that contain C+1 or C−1 memory opening fill structures 58, wherein C is an integer that is equal to or greater than 2, x is an integer that is equal to or greater than 2, and Y is an integer that is equal to or greater than 1. For example, as shown in FIG. 12B, the set includes four columns (e.g., columns 2, 3, 4 and 5). There are three columns (e.g., columns 2, 3 and 4) that contain two memory opening fill structures 58 (i.e., C=2 and X=3) followed by one column (e.g., column 5) that contains three memory opening fill structures (i.e., C+1=3 and Y=1). Similar repeating sets of columns are shown in FIGS. 12C-12G, with different values of C, x and Y.

In one embodiment, each N-th memory opening fill structure within the row of memory opening fill structures 58 belongs to the first memory string group, and all other memory opening structures within the row of memory opening fill structures 58 belong to the second memory string group, wherein N is an integer greater than 1 and less than 13. In one embodiment, if the number M/K is an integer, the integer N may be the same as M/K. In the example illustrated in FIG. 12B, M is 2, P is 4, and K is 1, and the integer N is 2. In the example illustrated in FIG. 12C, M is 4, P is 4, and K is 2, and the integer N is 2. In the example illustrated in FIG. 12D, M is 3, P is 4, and K is 1, and the integer N is 3. In the example illustrated in FIG. 12E, M is 6, P is 4, and K is 2, and the integer N is 3. In the example illustrated in FIG. 12F, M is 3, P is 5, and K is 1, and the integer N is 3. In the example illustrated in FIG. 12G, M is 6, P is 5, and K is 2, and the integer N is 3.

In one embodiment, the at least one drain-select-level dielectric isolation structure 72 may consist of only one drain-select-level dielectric isolation structure 72, and the non-zero fraction may be ½, as illustrated in FIG. 12B.

In one embodiment, M memory string groups are located in each memory block MB between the first lateral isolation trench fill structure 76 and the second lateral isolation trench fill structure 76, the at least one drain-select-level dielectric isolation structure 72 comprises (M-1) drain-select-level dielectric isolation structures 72, and M is an integer greater than or equal to 2, for example, an integer greater than 2, as illustrated in FIGS. 12C-12G.

In one embodiment, M is an odd number greater than 2, and each of the (M-1) drain-select-level dielectric isolation structures 72 meanders around a respective row of memory opening fill structures 58 such that a first non-zero fraction of the memory opening fill structures 58 in the respective row is located on a first side of a respective drain-select-level dielectric isolation structure 72, and a second non-zero fraction of the memory opening fill structures 58 is located on a second side of the respective drain-select-level dielectric isolation structure 72, as illustrated in FIGS. 12D and 12F.

In one embodiment, M is an even number greater than 3, and at least two and less than (M-1) of the (M-1) drain-select-level dielectric isolation structures 72 meander around a respective row of memory opening fill structures 58 such that a first non-zero fraction of the memory opening fill structures 58 in the respective row is located on a first side of a respective drain-select-level dielectric isolation structure 72, and a second non-zero fraction of the memory opening fill structures 58 is located on a second side of the respective drain-select-level dielectric isolation structure 72; and at least one of the (M-1) drain-select-level dielectric isolation structure 72 laterally extends straight along the first horizontal direction hd1, as illustrated in FIGS. 12C, 12E, and 12G.

In one embodiment, M memory string groups are located in each memory block MB between the first lateral isolation trench fill structure 76 and the second lateral isolation trench fill structure 76, and for two memory string groups of the M memory string groups, the non-zero fraction is given by K/M, in which M is an integer greater than 1 and less than 13, and K is a positive integer less than M.

In one embodiment, each row of memory opening fill structures 58 includes Q memory opening fill structures 58; and each memory string group includes (P+K/M)×Q memory opening fill structures 58, where P is an integer greater than 1, M is an integer greater than 1 and less than 13, and K is a positive integer less than M. In one embodiment, each of the memory opening fill structures 58 comprises a vertical semiconductor channel 60, a vertical stack of memory elements (e.g., portions of the memory film 50) and a drain region 63; and the memory device also comprises bit lines 128 (described below) laterally extending along the second horizontal direction hd2 and electrically connected to a respective subset of the drain regions 63 of the memory opening fill structures 58.

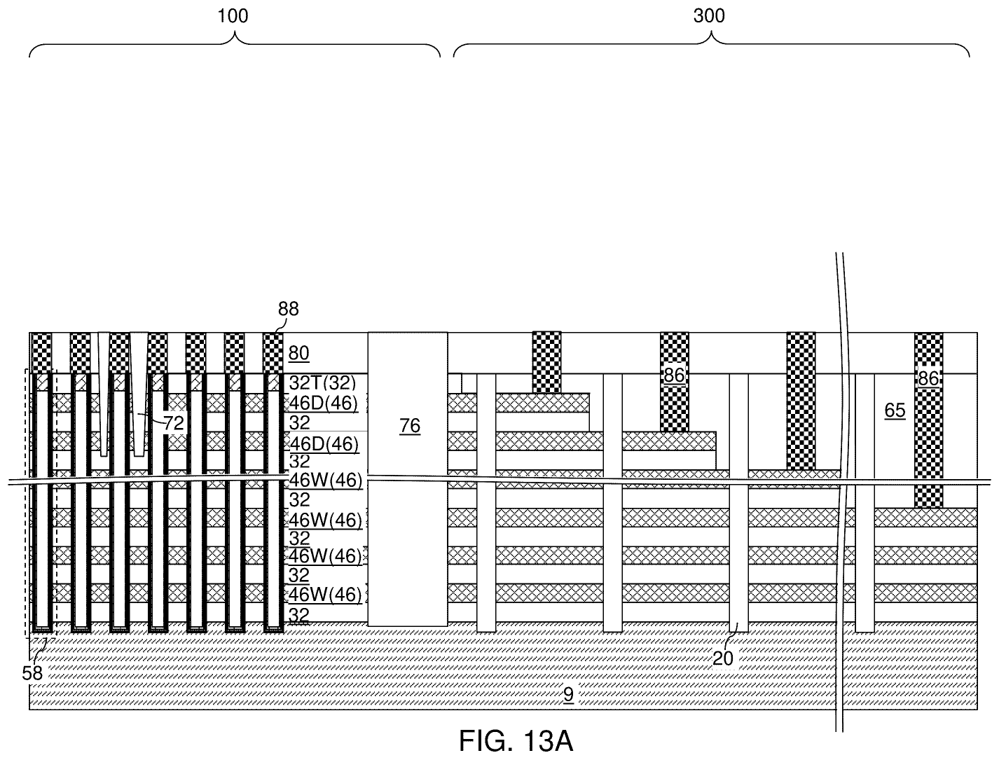

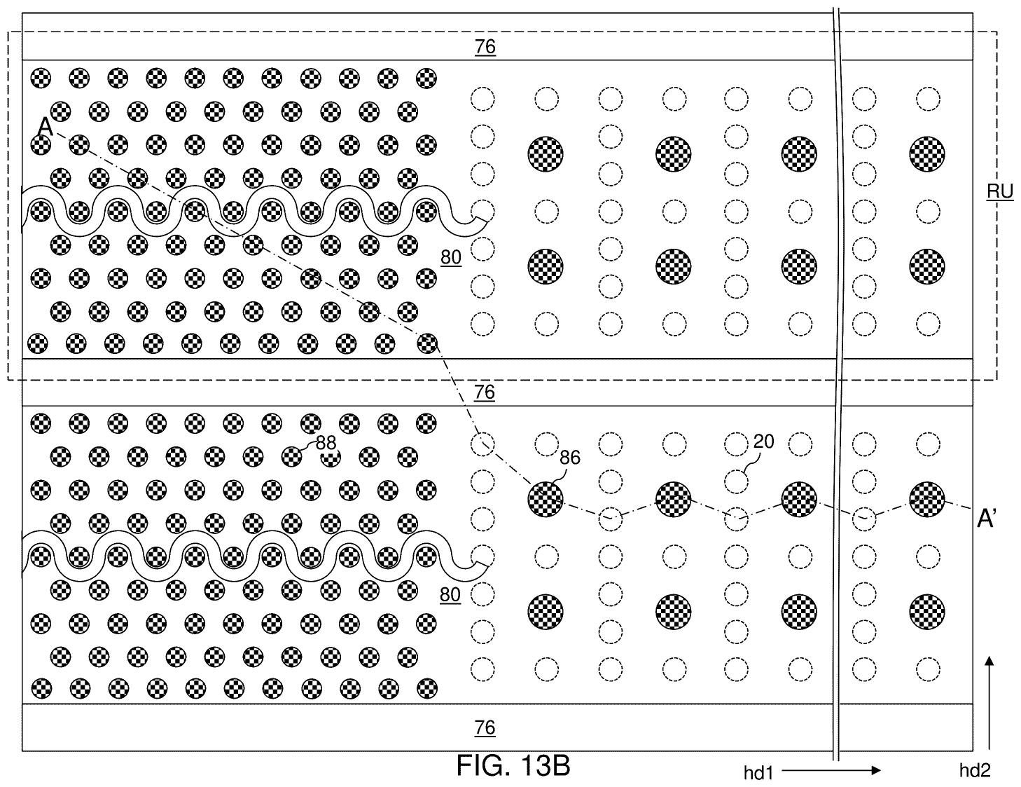

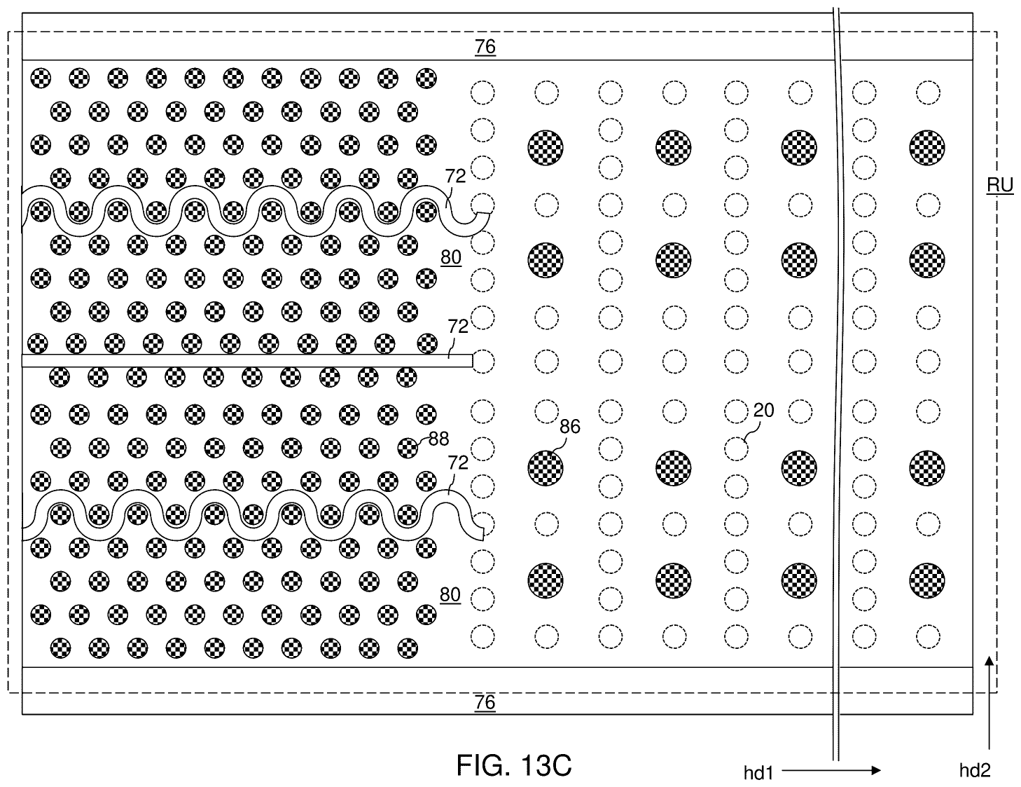

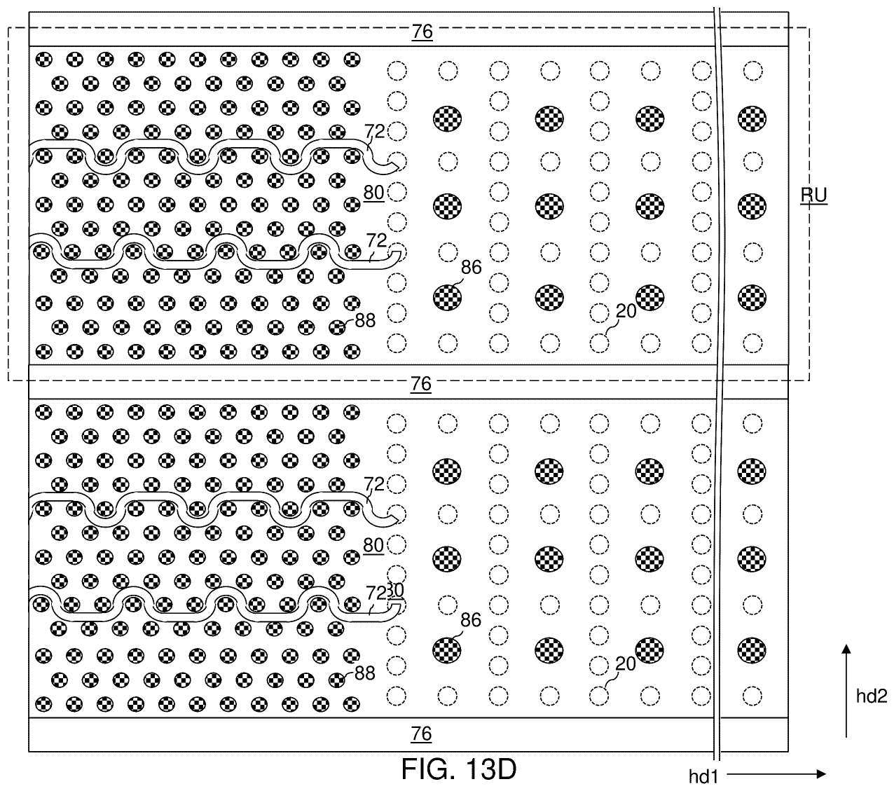

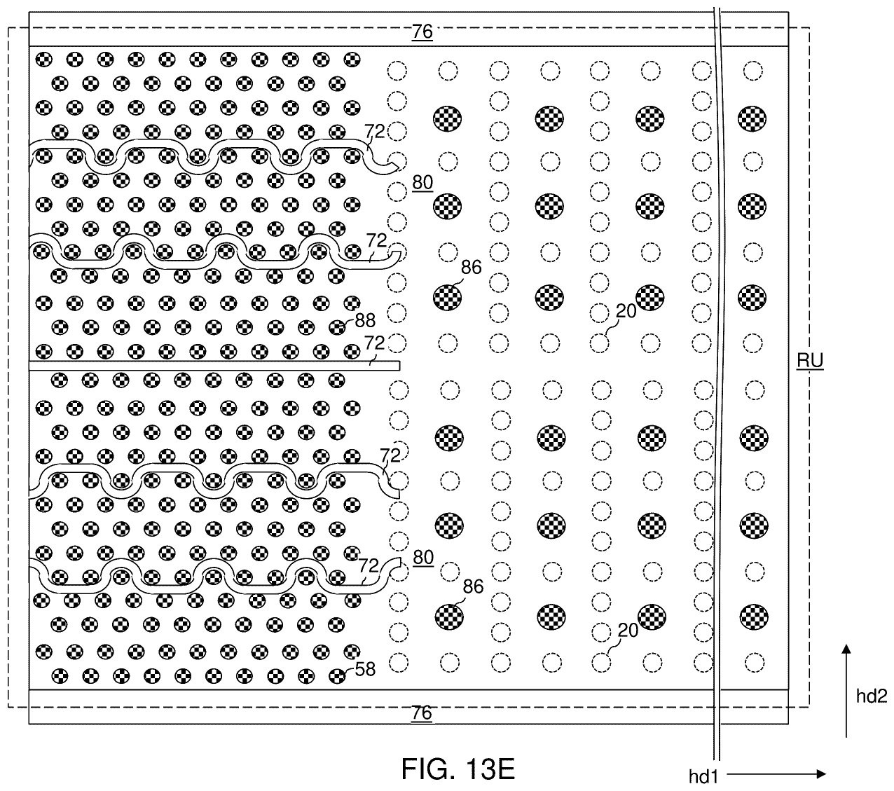

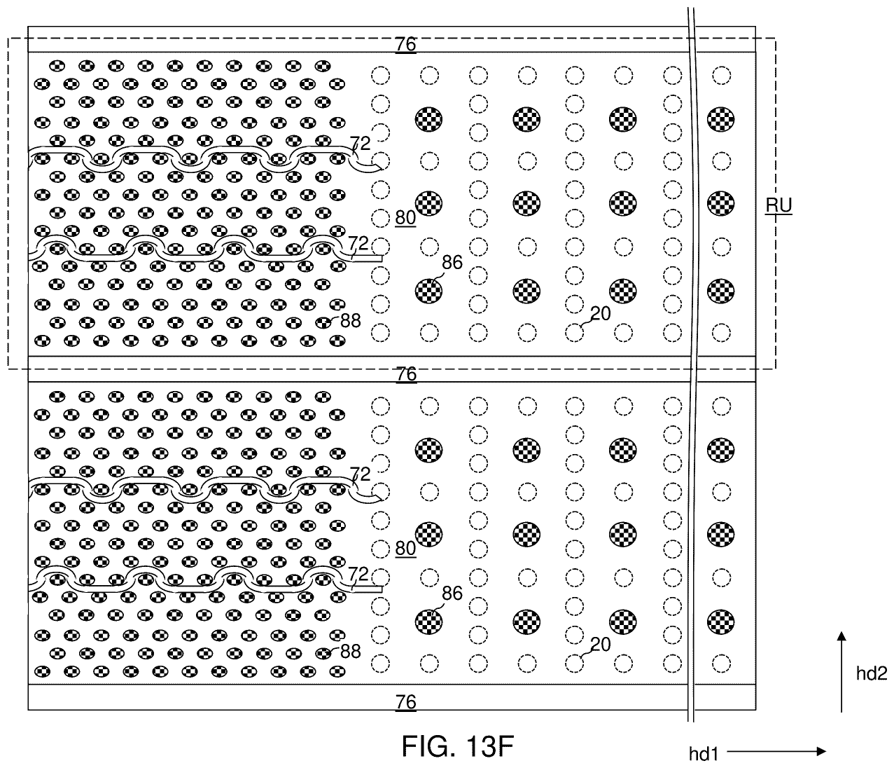

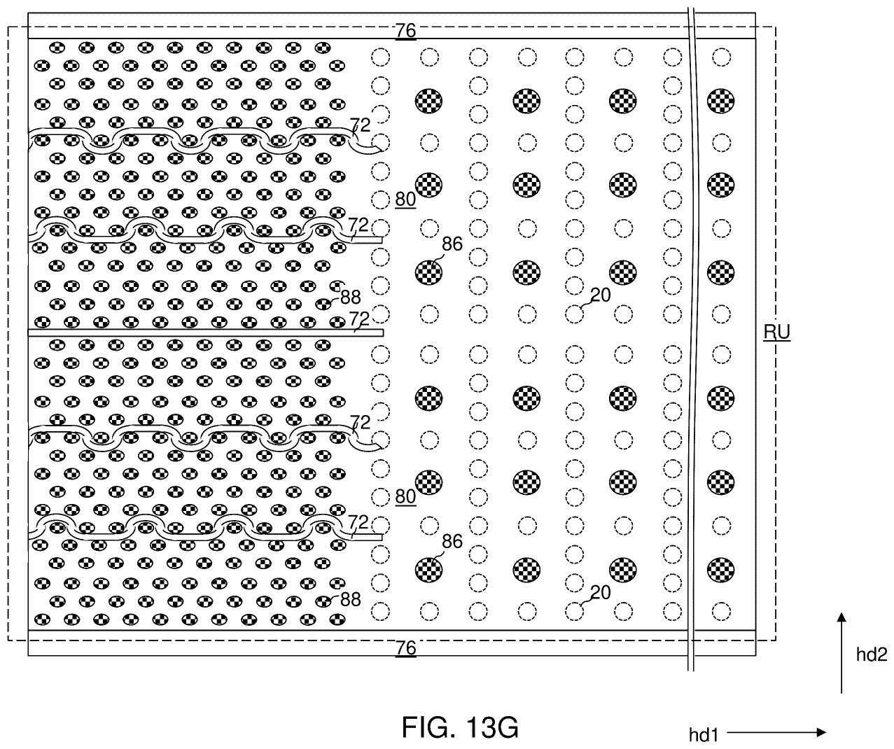

FIG. 13A is a vertical cross-sectional view of the first exemplary structure after formation of layer contact via structures 86 and drain contact via structures 88 according to an embodiment of the present disclosure. FIG. 13B is a top-down view of the first exemplary structure of FIG. 13A. The vertical plane A-A is the cut plane of the vertical cross-sectional view of FIG. 13A. FIGS. 13C-13G are top-down views of alternative configurations of the first exemplary structure at the processing steps of FIGS. 13A and 13B.

Referring to FIGS. 13A-13G, contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

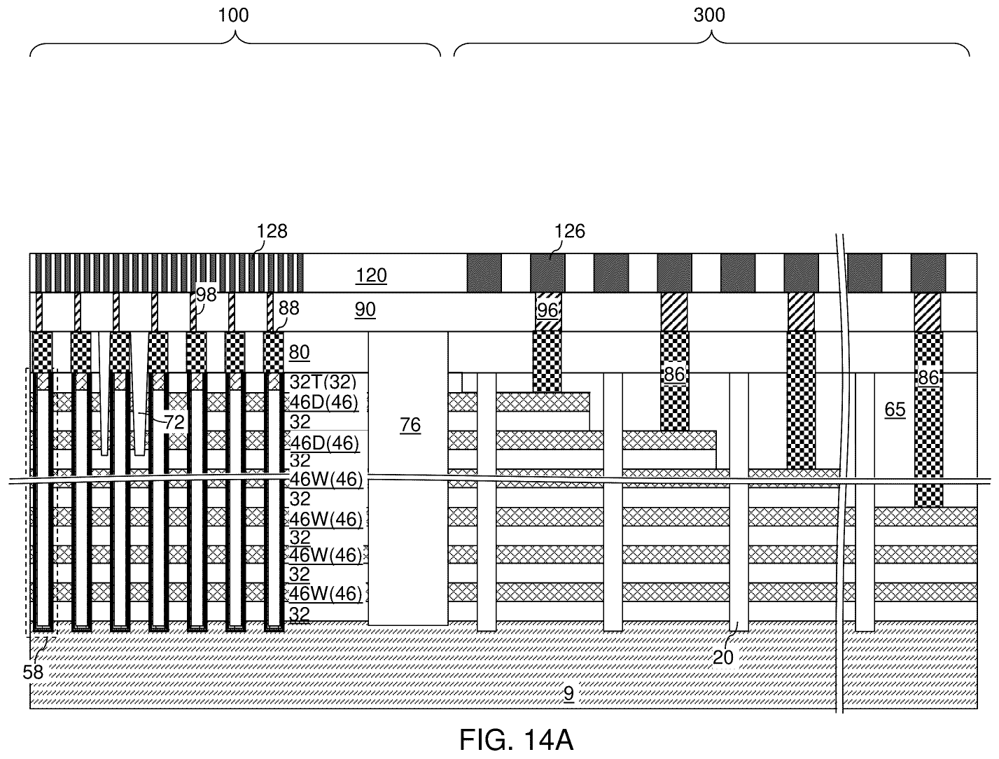

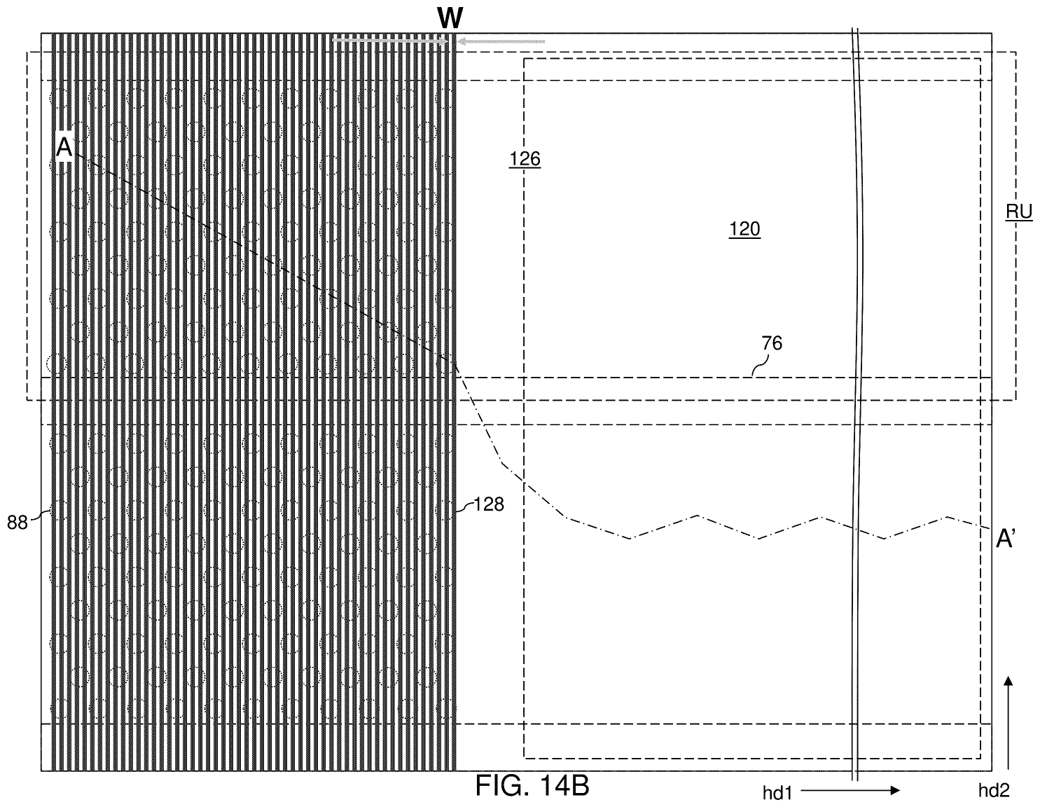

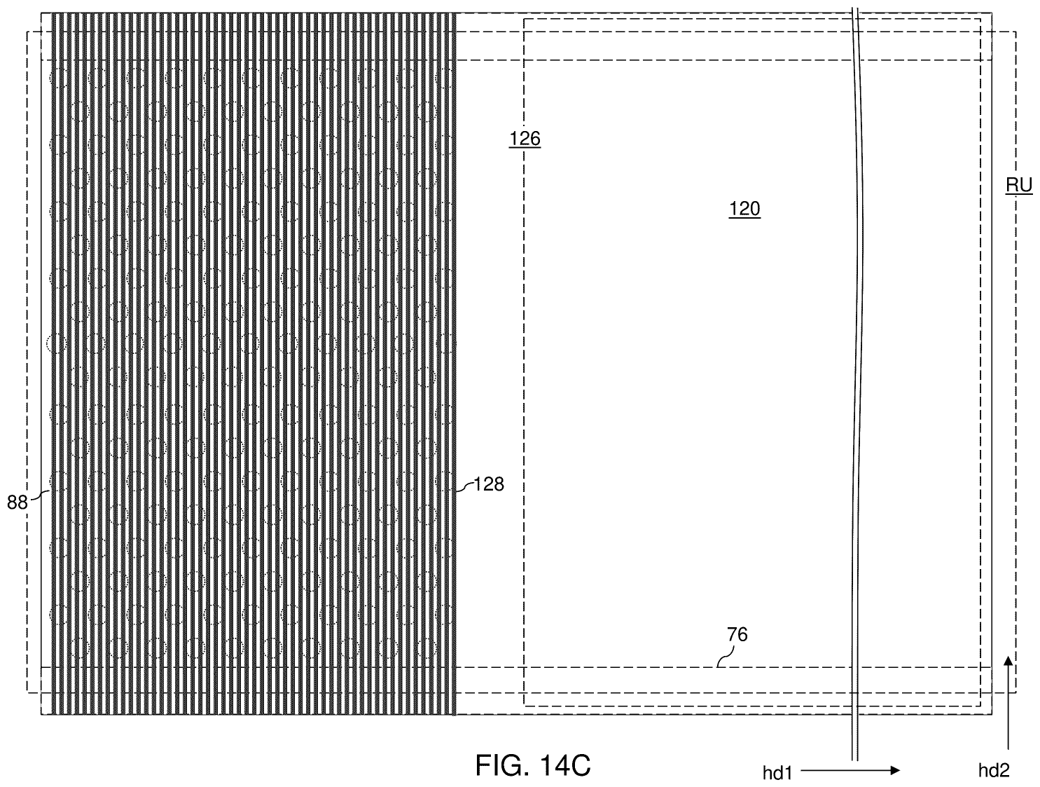

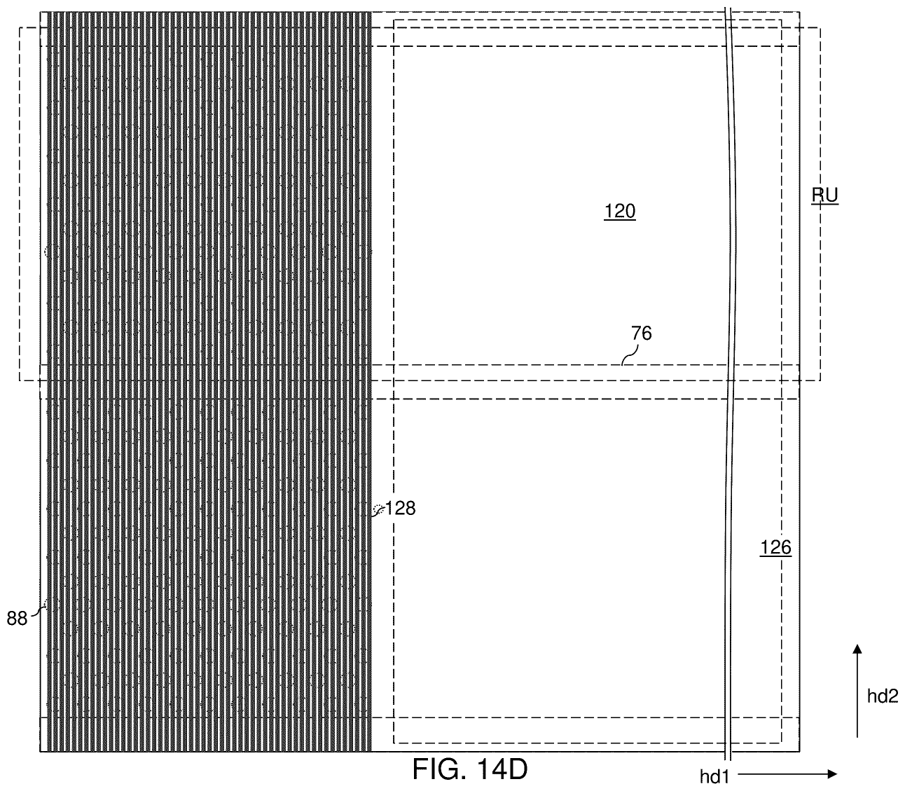

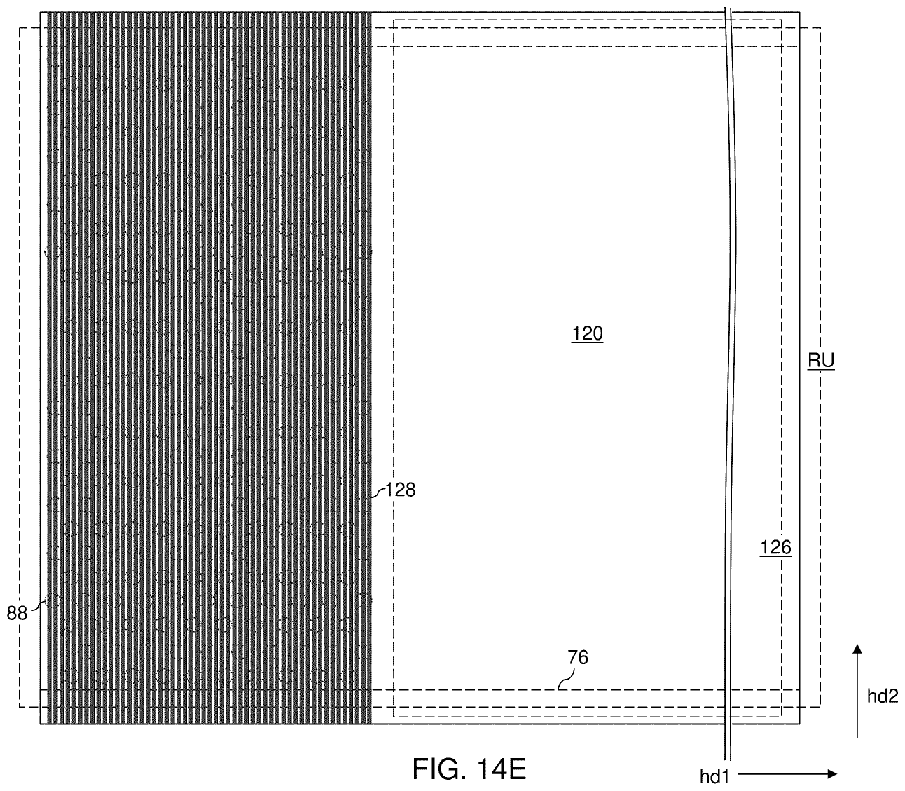

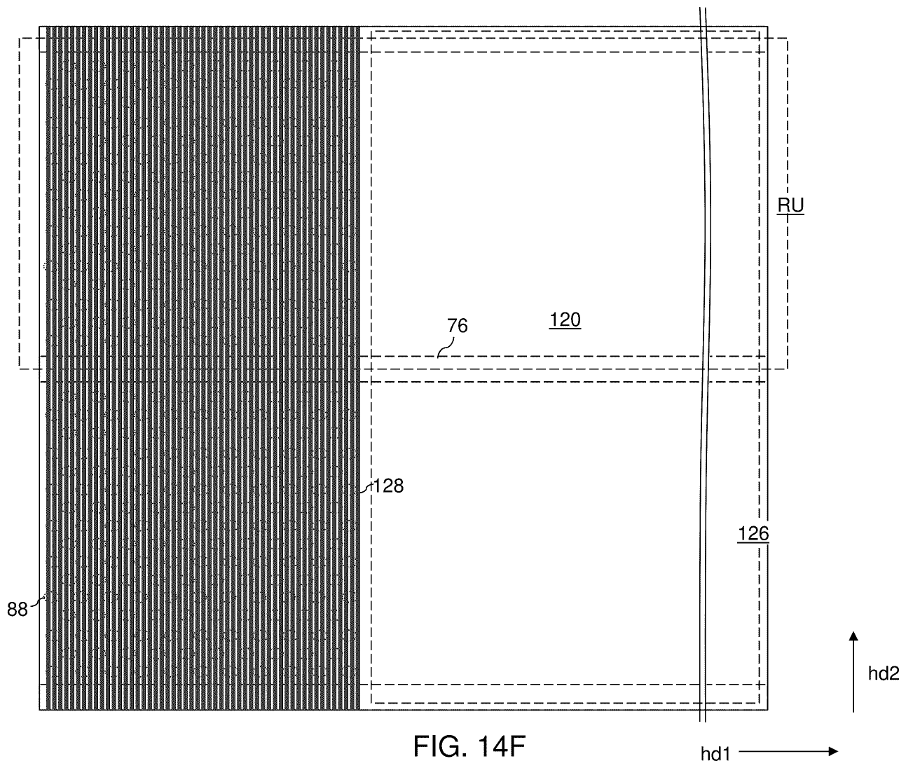

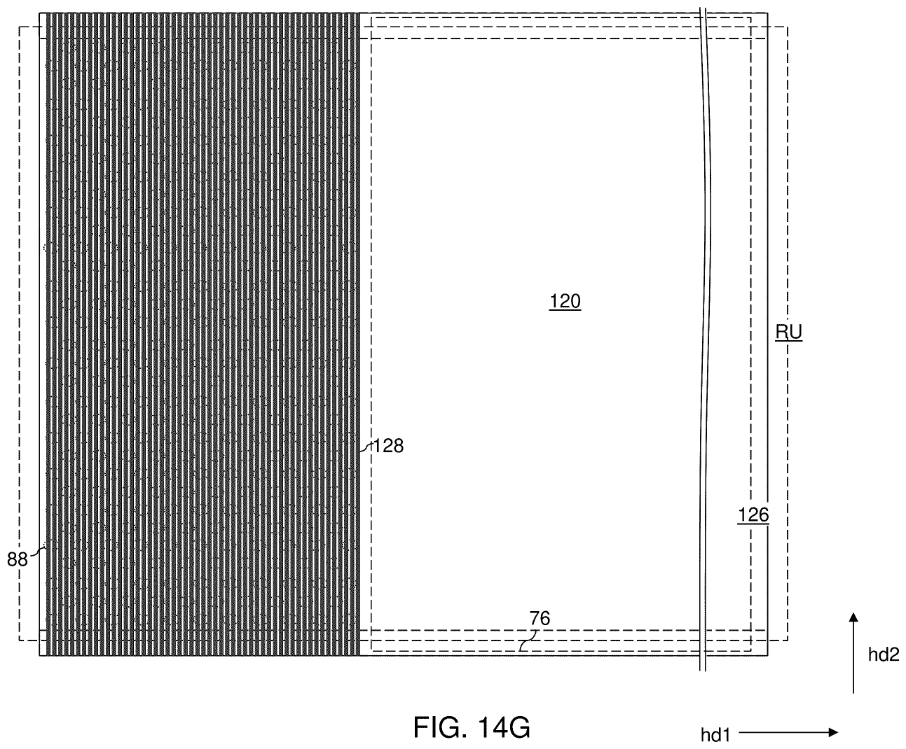

FIG. 14A is a vertical cross-sectional view of the first exemplary structure after formation of connection via structures and bit lines 128 according to an embodiment of the present disclosure. FIG. 14B is a top-down view of the first exemplary structure of FIG. 14A. The vertical plane A-A is the cut plane of the vertical cross-sectional view of FIG. 14A. FIGS. 14C-14G are top-down views of alternative configurations of the first exemplary structure at the processing steps of FIGS. 14A and 14B.

Referring to FIGS. 14A-14G, a connection-level dielectric layer 90 can be formed above the contact-level dielectric layer 80. Connection via cavities can be formed through the connection-level dielectric layer 90, and can be filled with at least one conductive material to form connection-level via structures (98, 96). The connection-level via structures (98, 96) comprise drain connection via structures 98 that contact a respective one of the drain contact via structures 88, and layer connection via structures 96 that contact a respective one of the layer contact via structures 86.

A bit-line-level dielectric layer 120 can be formed above the connection-level dielectric layer 90. Bit-line-level line cavities can be formed through the bit-line-level dielectric layer 120, and can be filled with at least one conductive material (which may comprise at least one metallic material) to form bit-line-level metal lines (128, 126). The bit-line-level metal lines 128 may comprise bit lines 128 that laterally extend along the second horizontal direction hd2, and bit-line-level interconnect metal lines 126 that can be employed to provide electrical connection to the layer connection via structures 96.

In one embodiment, a two-dimensional array of drain connection via structures 98 can be located within each memory block MB (e.g., in each repetition unit RU) between areas of a neighboring pair of lateral isolation trench fill structures 76. The two-dimensional array of drain connection via structures 98 may comprise and/or may consist of M×P+K rows of drain connection via structures 98. M is an integer greater than 1 and less than 13, P is an integer greater than 1 and less than 9, and K is a positive integer less than M. In one embodiment, each row of drain connection via structures 98 may comprise Q drain connection via structures 98. The integer Q may be in a range from 2⁴ to 2¹⁶, such as from 2⁶ to 2¹³, although lesser and greater numbers may also be employed. In the example illustrated in FIG. 14B, M is 2, P is 4, and K is 1. In the example illustrated in FIG. 14C, M is 4, P is 4, and K is 2. In the example illustrated in FIG. 14D, M is 3, P is 4, and K is 1. In the example illustrated in FIG. 14E, M is 6, P is 4, and K is 2. In the example illustrated in FIG. 14F, M is 3, P is 5, and K is 1. In the example illustrated in FIG. 14G, M is 6, P is 5, and K is 2.

In one embodiment, the total number of bit lines 128 in the memory array region 100 may be not greater than (P+1)×Q. In one embodiment, P is an even number; and for a memory string group of the M memory string groups in each memory block MB between a first lateral isolation trench fill structure 76 and a second lateral isolation trench fill structure 76, a first subset of the bit lines 128 is electrically connected to a respective drain region 63 within the memory string group, and a second subset of the bit lines 128 is electrically isolated from each drain region 63 within the memory string group. In one embodiment, for a memory string group of the M memory string groups, a total number of bit lines 128 electrically connected to drain regions 63 within the memory string group is the same as a total number of drain regions 63 within the memory string group. The total number of memory strings within a memory block MB located between a neighboring pair of lateral isolation trench fill structures 76 may be Q×(M×P+K). Thus, the average number of memory strings electrically connected to a single bit line 128 of all memory strings in the memory block is given by Q×(M×P+K) divided by (P+1)×Q, which is M−(M−K)/(P+1). Generally, a first subset of the bit lines 128 is electrically connected to M memory strings within the memory block MB, and a second subset of the bit lines 128 is electrically connected to (M-1) memory strings.

In one embodiment, the bit lines 128 extend along the second horizontal direction hd2 and are electrically connected to a respective drain regions 63 in the memory opening fill structures 58. As shown in FIG. 14B, the bit lines 128 have a pitch W along the first horizontal direction which equals to the pitch V of the columns of the memory opening fill structures 58 (shown in FIG. 12B) along the first horizontal direction hd1 divided by an odd integer.

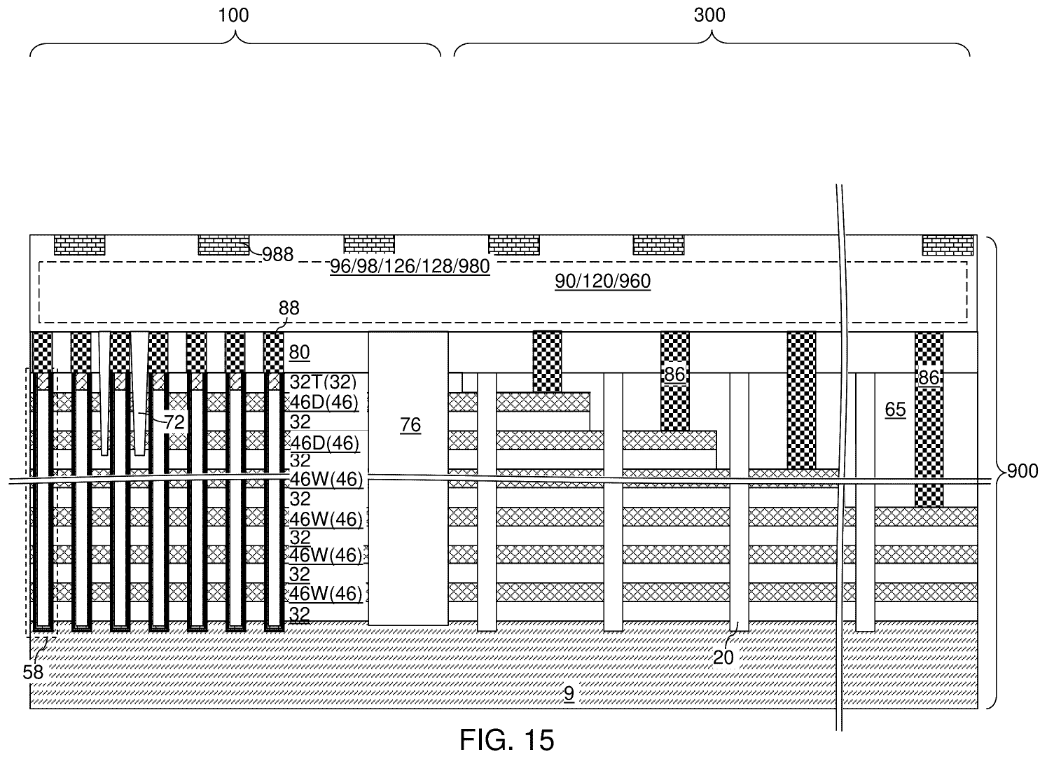

Referring to FIG. 15, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

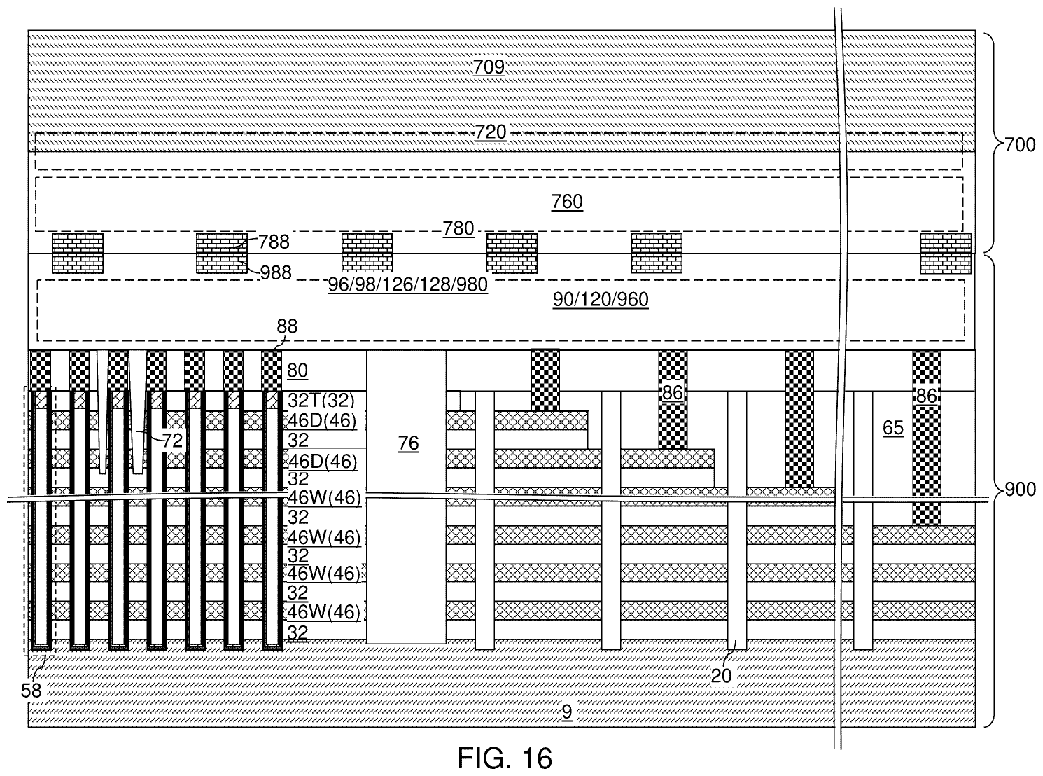

Referring to FIG. 16, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

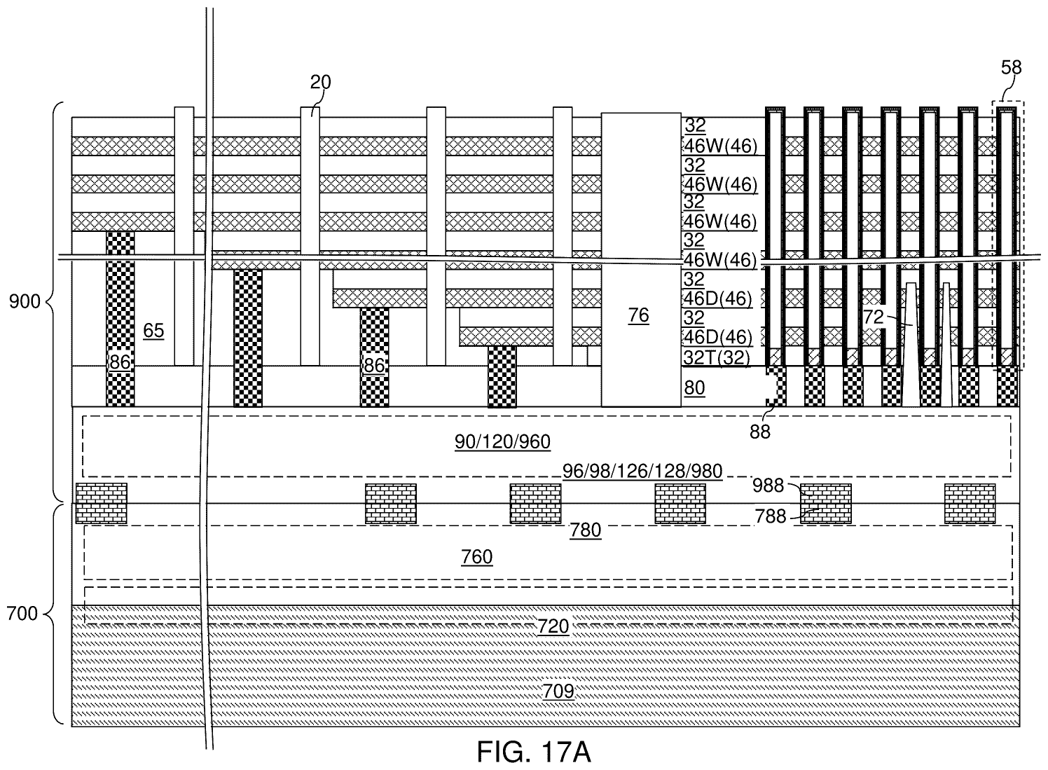

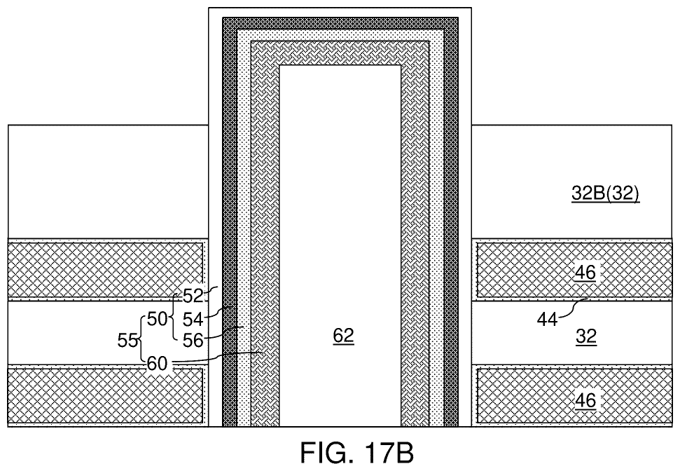

Referring to FIGS. 17A and 17B, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selectively to dielectric materials of the memory films 50. In an illustrative example, if the carrier substrate 9 comprises a semiconductor material, the terminal step of the at least one removal process may comprise a wet etch process using hot trimethyl-2-hydroxyethyl ammonium hydroxide (“hot TMY”) or tetramethylammonium hydroxide (TMAH). The entirety of the carrier substrate 9 can be removed by the selective wet etch process. Backside end surfaces of the support pillar structures 20 can be physically exposed upon removal of the carrier substrate 9.

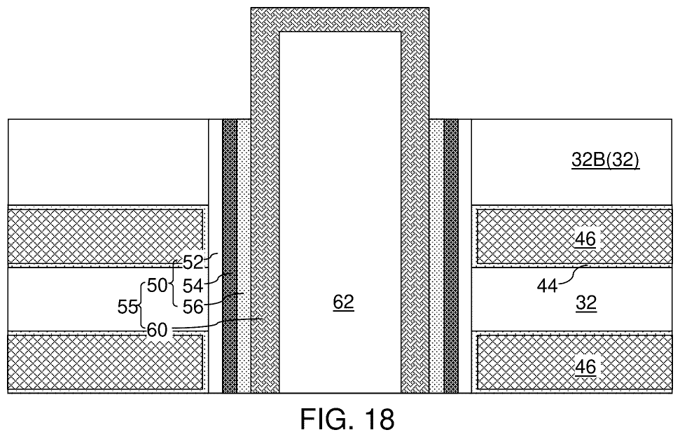

Referring to FIG. 18, an end portion of each memory film 50 may be removed by performing a sequence of wet etch processes. In one embodiment, the sequence of wet etch processes may comprise a first wet etch process that etches the material of the blocking dielectric layer 52 selectively to the material of the memory material layer 54, a second wet etch process that etches the material of the memory material layer 54 selectively to the material of the dielectric liner 56, and a third wet etch process that etches the material of the dielectric liner 56 selectively to the material of the vertical semiconductor channel 60. Upon removal of the end portion of the memory film 50, an end portion of each vertical semiconductor channel 60 may be physically exposed.

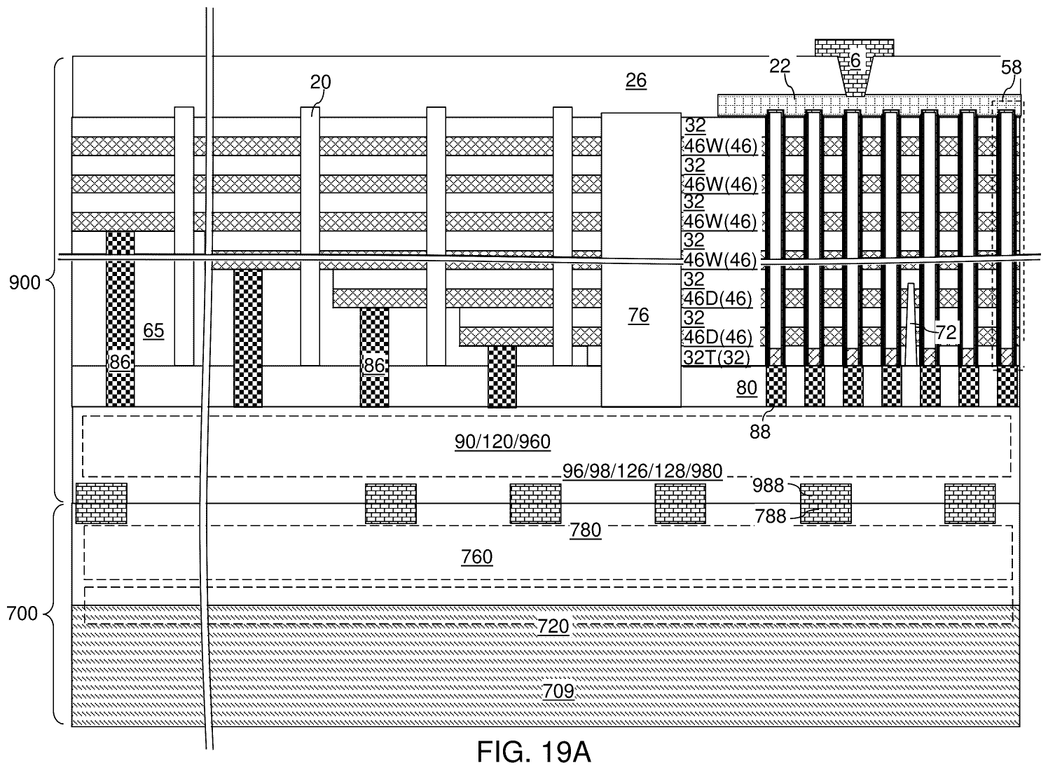

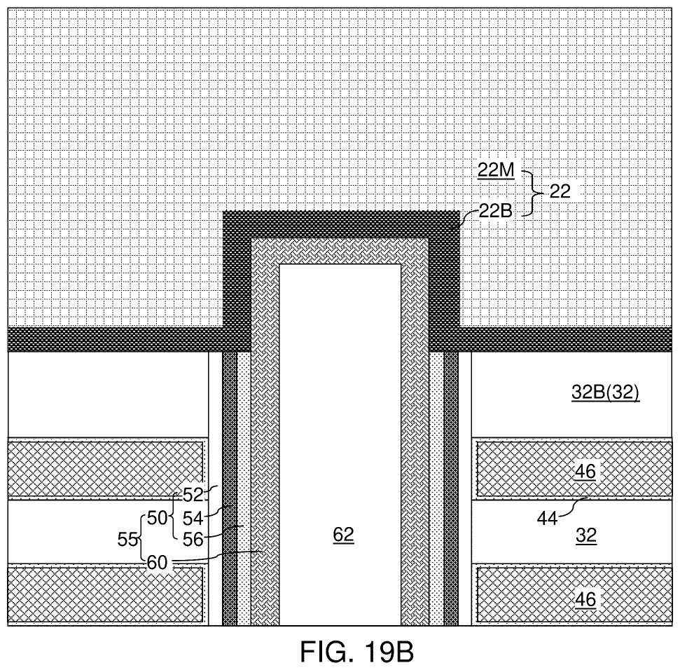

Referring to FIGS. 19A and 18B, a source layer 22 may be formed on the physically exposed end surfaces of the vertical semiconductor channels 60. The source layer 22 may comprise a heavily-doped semiconductor material and/or at least one metallic material. A backside dielectric layer 26 can be formed over the source layer, and various backside contact via structures such as source contact structures 6 may be formed through the backside dielectric layer 26.

Referring to all drawings and according to various embodiments of the present disclosure, a memory device is provided, which comprises: an alternating stack (32, 46) of insulating layers 32 and electrically conductive layers 46, wherein the alternating stack (32, 46) is located between a first lateral isolation trench fill structure 76 and a second lateral isolation trench fill structure 76 that laterally extend along a first horizontal direction hd1 and are laterally spaced from each other along a second horizontal direction hd2, wherein the electrically conductive layers 46 comprise word lines 46W that laterally extend contiguously from the first lateral isolation trench fill structure 76 to the second lateral isolation trench fill structure 76, and further comprise drain-side select gate electrodes 46D overlying the word lines 46W, wherein each of the drain-side select gate electrodes 46D comprises a respective plurality of drain-side select gate electrodes that are laterally spaced among one another along the second horizontal direction hd2 by at least one drain-select-level dielectric isolation structure 72 that generally extends along the first horizontal direction hd1; memory openings 49 vertically extending through the alternating stack (32, 46) and arranged in multiple rows such that each of the multiple rows is arranged along the first horizontal direction hd1 and neighboring rows among the multiple rows are laterally spaced from each other along the second horizontal direction hd2; and memory opening fill structures 58 located in the memory openings 49, wherein each set of memory opening fill structures 58 that vertically extends between a respective neighboring pair of isolation structures (72, 76) that are selected from the first lateral isolation trench fill structure 76, the second lateral isolation trench fill structure 76, and the at least one drain-select-level dielectric isolation structure 72 defines a memory string group, and each memory string group includes all memory opening fill structures 58 within a respective set of rows of memory opening fill structures 58 and includes a non-zero fraction of memory opening fill structures 58 within a respective additional row of memory opening fill structures 58, the non-zero fraction being less than an entirety of the memory opening fill structures 58 within a respective additional row.

The various embodiments of the present disclosure include columns of memory opening fill structures having a non-integer average number of memory opening fill structures and memory string groups including a fractional number of rows of memory strings. This configuration provides an optimum combination of the pitch W of the bit lines 128 along the first horizontal direction hd1 that may be achieved using available photolithography methods versus array size and device response speed that is a function of the length of the word lines 46 along the first horizontal direction hd1.

In a second embodiment, the lateral trench isolation structures 76 are wavy to provide columns of memory opening fill structures 58 having a non-integer average number of memory opening fill structures. In the second embodiment, the drain-select-level isolation structures 72 may be straight.

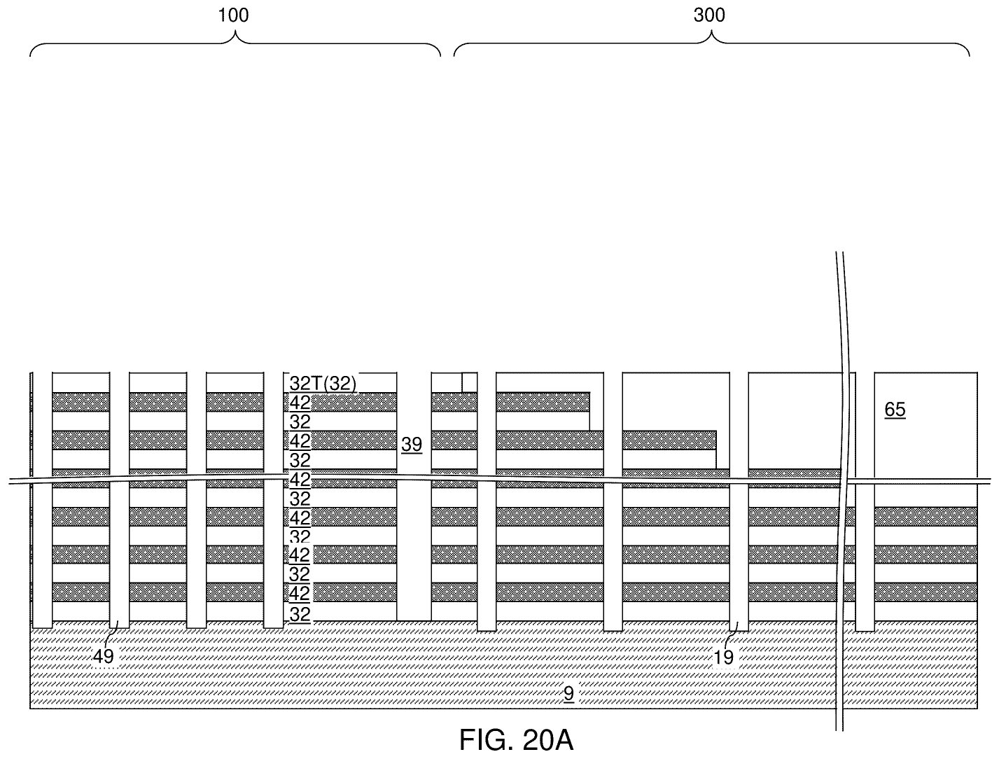

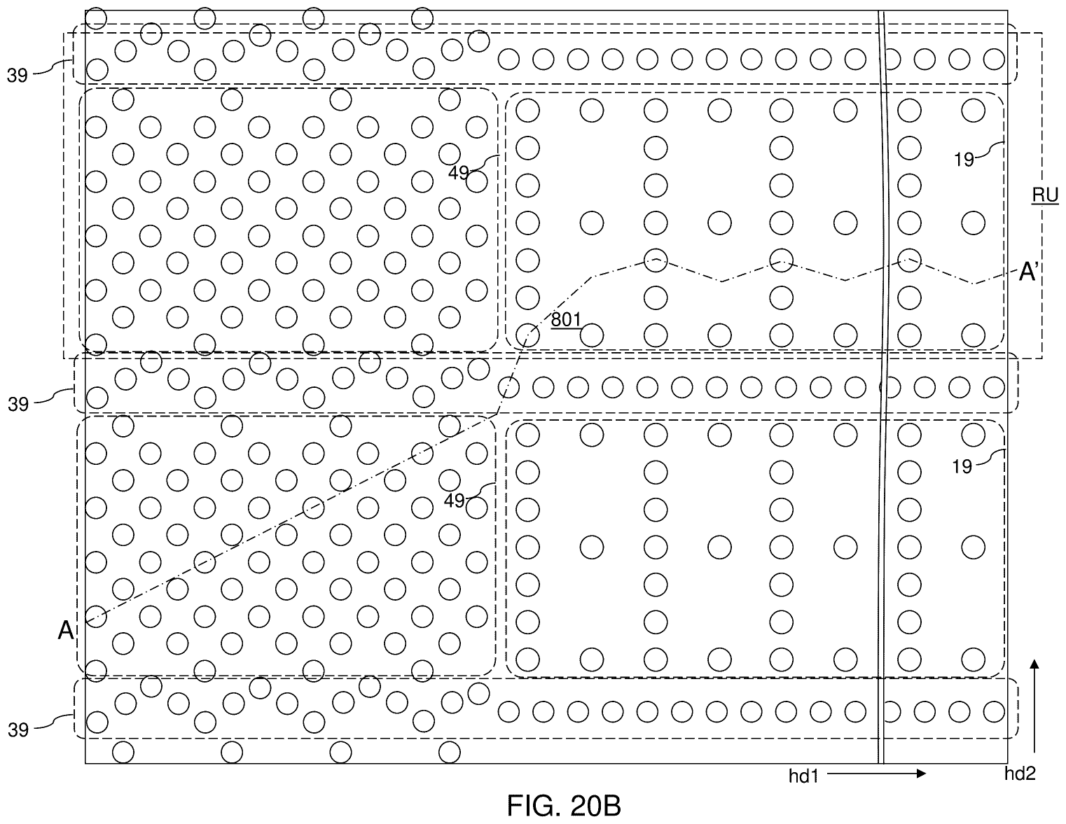

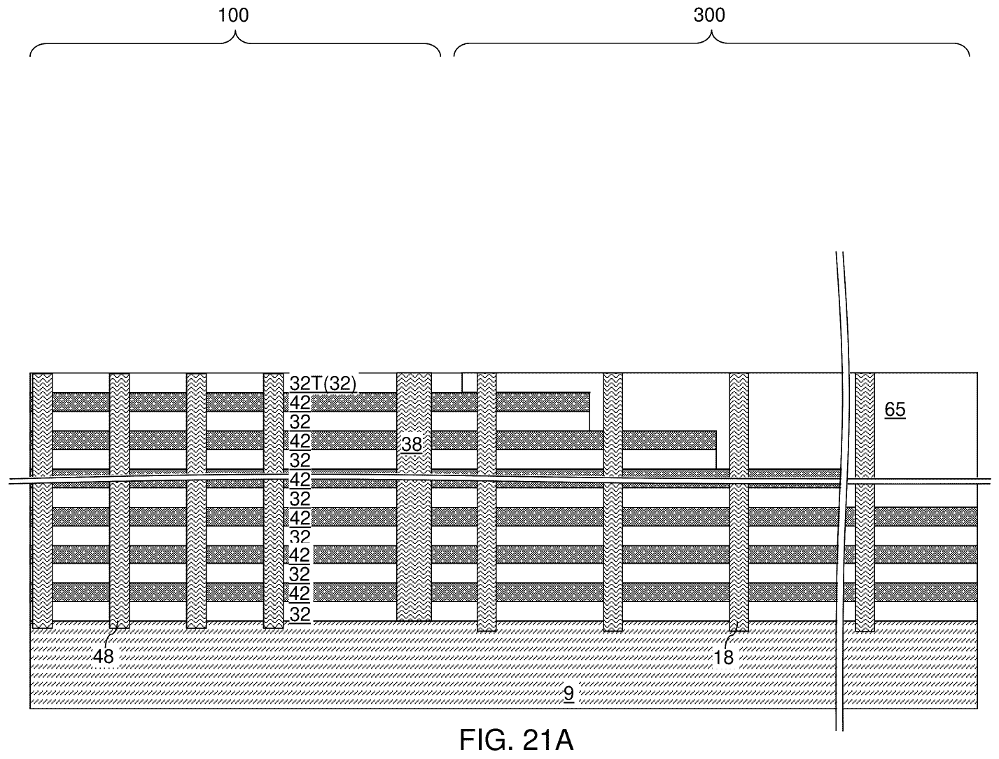

Referring to FIGS. 20A and 20B, the second exemplary structure according to the second embodiment of the present disclosure can be derived from the first exemplary structure of the first embodiment illustrated in FIG. 2 by performing the processing steps described with reference to FIGS. 3A-3G with a modification in the pattern of openings that are formed through the alternating stack of insulating layers 32 and sacrificial material layers 42 and through the retro-stepped dielectric material portion 65. In the second embodiment, a vertically alternating sequence (which constitutes an alternating stack (32, 42)) of continuous insulating layers 32 and continuous sacrificial material layers 42 can be formed over a substrate. Isolation openings 39 may be formed in addition to memory openings 49 and support openings 19. The discrete isolation openings 39 are formed instead of the lateral isolation trenches 79.

In the second exemplary structure, the isolation openings 39, the memory openings 49, and the support openings 19 are formed as components of a periodic pattern. A repetition unit RU includes a unit pattern that is repeated along the second horizontal direction hd2. The memory openings 49 are arranged in columns which extend along the second horizontal direction hd2 which is perpendicular to the first horizontal direction hd1. The average number of the memory openings 49 per column within each repetition unit RU is a non-integer number greater than zero. In the illustrated example of FIG. 20B, a first subset of the columns of the memory openings 49 in each repetition unit RU includes 5 memory openings, and a second subset of the columns of the memory openings in each repetition unit RU includes 4 memory openings, such that the average number of the memory openings 49 per column within each repetition unit RU is 4.5. While an embodiment is described in which the average number of the memory openings 49 per column within each repetition unit RU is 4.5, in alternative embodiments, the average number may generally be a non-integer number between 3 and 9.

In one embodiment, the columns of memory openings 49 within each repetition unit RU may comprise a repeating set of a combination of I columns that contain P memory opening fill structures 58 and J columns that contain (P+1) or (P−1) memory opening fill structures 58. In this case, P is an integer that is equal to or greater than 2, I is a first integer that is equal to or greater than 2, and J is a second integer that is equal to or greater than 1. In the illustrated example, P is 4, I is 2, J is 2, and the J columns contain 5 memory openings 49.

The pattern of the support openings 19 in the second exemplary structure may, or may not, be the same as the pattern of the support openings 19 in the first exemplary structure illustrated in FIGS. 3A-3G.

The pattern of the isolation openings 39 can be selected such that the isolation openings 39 may be expanded to form lateral isolation trenches in a subsequent processing step. In this case, the lateral isolation trenches may be formed by lateral expansion of the isolation openings 39 and by merging the laterally expanded isolation openings in the subsequent processing step. In one embodiment, a first subset of the isolation openings 39 located between neighboring clusters of support openings 19 in the contact region 300 may be arranged along a straight line that is parallel to the first horizontal direction hd1, and a second subset of the isolation trenches 39 located between neighboring clusters of memory openings 39 in the memory array region 100 may be arranged generally along the first horizontal direction hd1 with periodic lateral shifts in the positions along the second horizontal direction hd2 so that nearest lateral distance between the isolation openings 39 and the memory openings 49 is maximized.

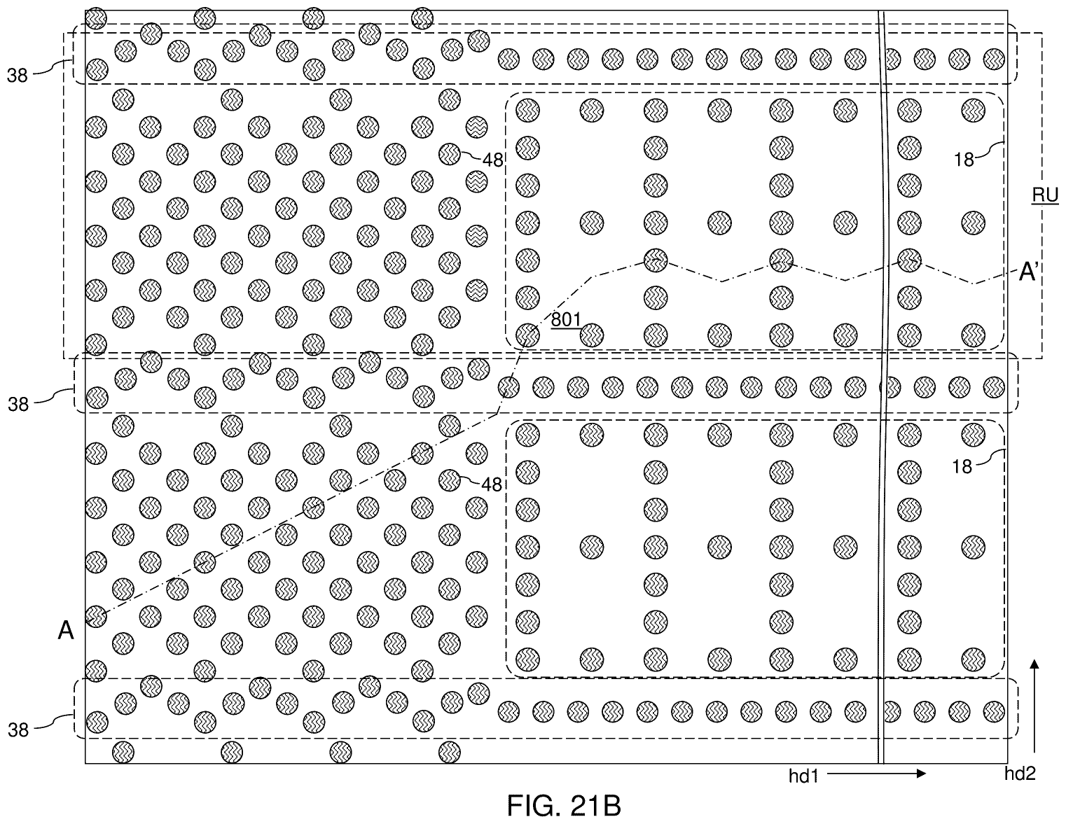

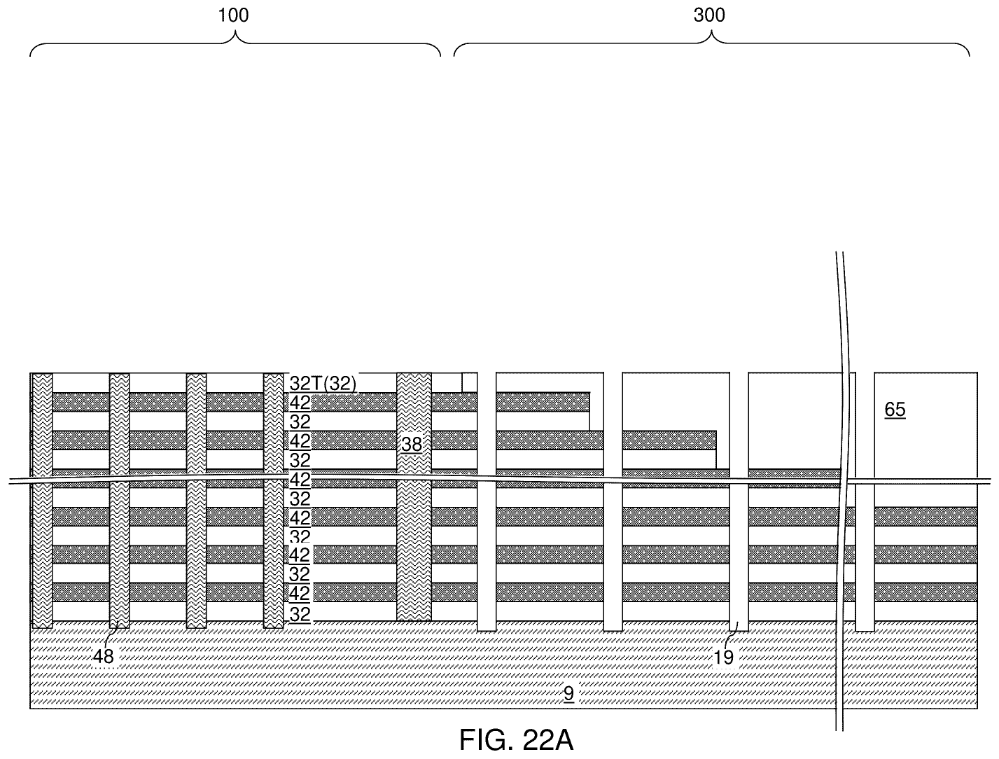

Referring to FIGS. 21A and 21B, the processing steps described with reference to FIG. 4 can be performed to form various sacrificial opening fill structures (48, 18, 38) through the vertically alternating sequence of the continuous insulating layers and the continuous sacrificial material layers, i.e., through the alternating stack (32, 42) of insulating layers 32 and sacrificial material layers 42. The sacrificial opening fill structures (48, 18, 38) may comprise sacrificial memory opening fill structures 48 that are formed in the memory openings 49, sacrificial support opening fill structures 18 that are formed in the support openings 19, and sacrificial isolation opening fill structures 38 that are formed in the isolation openings 39.

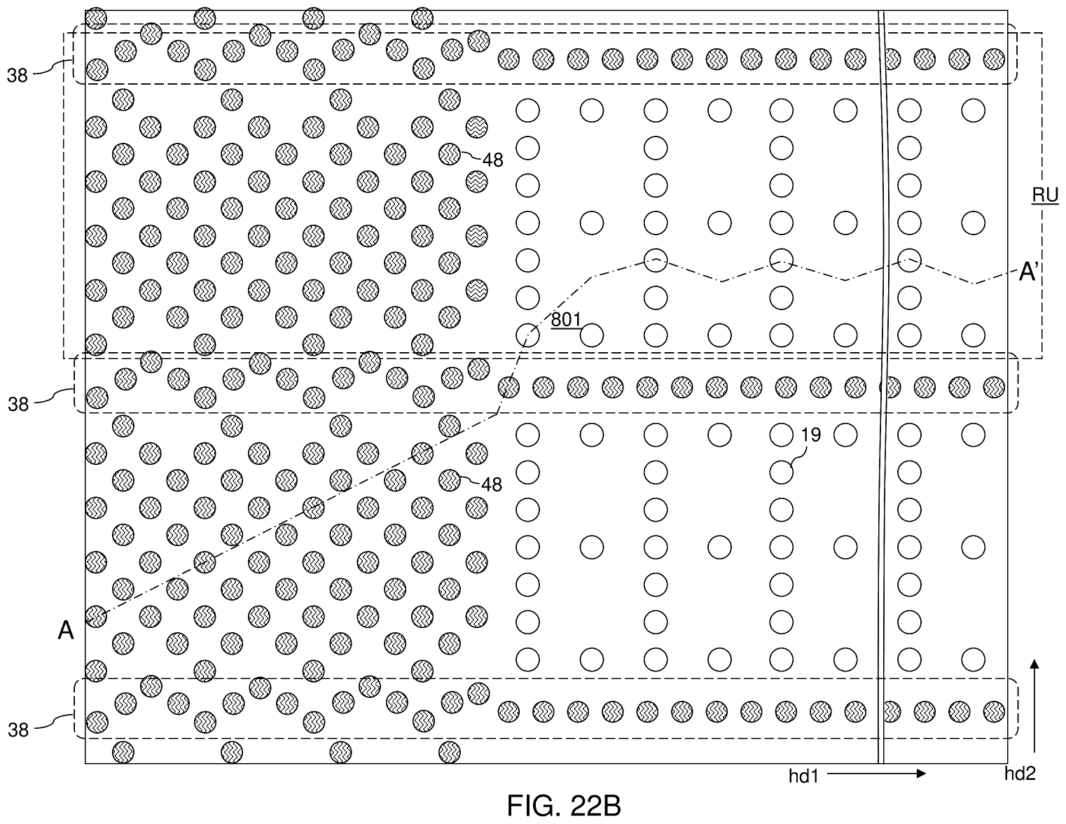

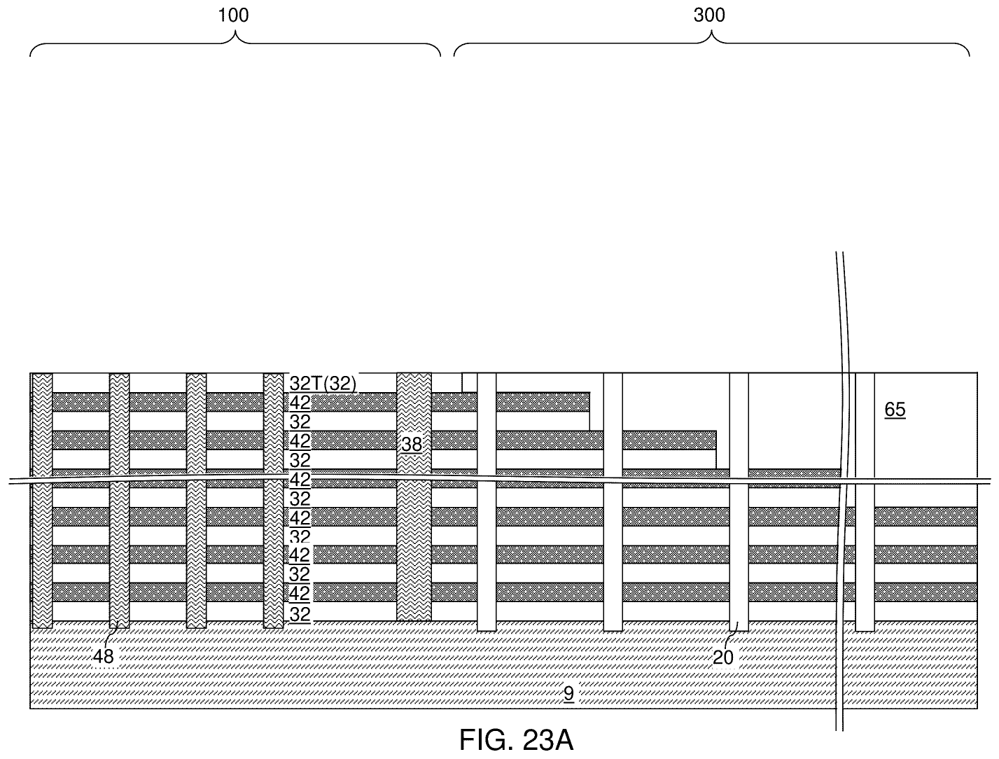

Referring to FIGS. 22A and 22B, a photoresist layer (not shown) can be applied over the first exemplary structure, and can be lithographically patterned to cover the sacrificial memory opening fill structures 48 and the sacrificial isolation opening fill structures 38 without covering the sacrificial support opening fill structures 18. The sacrificial support opening fill structures 18 are subsequently removed selectively to the materials of the insulating layers 32, the sacrificial material layers 42, and the carrier substrate 9 by ashing or selective etching. Voids are formed in the volumes of the support openings 19 from which the sacrificial support opening fill structures 18 are removed.

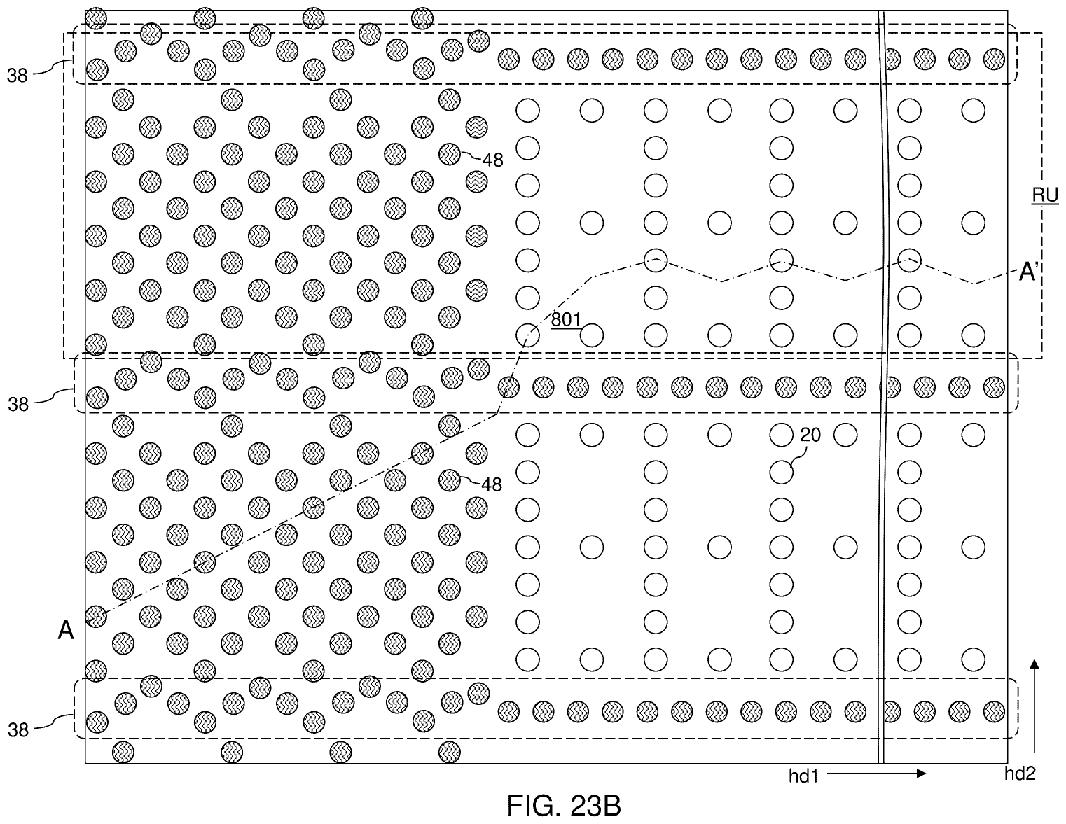

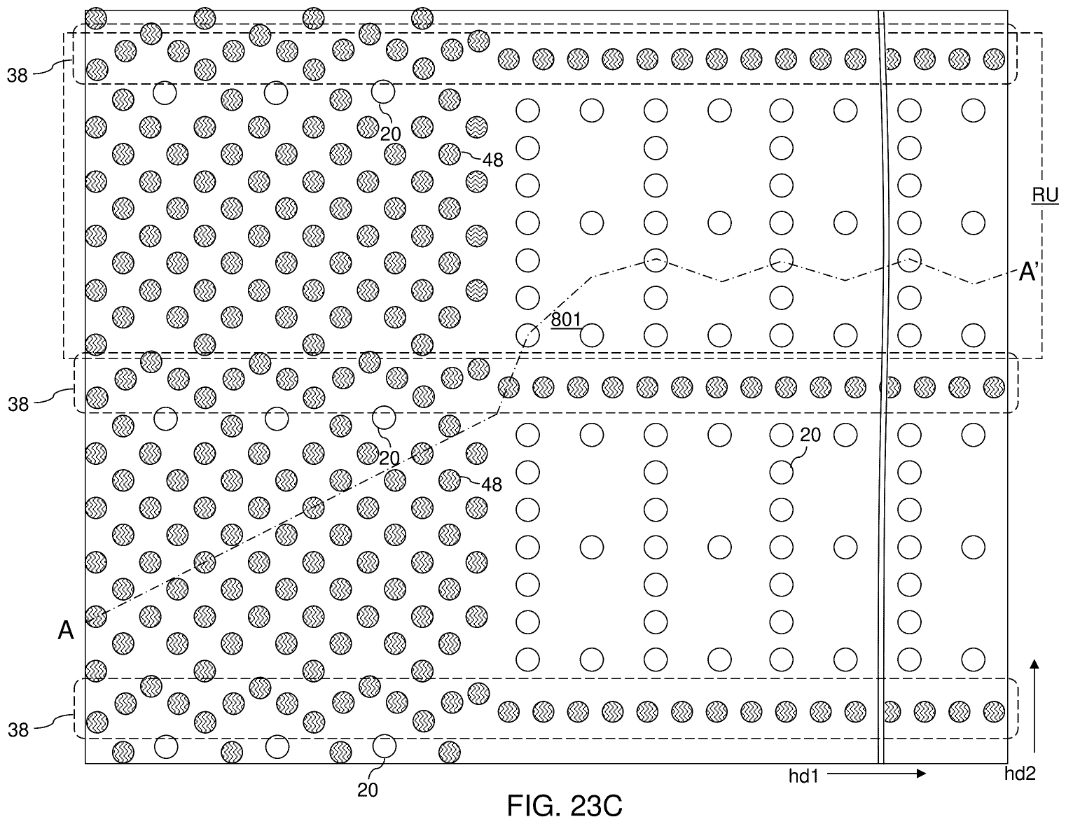

Referring to FIGS. 23A and 23B, a dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings 19.

Referring to FIGS. 23A and 23C, an alternative configuration of the second exemplary structure can be derived from the second exemplary structure of FIGS. 23A and 23B by forming additional support pillar structures 20 in the memory array region 100. Specifically, the additional support pillar structures 20 may be formed in areas in which the additional support pillar structures 20 can fit in between neighboring pairs of a sacrificial memory opening fill structure 48 and a sacrificial isolation opening fill structure 39.

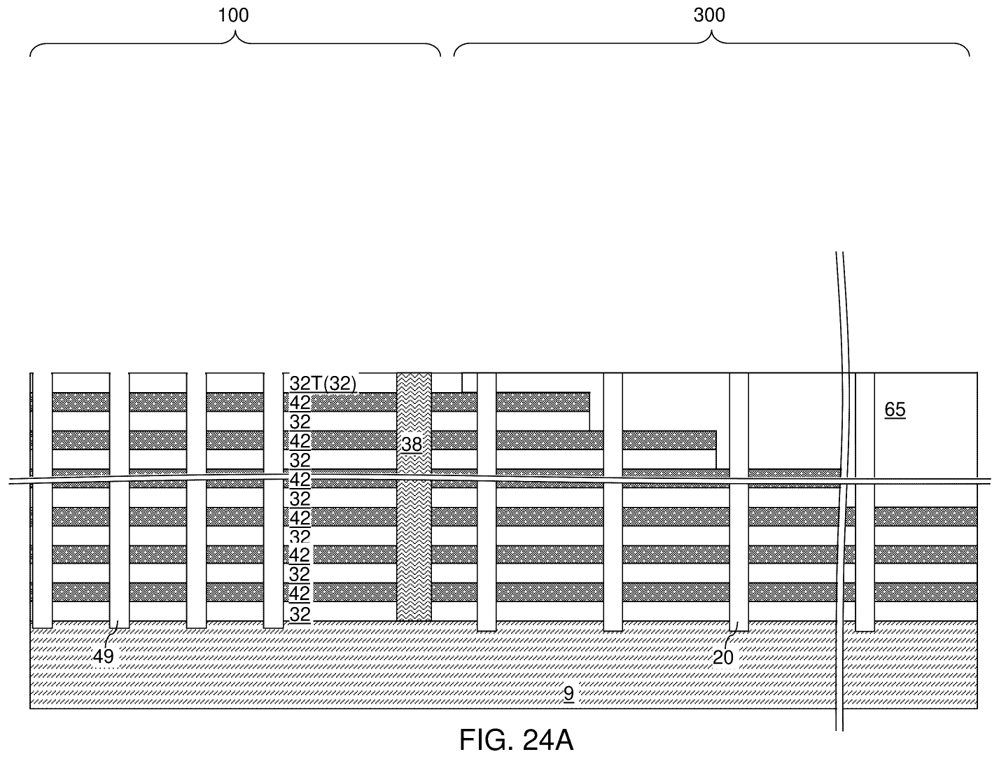

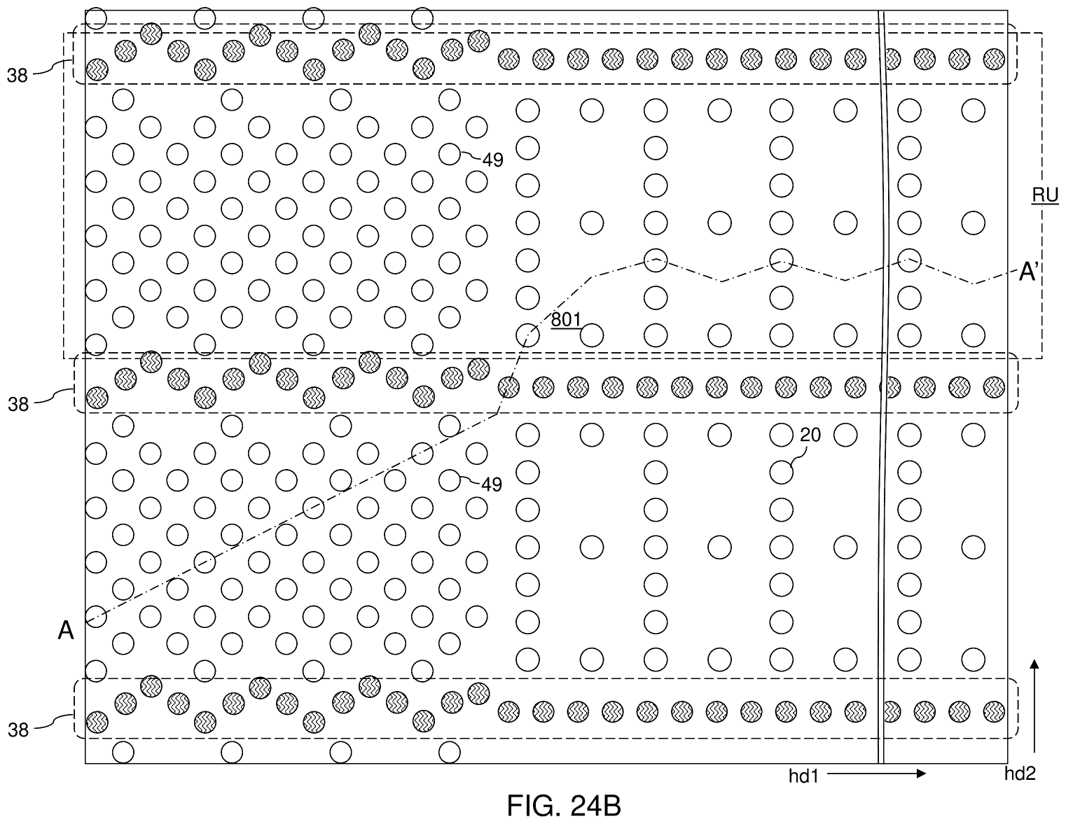

Referring to FIGS. 24A and 24B, the processing steps described with reference to FIG. 6 can be performed to remove the sacrificial memory opening fill structures 48 from the memory openings 49.

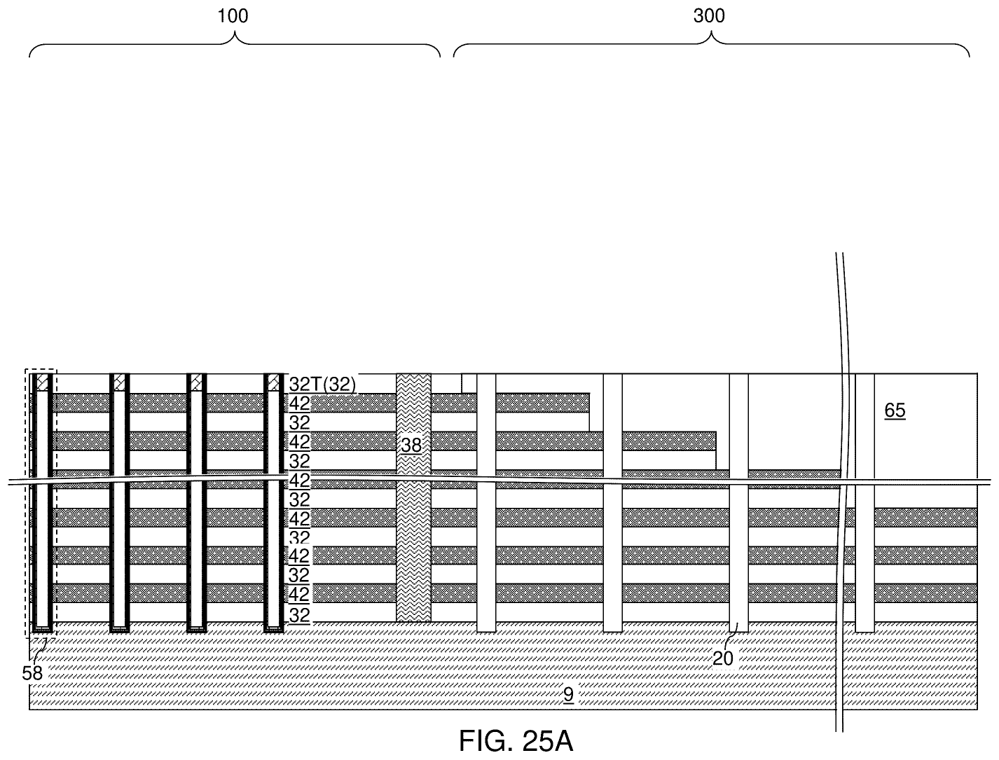

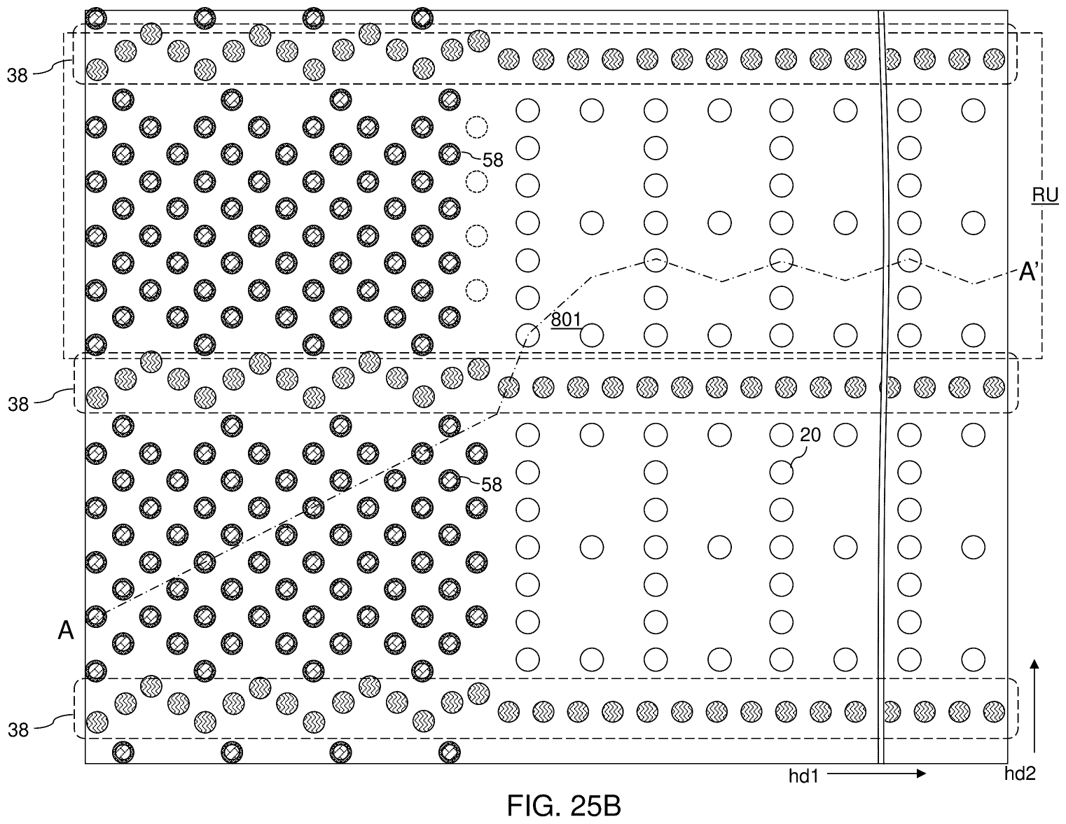

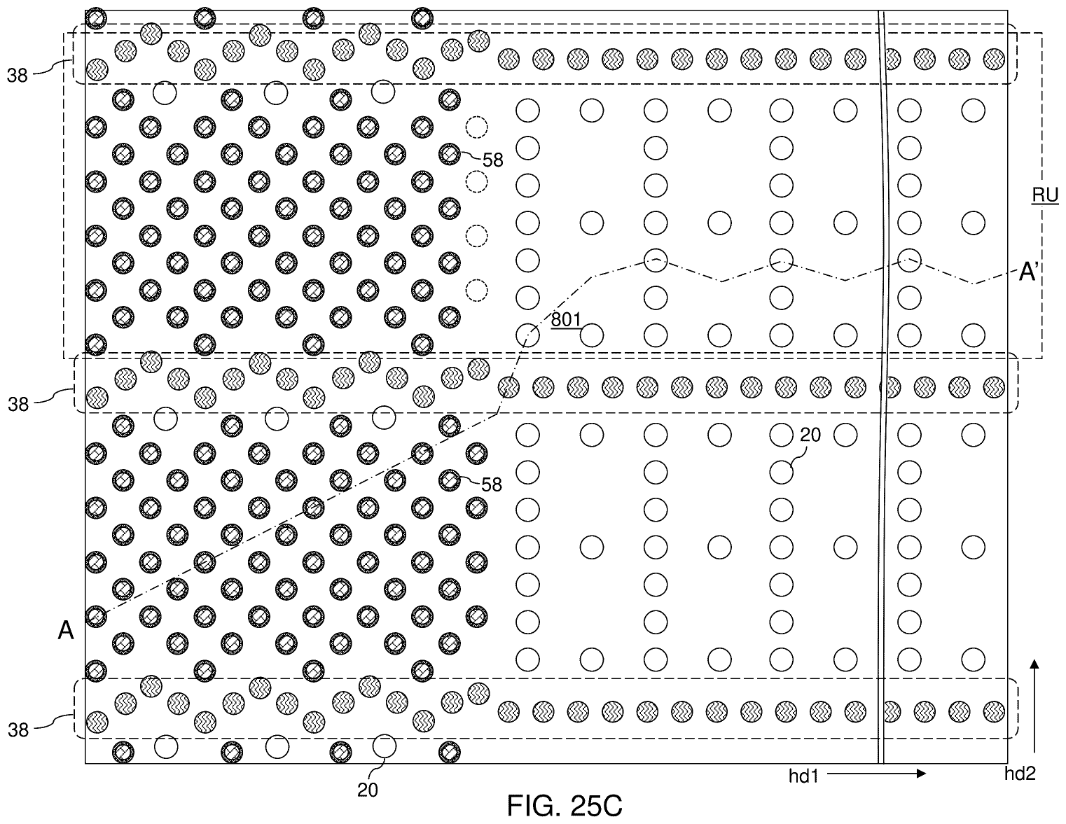

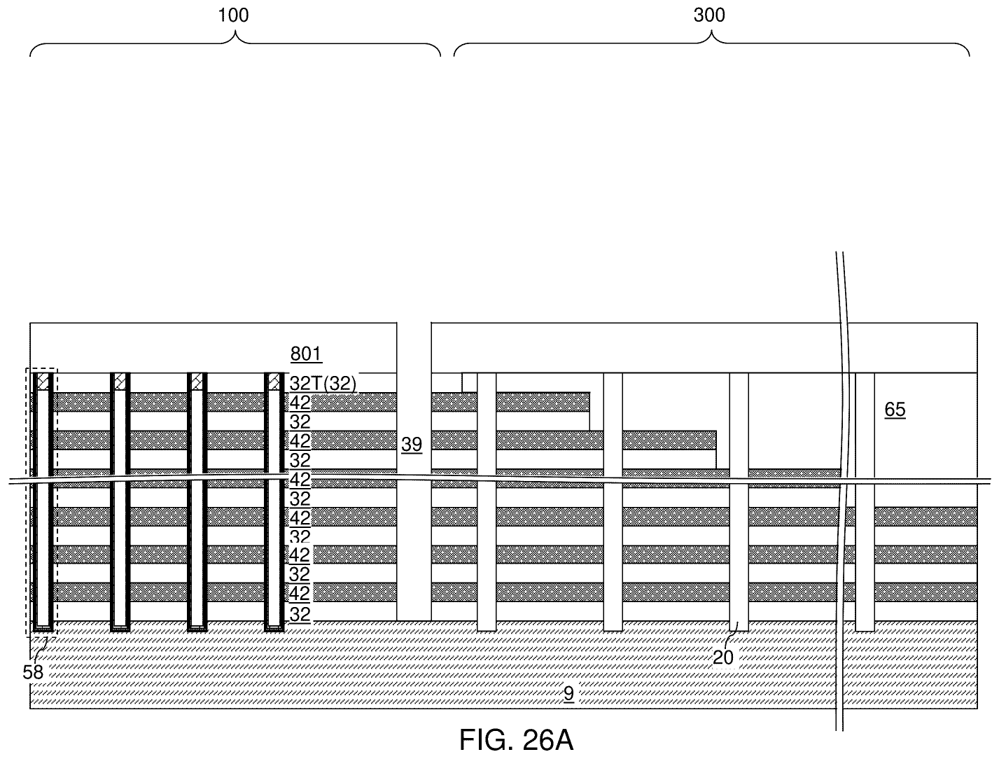

Referring to FIGS. 25A and 25B, the processing steps described with reference to FIGS. 7A-7F can be performed to form memory opening fill structures 58 in the memory openings.

Referring to FIGS. 25A and 25C, an alternative configuration of the second exemplary structure can be derived from the second exemplary structure illustrated in FIGS. 25A and 25B by providing additional support pillar structures 20 as described with reference to FIGS. 23A and 23C.

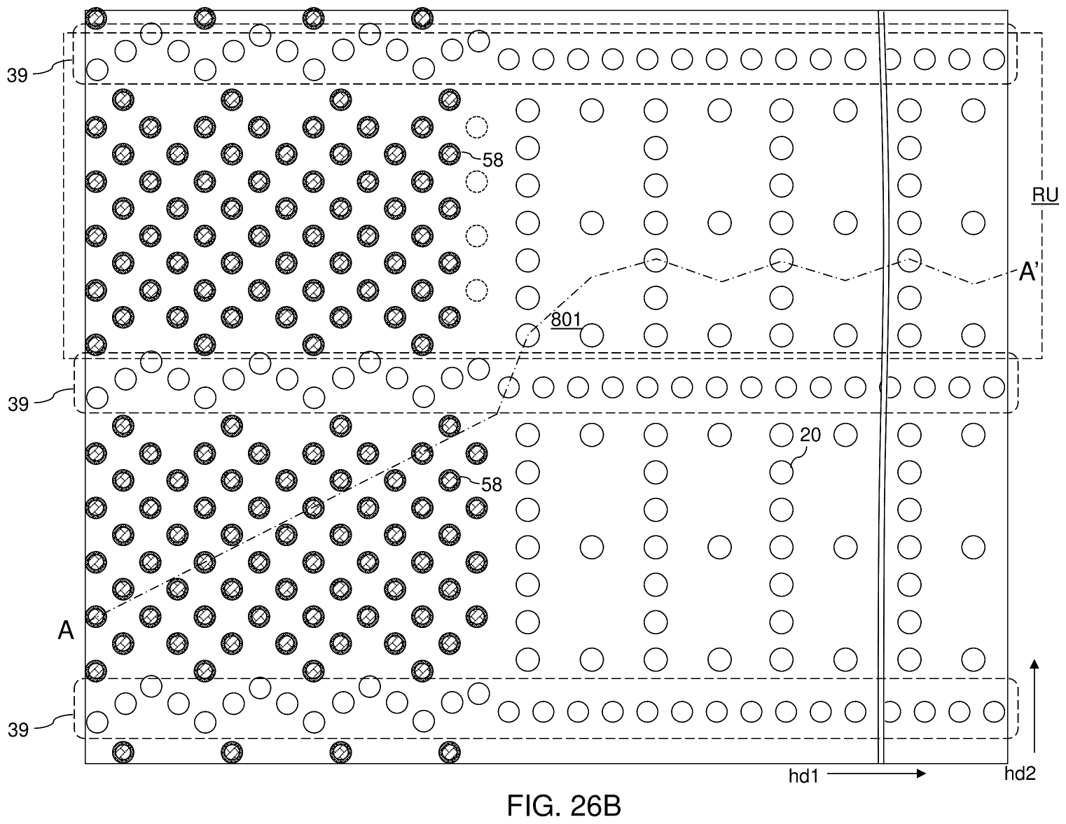

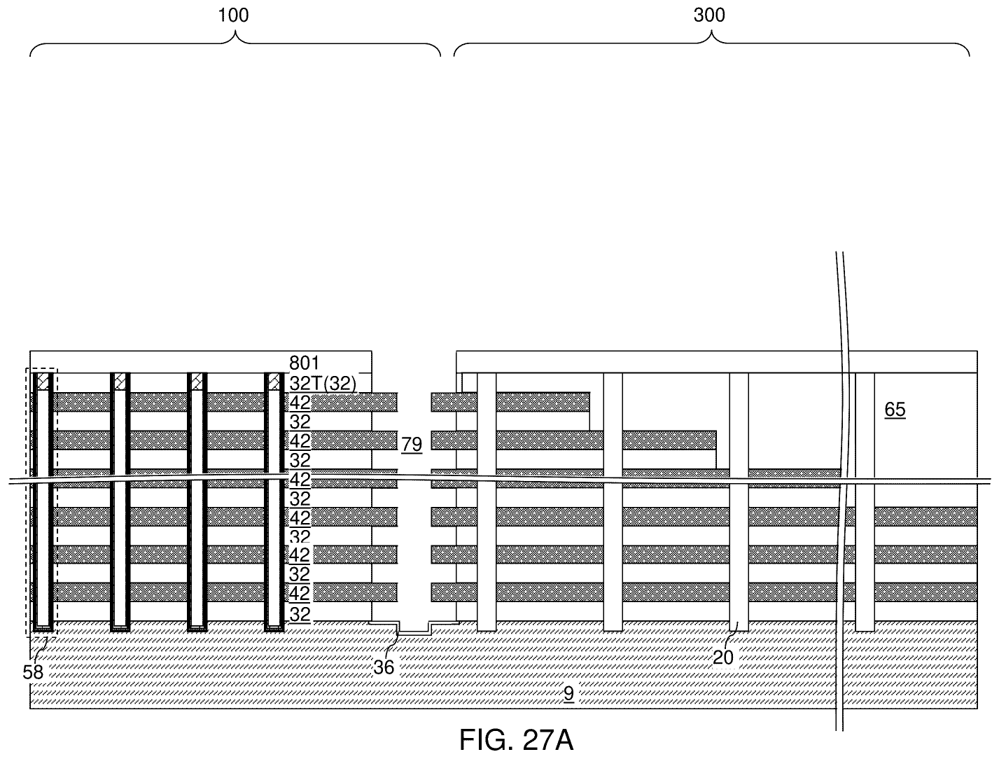

Referring to FIGS. 26A and 26B, a dielectric cover layer 801 can be deposited over the alternating stack (32, 42) and the retro-stepped dielectric material portion 65, and openings can be formed through the dielectric cover layer 801 above each of the sacrificial isolation opening fill structures 38. In one embodiment, the dielectric cover layer 801 comprises a silicate glass material, such as undoped silicate glass or a doped silicate glass. Subsequently, an isotropic etch process or an ashing process can be performed to remove the sacrificial isolation opening fill structures 38 selectively to the materials of the alternating stack (32, 42).

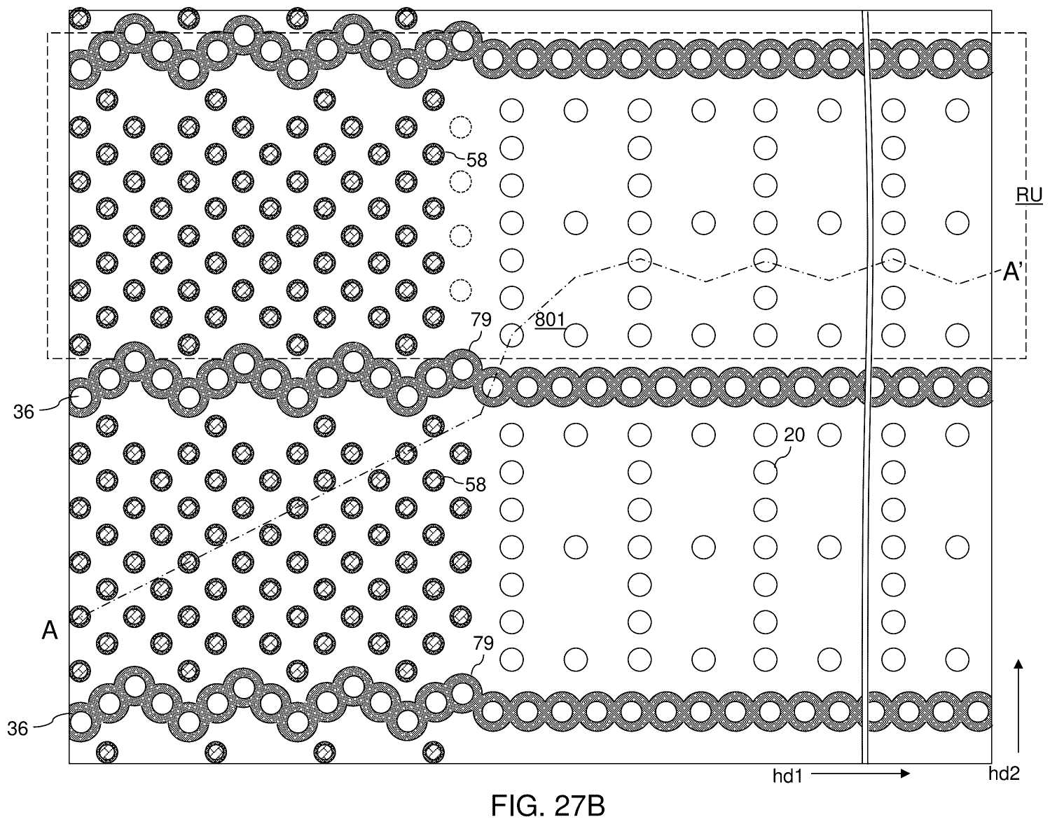

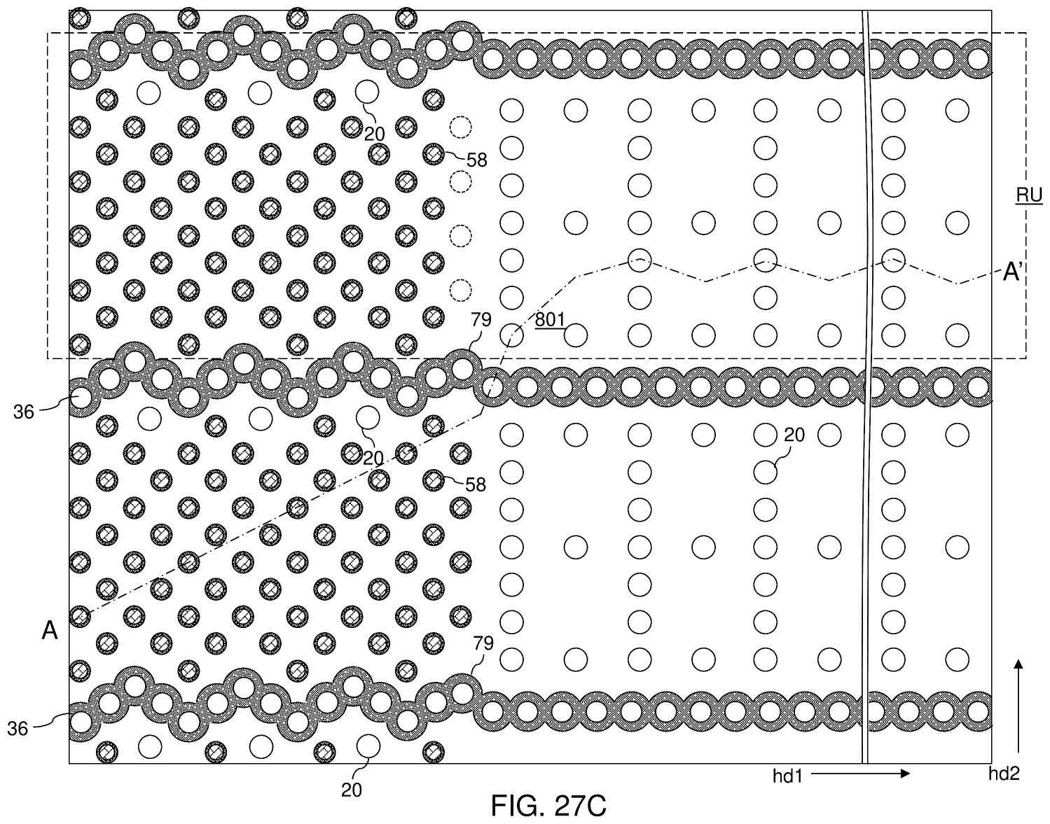

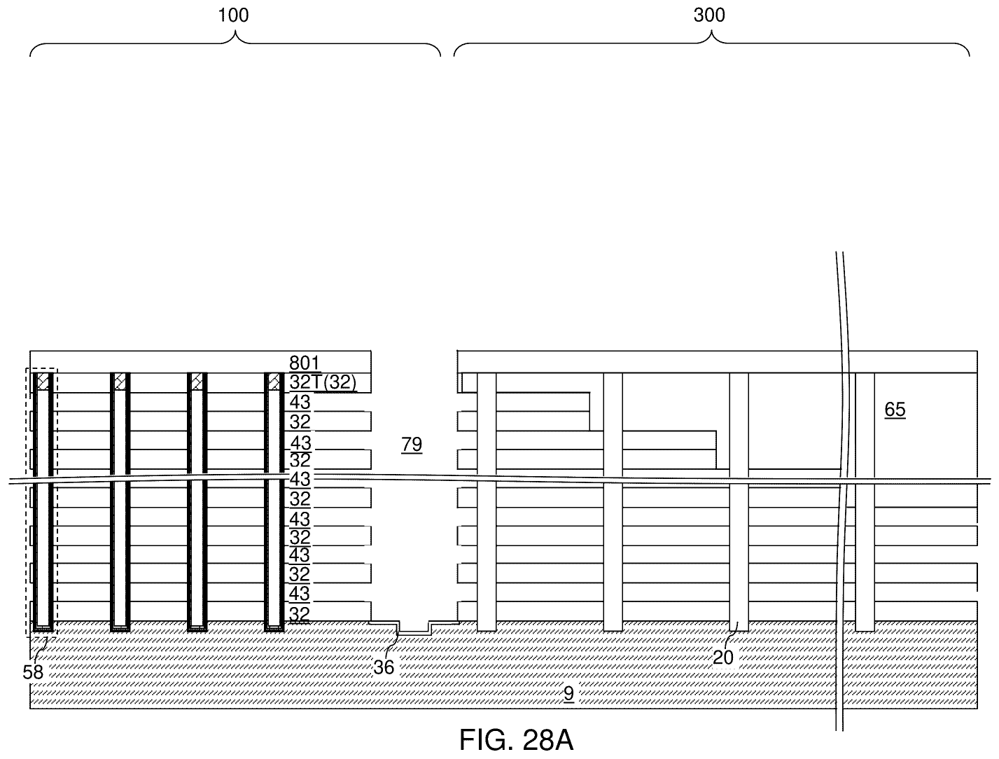

Referring to FIGS. 27A and 27B, a selective isotropic etch process can be performed to isotropically etch the material of the insulating layers 32 selectively to the material of the carrier substrate 9. For example, the selective isotropic etch process may comprise a wet etch process employing dilute hydrofluoric acid. The duration of the selective isotropic etch process may be selected such that the discrete isolation openings 39 are laterally expanded at each level of the insulating layers 32 and each neighboring set of isolation openings 39 is interconnected among one another at levels of the insulating layers 32 to form a continuous lateral isolation trench 79. In one embodiment, the dielectric cover layer 801 may be collaterally isotropically recessed during the selective isotropic etch process. In one embodiment, the isotropic etch process may be selective to the material of the sacrificial material layers 42.

Referring to FIGS. 27A and 27C, an alternative configuration of the second exemplary structure can be derived from the second exemplary structure illustrated in FIGS. 25A and 25B by providing additional support pillar structures 20 as described with reference to FIGS. 23A and 23C.

Referring collectively to FIGS. 27A-27C, the isolation openings 39 can be laterally expanded so that each set of isolation openings 39 located around a boundary between a respective neighboring pair of repetition units RU is merged into a respective lateral isolation trench 79. Each continuous laterally extended volume formed by merging a respective subset of the isolation openings 39 constitutes a respective one of the lateral isolation trenches 79.

The lateral isolation trenches 79 generally extend along the first horizontal direction (e.g., word line direction) hd1. Each cluster of memory opening fill structures 58 between a respective neighboring pair of lateral isolation trenches 79 is arranged in columns which extend along the second horizontal direction (e.g., bit line direction) hd2 that is perpendicular to the first horizontal direction hd1 between the respective neighboring pair of the lateral isolation trenches 79. The average number of the memory opening fill structures 58 per column between each neighboring pair of the lateral isolation trenches 79 is a non-integer number greater than zero.

The columns of memory opening fill structures 58 comprise a repeating set of a combination of I columns that contain P memory opening fill structures 58 and J columns that contain (P+1) or (P−1) memory opening fill structures 58. P is an integer that is equal to or greater than 2, I is a first integer that is equal to or greater than 2, and J is a second integer that is equal to or greater than 1. Each lateral isolation trench 79 has a modulating lateral width along the second horizontal direction hd2. The modulating lateral width of each lateral isolation trench 79 modulates as a function of a coordinate along the first horizontal direction hd1. In one embodiment, the ratio of a maximum of the modulating lateral width to the minimum of the modulating lateral width may be in a range from 1.1 to 3. In one embodiment, each physically exposed surface segments of the insulating layers 32 around a lateral isolation trench 79 may be a vertically-straight and laterally concave surface segment of a respective one of the insulating layers 32.

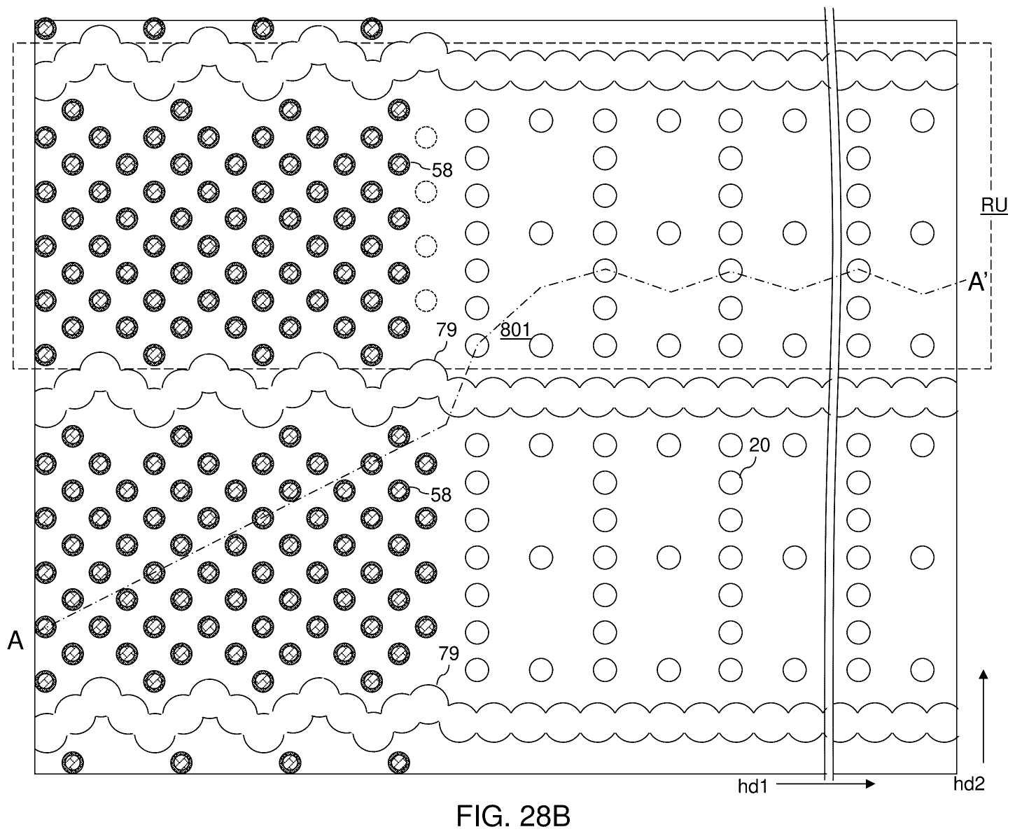

Referring to FIGS. 28A and 28B, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selectively to silicon oxide and silicon. The support pillar structures 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings 49 in which the memory stack structures 55 are formed are herein referred to as front side openings or front side cavities in contrast to the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

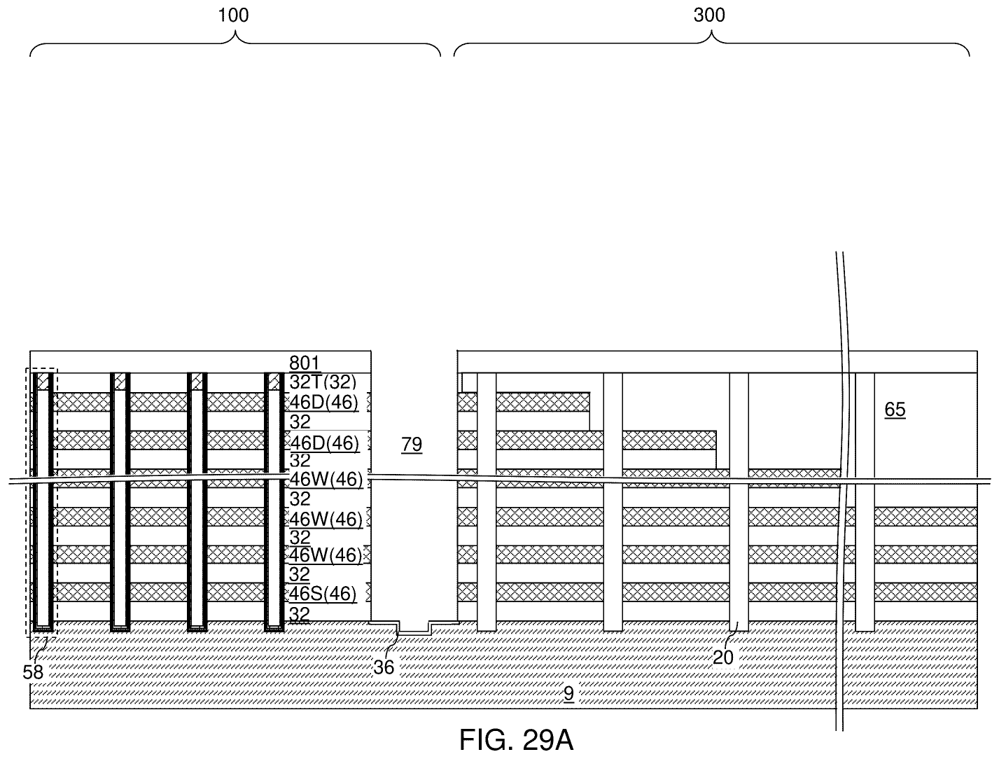

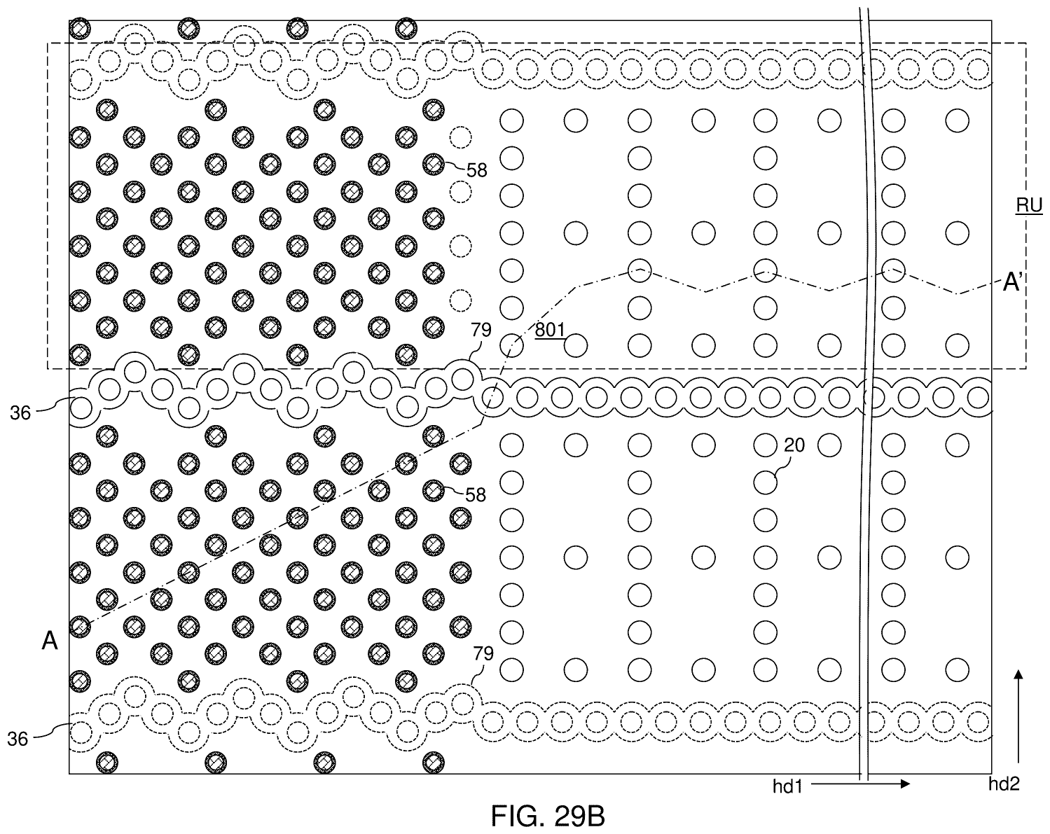

Referring to FIGS. 29A and 29B, the processing steps described with reference to FIG. 11 can be performed to form a plurality of electrically conductive layers 46 in the plurality of lateral recesses 43. A continuous metallic material layer can be formed on the sidewalls of each lateral isolation trench 79 and over the contact-level dielectric layer 80. The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43. At least one uppermost electrically conductive layer 46 may comprise a drain-side select layer 46DL. At least one bottommost electrically conductive layer 46 may comprise a source side select gate electrode 46S. The remaining electrically conductive layers 46 may comprise word lines 46W. Each word line 46W functions as a common control gate electrode for the plurality of vertical NAND strings (e.g., memory opening fill structures 58).

Memory strings are provided in and around the memory opening fill structures 58. Specifically, each memory string is provided in and around each memory opening fill structure 58. A “memory string” refers to a set of memory cells that are electrically connected in a series connection. In the second exemplary structure, each memory string comprises a memory stack structure 55 including a respective vertical semiconductor channel 60 and a respective memory film 50, which includes a respective vertical stack of memory elements. Each memory string further comprises proximal portions of the electrically conductive layers 46, which function as control gate electrodes of the NAND memory string.

Typically, in a NAND memory device, memory cells are organized as a set of pages, and each page includes a respective set of memory blocks. The set of all memory strings (e.g., memory opening fill structures 58 and associated select gate electrodes and word lines/control gate electrodes) between a neighboring pair of lateral isolation trenches 79 constitutes a memory block.

In summary, remaining portions of the continuous sacrificial material layers are replaced with electrically conductive layers 46 employing the lateral isolation trenches 79 as conduits for an etchant and a reactant. An alternating stack (32, 46) of insulating layers 32 and electrically conductive layers 46 is formed between each neighboring pair of the lateral isolation trenches 79. Each alternating stack (32, 46) of insulating layers 32 and electrically conductive layers 46 extends laterally along the first horizontal direction hd1. Memory opening fill structures 58 vertically extend through the alternating stack (32, 46). Each of the memory opening fill structures 58 comprises a vertical stack of memory elements (e.g., portions of the memory film 50 located at the levels of the word lines 46W) and a vertical semiconductor channel 60. The memory opening fill structures 58 are arranged in columns which extend along a second horizontal direction hd2 perpendicular to the first horizontal direction hd1. The average number of the memory opening fill structures 58 per column that extend through each alternating stack (32, 46) is a non-integer number greater than zero.

The electrically conductive layers 46 within each alternating stack (32, 46) comprise word lines 46W and drain-side select gate electrodes 46D overlying the word lines 46W. In one embodiment, each of the word lines 46W laterally extends along the first horizontal direction hd1 that is perpendicular to the second horizontal direction hd2 from a first lateral isolation trench 79 to a second lateral isolation trench 79. In one embodiment, each lateral isolation trench 79 comprises a pair of laterally-undulating lengthwise sidewalls that generally extend along the first horizontal direction hd1 and having a respective lateral undulation along the second horizontal direction hd2.

In one embodiment, each alternating stack (32, 46) comprises a first lengthwise sidewall including multiple vertically-straight and laterally-concave surface segments that are adjoined to each other by straight vertically-extending edges. The columns of memory opening fill structures 58 though each alternating stack (32, 46) comprise a repeating set of a combination of I columns that contain P memory opening fill structures 58 and J columns that contain (P+1) or (P−1) memory opening fill structures 58, wherein P is an integer that is equal to or greater than 2, I is a first integer that is equal to or greater than 2, and J is a second integer that is equal to or greater than 1.

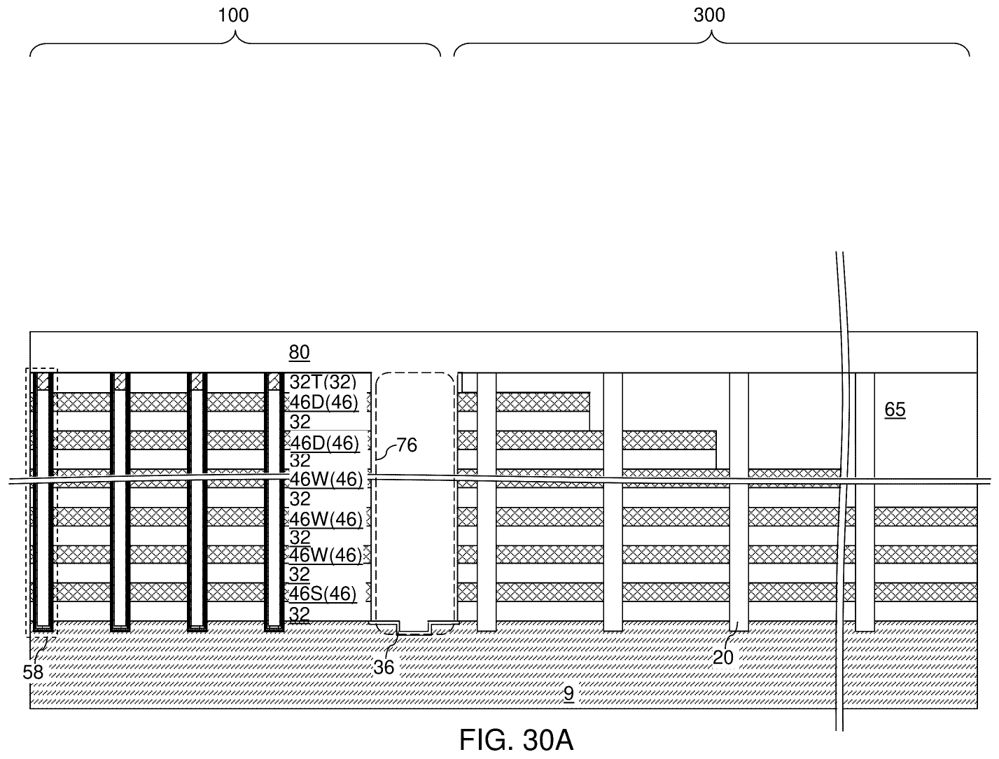

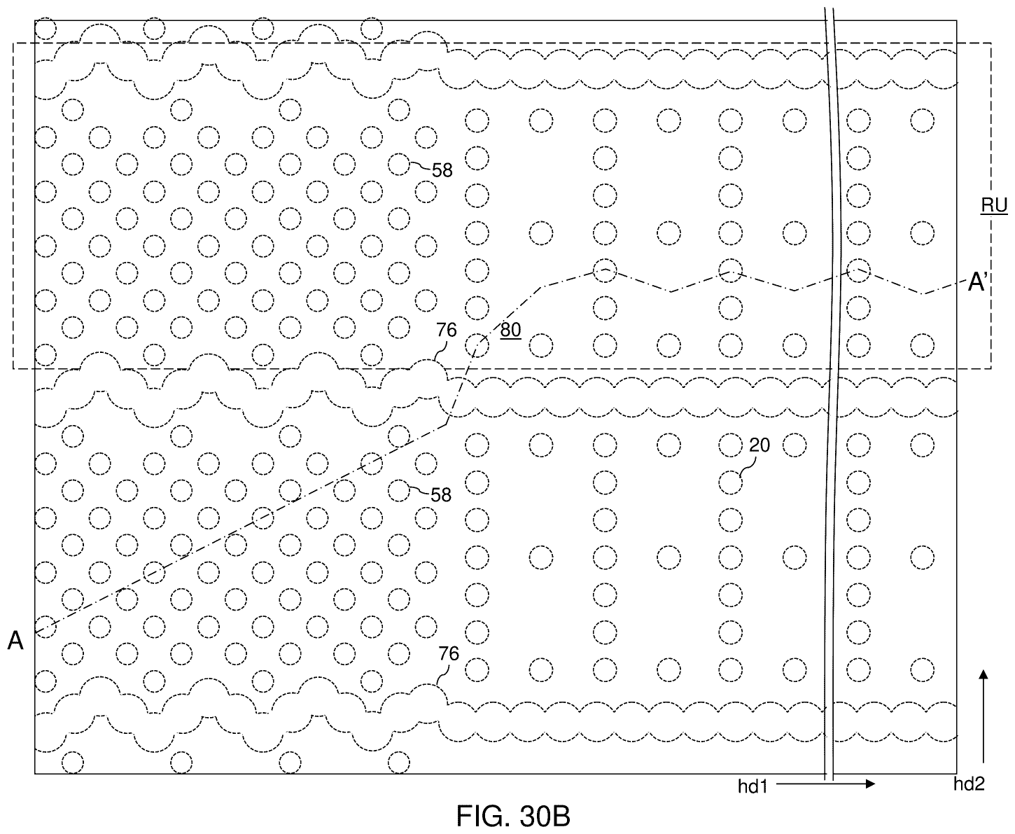

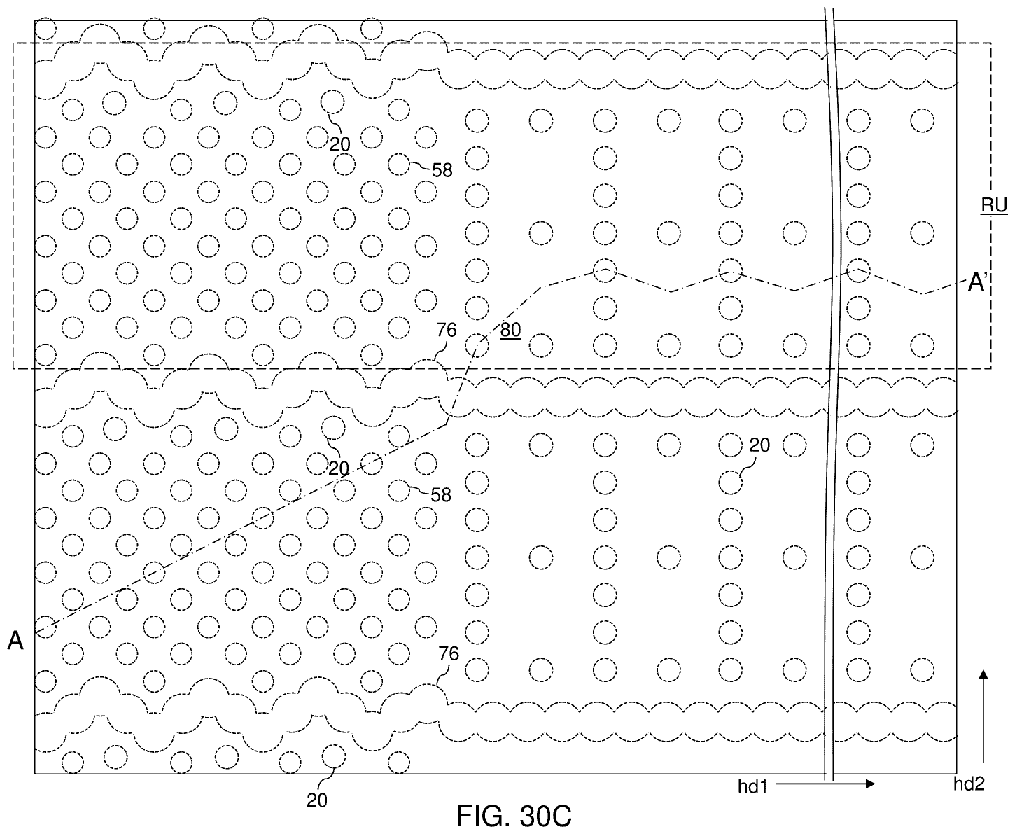

Referring to FIGS. 30A and 30B, a dielectric fill material, such as silicon oxide, may be deposited in the lateral isolation trenches 79 and over the remaining portions of the dielectric cover layer 801. Each portion of the dielectric fill material filling a respective lateral isolation trench 79 comprises a lateral isolation trench fill structure 76. The combination of the remaining portions of the dielectric cover layer 801 and a horizontally-extending portion of the dielectric fill material constitutes a contact-level dielectric layer 80.

Referring to FIGS. 30A and 30C, an alternative configuration of the second exemplary structure can be derived from the second exemplary structure illustrated in FIGS. 30A and 30B by providing additional support pillar structures 20 as described with reference to FIGS. 23A and 23C.

Referring collectively to FIGS. 30A-30C, each lateral isolation trench 79 is filled with a respective lateral isolation trench fill structure 76 having a modulated (i.e., varying) lateral width along the second horizontal direction hd2. The ratio of the maximum of the modulated lateral width to the minimum of the modulated lateral width may be in a range from 1.1 to 3.

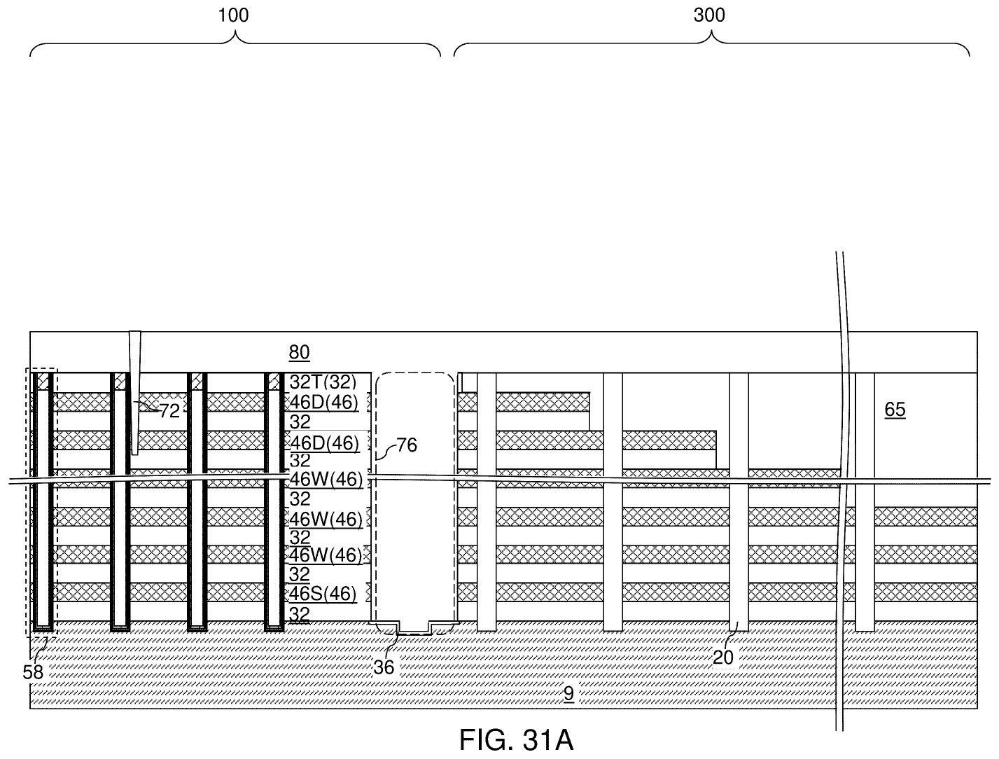

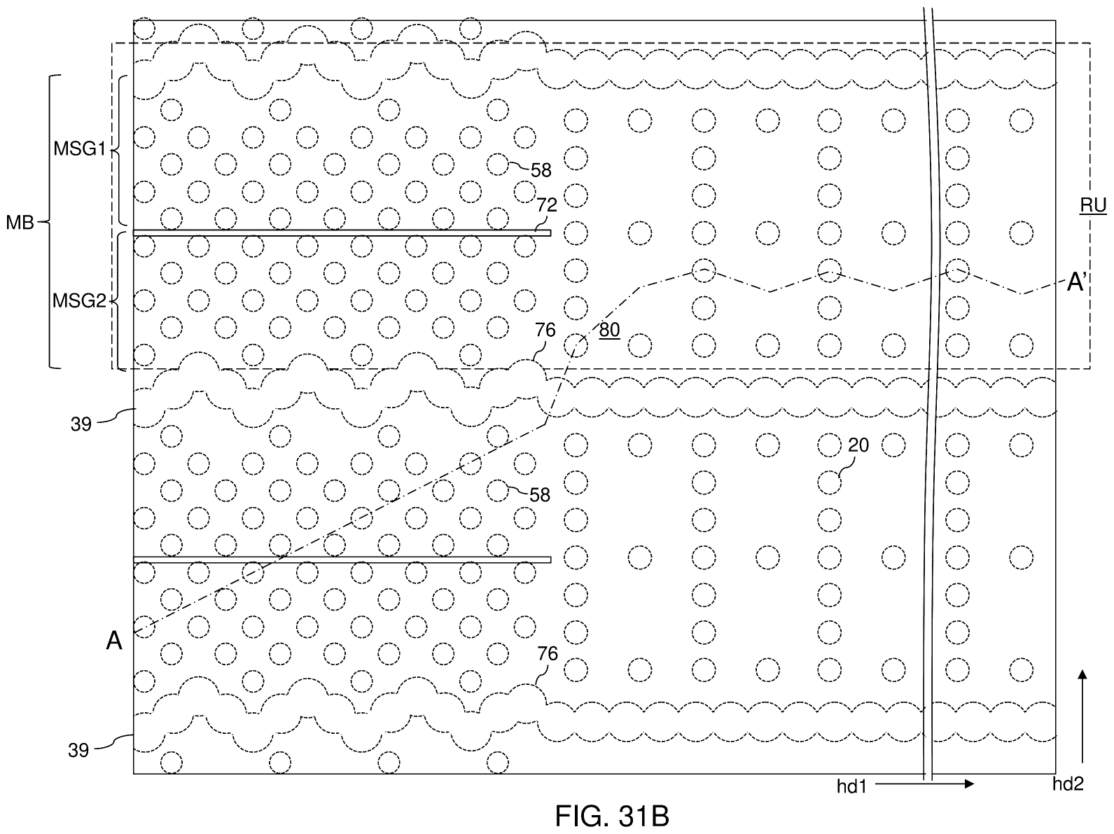

Referring to FIGS. 31A and 31B, the processing steps described with reference to FIGS. 12A-12G may be performed with a change in the lithographic pattern for forming the drain-select-level dielectric isolation structures 72. Thus, each memory block is divided into multiple memory string groups (“MSG”) through formation of drain-select-level dielectric isolation structures 72. Each set of memory strings located between a neighboring pair of drain-select-level isolation structures 72 constitutes a memory string group. Since the drain-select-level isolation structures 72 divide the drain-side select gate electrodes 46D (i.e., uppermost electrically conductive layers 46) but not the underlying word lines 46W or source side select gate electrodes 46S, the area of each drain-side select gate electrode 46D encompasses a respective memory string group.

In summary, drain-select-level lateral isolation structures 72 may be formed in an upper portion of each of the alternating stacks (32, 46). In one embodiment, each drain-select-level dielectric isolation structure 72 comprises a pair of straight lengthwise sidewalls that laterally extends along the first horizontal direction hd1.

In one embodiment, each of the word lines 46W laterally extends along first horizontal direction hd1 that is perpendicular to the second horizontal direction hd2, and has a width along the second horizontal direction hd2 that extends from a first lateral isolation trench 79 to a second lateral isolation trench 79. A first subset of the drain-side select gate electrodes 46D laterally extends along the first horizontal direction hd1 and has a width along the second horizontal direction hd2 from the first lateral isolation trench 79 to a drain-select-level dielectric isolation structure 72. A second subset of the drain-side select gate electrodes 46D laterally extends along the first horizontal direction hd1, and has a width from the drain-select-level dielectric isolation structure 72 to the second lateral isolation trench 79 along the second horizontal direction hd2.

In one embodiment, a first subset of the memory opening fill structures 58 and a first subset of the drain-side select gate electrodes 46D are located on one side of the drain-select-level dielectric isolation structure 72 in a plan view, and a second subset of the memory opening fill structures 58 and a second subset of the drain-side select gate electrodes 46D are located on another side of the drain-select-level dielectric isolation structure 72 in the plan view. In one embodiment, the drain-select-level dielectric isolation structure 72 comprises a pair of lengthwise sidewalls that laterally extend along the first horizontal direction hd1, and an entirety of each of the lengthwise sidewalls is parallel to the first horizontal direction hd1.

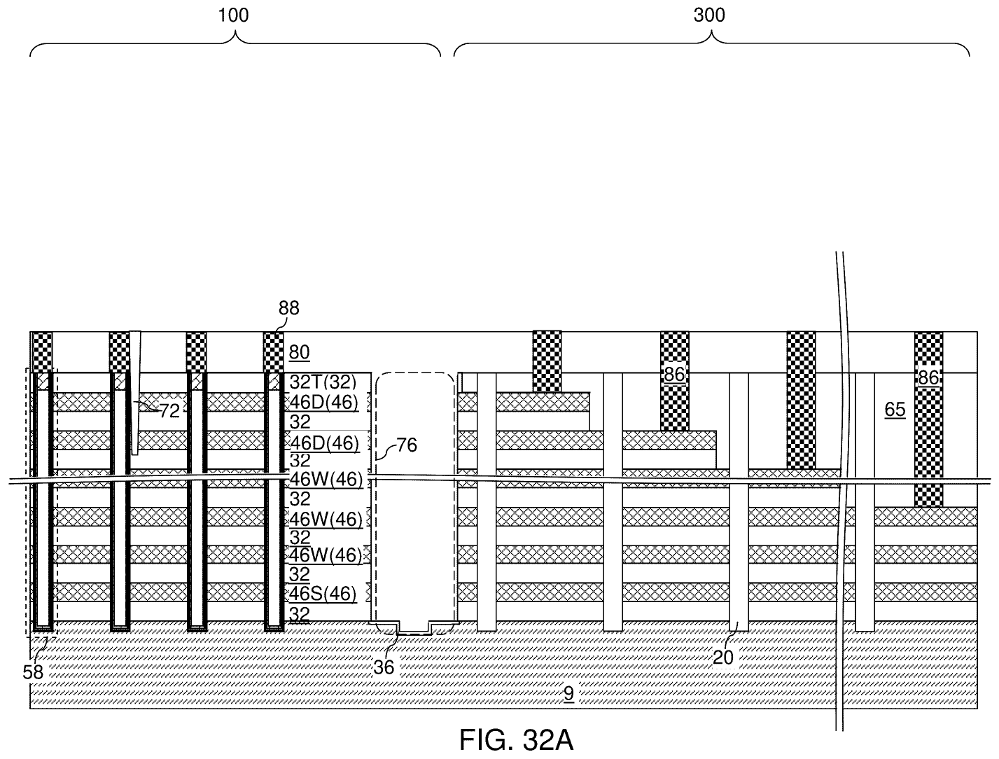

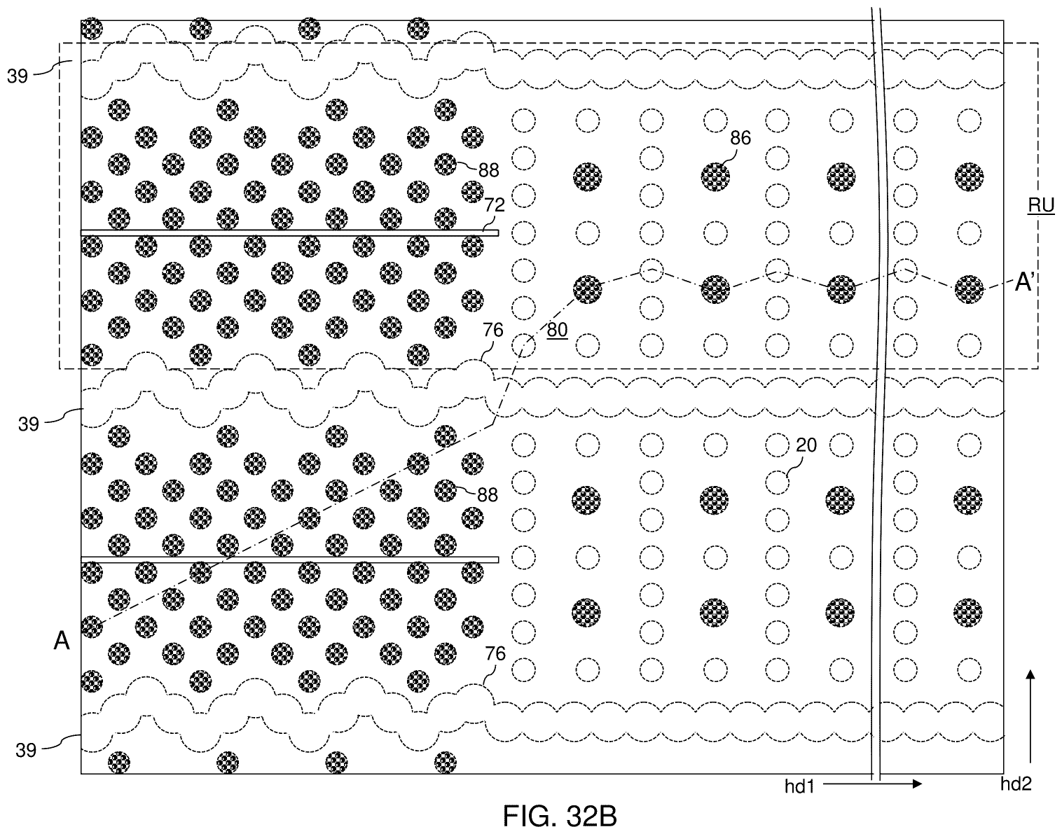

Referring to FIGS. 32A and 32B, the processing steps described with reference to FIGS. 13A-13G may be performed to form layer contact via structures 86 and drain contact via structures 88.

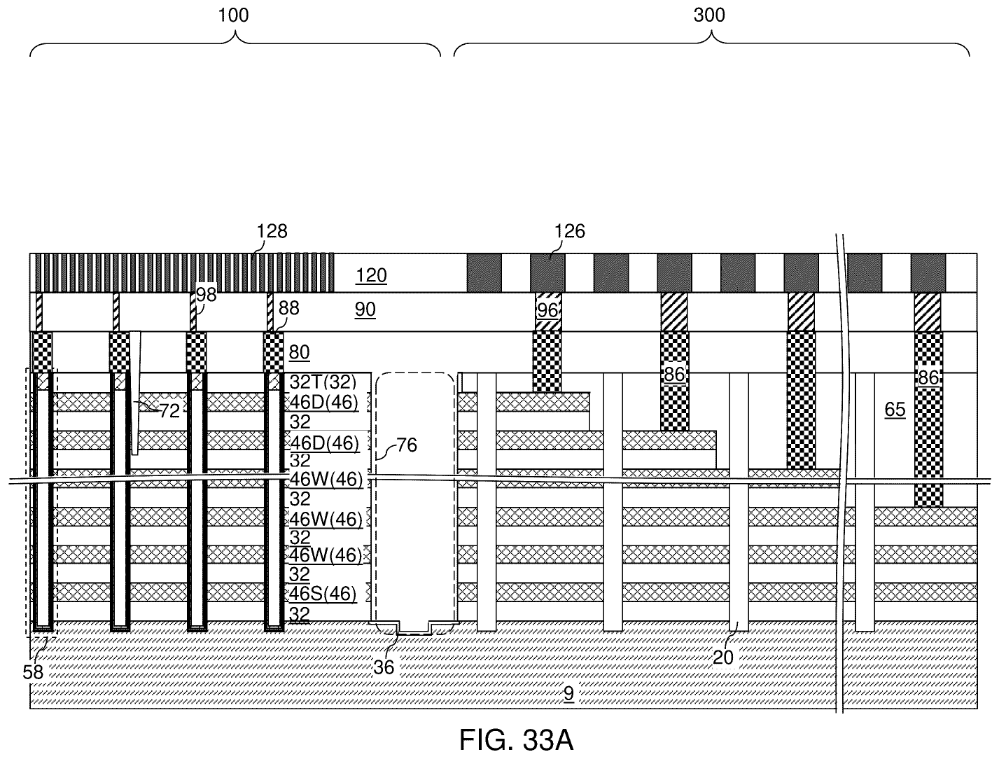

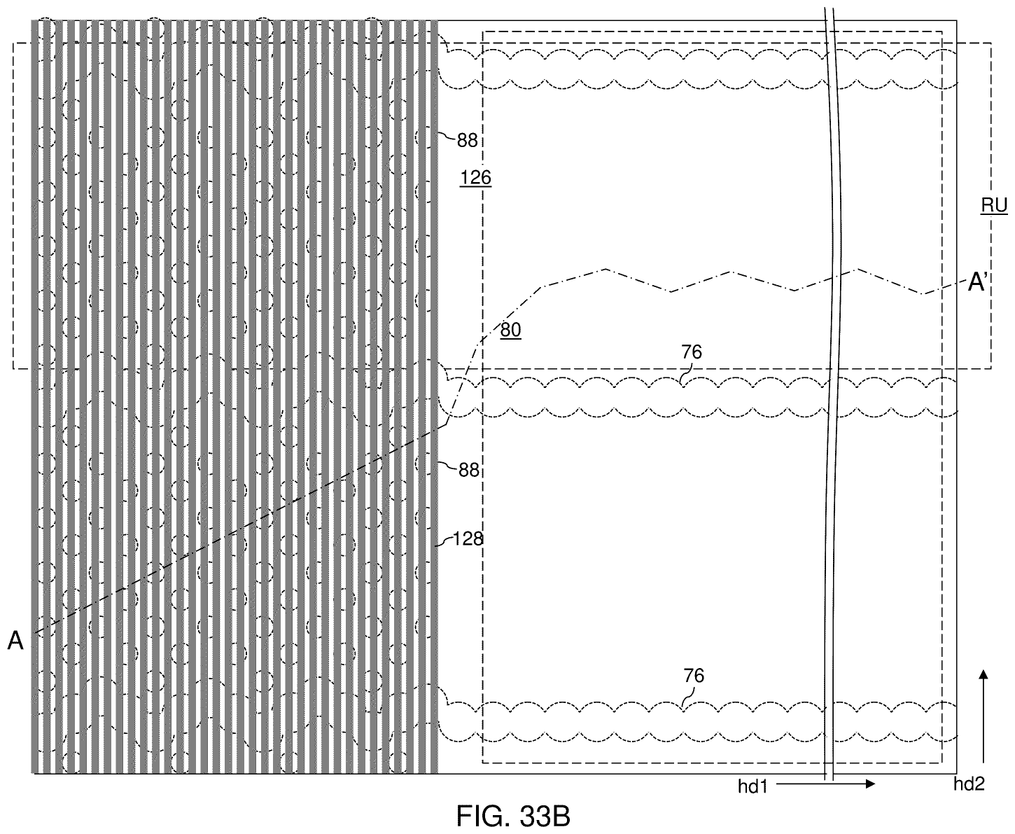

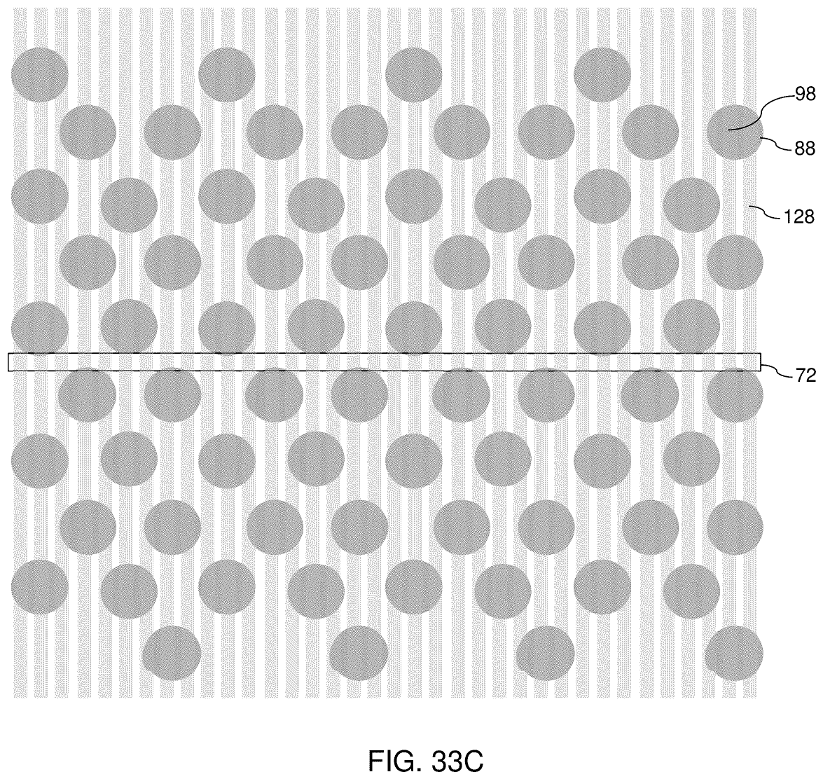

Referring to FIGS. 33A-33C, the processing steps described with reference to FIGS. 14A-14G may be performed to form connection via structures 98 and bit lines 128.

Multiple bit lines 128 extend along a second horizontal direction (e.g., bit line direction) hd2 that is perpendicular to the first horizontal direction (e.g., word line direction) hd1. The multiple bit lines 128 are electrically connected to a respective subset of drain regions 63 in the memory opening fill structures 58. In one embodiment, the ratio of the pitch of the columns of the memory opening fill structures 58 along the first horizontal direction hd1 to the pitch of the bit lines 128 along the first horizontal direction hd1 is a non-integer greater than 3. In the illustrated example, the ratio is 9/4.

In one embodiment, each of the memory opening fill structures 58 is electrically connected to a respective bit line 128; and support pillar structures 20 that are not electrically connected to any bit line 128 vertically extend through the first subset of the drain-side select gate electrodes 46D. In one embodiment, the support pillar structures 20 have an areal overlap with a subset of the bit lines 128 in a plan view.

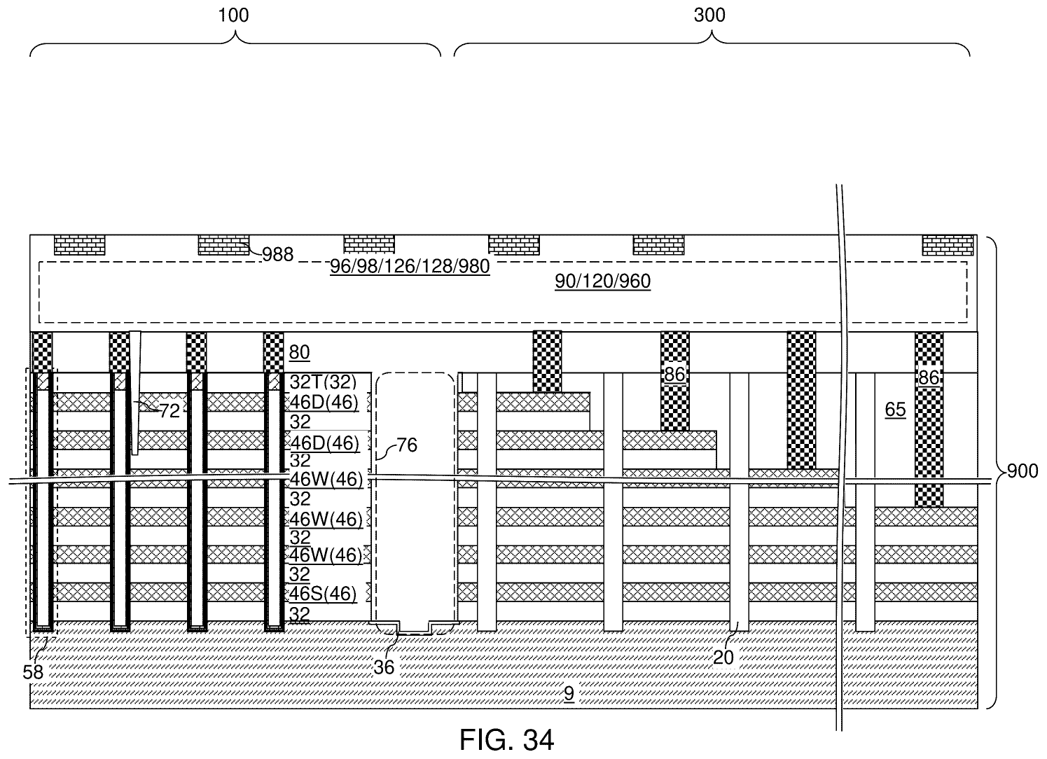

Referring to FIG. 34, the processing steps described with reference to FIG. 15 can be performed to form a memory die 900.

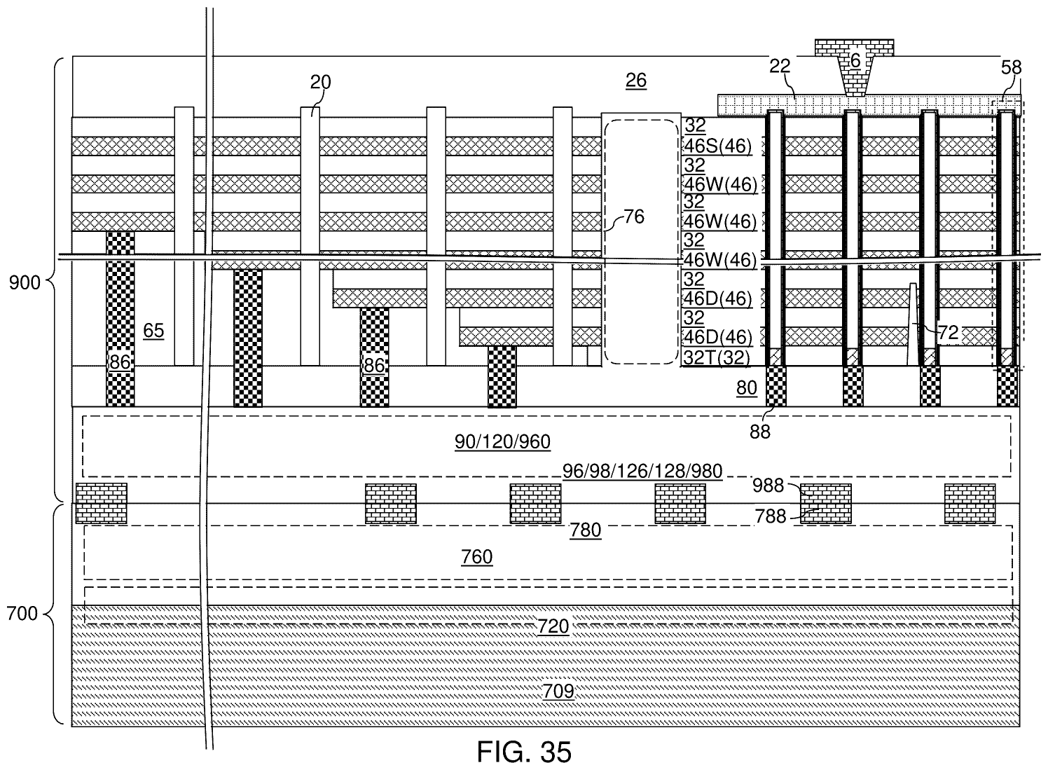

Referring to FIG. 35, the processing steps described with reference to FIGS. 16-19B may be performed to remove the carrier substrate 9 and to form source contact structures 6.

Referring collectively to FIGS. 20A-35 and according to various embodiments of the present disclosure, a memory device is provided, which comprises: an alternating stack (32, 46) of insulating layers 32 and electrically conductive layers 46 which extends along a first horizontal direction hd1; and memory opening fill structures 58 vertically extending through the alternating stack (32, 46), wherein each of the memory opening fill structures 58 comprises a vertical stack of memory elements (e.g., portions of the memory film 50) and a vertical semiconductor channel 60. The memory opening fill structures 58 are arranged in columns which extend along a second horizontal direction hd2 perpendicular to the first horizontal direction hd1; and an average number of the memory opening fill structures 58 per column is a non-integer number greater than zero.

In one embodiment, the electrically conductive layers 46 comprise word lines 46W and drain-side select gate electrodes 46D overlying the word lines 46W; and an average width of each of the drain-side select gate electrodes 46D along the second horizontal direction hd2 is less than one half of an average width of each of the word lines 46W along the second horizontal direction hd2. In one embodiment, each of the word lines 46W has a width along the second horizontal direction hd2 from a first lateral isolation trench 79 to a second lateral isolation trench 79; and a first subset of the drain-side select gate electrodes 46D has a width along the second horizontal direction hd2 from the first lateral isolation trench 79 to a drain-select-level dielectric isolation structure 72.

In one embodiment, the first lateral isolation trench 79 comprises a pair of laterally-undulating lengthwise sidewalls that generally extend along the first horizontal direction hd1 and having a respective lateral undulation along the second horizontal direction hd2. In one embodiment, the first lateral isolation trench 79 is filled with a first lateral isolation trench fill structure 76 having a modulated lateral width along the second horizontal direction hd2, wherein a ratio of a maximum of the modulated lateral width to a minimum of the modulated lateral width is in a range from 1.1 to 3.

In one embodiment, the alternating stack (32, 46) comprises a first lengthwise sidewall including multiple vertically-straight and laterally-concave surface segments that are adjoined among one another by straight vertically-extending edges. In one embodiment, the drain-select-level dielectric isolation structure 72 comprises a pair of straight lengthwise sidewalls that laterally extends along the first horizontal direction hd1.

In one embodiment, a second subset of the drain-side select gate electrodes 46D laterally extends along the second horizontal direction hd2 from the drain-select-level dielectric isolation structure 72 to the second lateral isolation trench 79. In one embodiment, the columns comprise a repeating set of a combination of I columns that contain P memory opening fill structures 58 and J columns that contain (P+1) or (P−1) memory opening fill structures 58, wherein P is an integer that is equal to or greater than 2, I is a first integer that is equal to or greater than 2, and J is a second integer that is equal to or greater than 1.

In one embodiment, multiple bit lines 128 extend along the second horizontal direction hd2, wherein the multiple bit lines 128 are electrically connected to a respective subset of drain regions in the memory opening fill structures 58. In one embodiment, a ratio of a pitch of the columns of the memory opening fill structures 58 along the first horizontal direction hd1 to a pitch of the bit lines 128 along the first horizontal direction hd1 is a non-integer greater than 3.

In one embodiment, the drain-select-level dielectric isolation structure 72 laterally extends along the first horizontal direction hd1. A first subset of the memory opening fill structures 58 and a first subset of the drain-side select gate electrodes 46D are located on one side of the drain-select-level dielectric isolation structure 72 in a plan view; and a second subset of the memory opening fill structures 58 and a second subset of the drain-side select gate electrodes 46D are located on another side of the drain-select-level dielectric isolation structure 72 in the plan view. In one embodiment, the drain-select-level dielectric isolation structure 72 comprises a pair of lengthwise sidewalls that laterally extend along the first horizontal direction hd1; and an entirety of each of the lengthwise sidewalls is parallel to the first horizontal direction hd1.

In one embodiment, each of the memory opening fill structures 58 is electrically connected to a respective bit line 128; and support pillar structures 20 that are not electrically connected to any bit line 128 vertically extend through the first subset of the drain-side select gate electrodes 46D. In one embodiment, the support pillar structures 20 have an areal overlap with a subset of the bit lines 128 in a plan view.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers which extends along a first horizontal direction; and
memory opening fill structures vertically extending through the alternating stack, wherein each of the memory opening fill structures comprises a vertical stack of memory elements and a vertical semiconductor channel, wherein:
the memory opening fill structures are arranged in columns which extend along a second horizontal direction perpendicular to the first horizontal direction; and
an average number of the memory opening fill structures per column is a non-integer number greater than zero.

2. The memory device of claim 1, wherein:
the electrically conductive layers comprise word lines and drain-side select gate electrodes overlying the word lines; and
an average width of each of the drain-side select gate electrodes along the second horizontal direction is less than one half of an average width of each of the word lines along the second horizontal direction.

3. The memory device of claim 2, wherein:
each of the word lines has a width along the second horizontal direction from a first lateral isolation trench to a second lateral isolation trench; and
a first subset of the drain-side select gate electrodes has a width along the second horizontal direction from the first lateral isolation trench to a drain-select-level dielectric isolation structure.

4. The memory device of claim 3, wherein the first lateral isolation trench comprises a pair of laterally-undulating lengthwise sidewalls that generally extend along the first horizontal direction and having a respective lateral undulation along the second horizontal direction.

5. The memory device of claim 3, wherein the first lateral isolation trench is filled with a first lateral isolation trench fill structure having a modulated lateral width along the second horizontal direction, wherein a ratio of a maximum of the modulated lateral width to a minimum of the modulated lateral width is in a range from 1.1 to 3.

6. The memory device of claim 3, wherein the alternating stack comprises a first lengthwise sidewall including multiple vertically-straight and laterally-concave surface segments that are adjoined among one another by straight vertically-extending edges.

7. The memory device of claim 3, wherein the drain-select-level dielectric isolation structure comprises a pair of straight lengthwise sidewalls that laterally extends along the first horizontal direction.

8. The memory device of claim 3, wherein a second subset of the drain-side select gate electrodes laterally extends along the second horizontal direction from the drain-select-level dielectric isolation structure to the second lateral isolation trench.

9. The memory device of claim 1, wherein the columns comprise a repeating set of a combination of I columns that contain P memory opening fill structures and J columns that contain (P+1) or (P−1) memory opening fill structures, wherein P is an integer that is equal to or greater than 2, I is a first integer that is equal to or greater than 2, and J is a second integer that is equal to or greater than 1.

10. The memory device of claim 1, further comprising multiple bit lines which extend along the second horizontal direction, wherein the multiple bit lines are electrically connected to a respective subset of drain regions in the memory opening fill structures.

11. The memory device of claim 10, wherein a ratio of a pitch of the columns of the memory opening fill structures along the first horizontal direction to a pitch of the bit lines along the first horizontal direction is a non-integer greater than 3.

12. The memory device of claim 3, wherein:
the drain-select-level dielectric isolation structure laterally extends along the first horizontal direction;
a first subset of the memory opening fill structures and a first subset of the drain-side select gate electrodes are located on one side of the drain-select-level dielectric isolation structure in a plan view; and
a second subset of the memory opening fill structures and a second subset of the drain-side select gate electrodes are located on another side of the drain-select-level dielectric isolation structure in the plan view.

13. The memory device of claim 12, wherein:
the drain-select-level dielectric isolation structure comprises a pair of lengthwise sidewalls that laterally extend along the first horizontal direction; and
an entirety of each of the lengthwise sidewalls is parallel to the first horizontal direction.

14. The memory device of claim 12, wherein:
each of the memory opening fill structures is electrically connected to a respective bit line; and
support pillar structures that are not electrically connected to any bit line vertically extend through the first subset of the drain-side select gate electrodes.

15. The memory device of claim 14, wherein the support pillar structures have an areal overlap with a subset of the bit lines in a plan view.

16. A method of forming a memory device, comprising:
forming a vertically alternating sequence of continuous insulating layers and continuous sacrificial material layers over a substrate;
forming memory openings and isolation openings through the alternating stack;
forming memory opening fill structures in the memory openings, wherein each of the memory opening fill structures comprises a respective vertical stack of memory elements and a vertical semiconductor channel;
forming lateral isolation trenches that generally extend along a first horizontal direction, wherein the memory opening fill structures are arranged in columns which extend along a second horizontal direction perpendicular to the first horizontal direction between each neighboring pair of the lateral isolation trenches, and wherein an average number of the memory opening fill structures per column between each neighboring pair of the lateral isolation trenches is a non-integer number greater than zero; and
replacing remaining portions of the continuous sacrificial material layers with electrically conductive layers through the lateral isolation trenches.

17. The method of claim 16, further comprising:
forming isolation openings through the vertically alternating sequence; and
laterally expanding the isolation openings to merge a respective subset of the isolation openings into respective one of the lateral isolation trenches.

18. The method of claim 16, wherein:
an alternating stack of insulating layers and electrically conductive layers is formed between each neighboring pair of the lateral isolation trenches; and
the method further comprises forming a drain-select-level lateral isolation structure in an upper portion of each of the alternating stacks.

19. The method of claim 16, wherein:
the columns comprise a repeating set of a combination of I columns that contain P memory opening fill structures and J columns that contain (P+1) or (P−1) memory opening fill structures; and
P is an integer that is equal to or greater than 2, I is a first integer that is equal to or greater than 2, and J is a second integer that is equal to or greater than 1.

20. The method of claim 16, further comprising forming multiple bit lines which extend along a second horizontal direction that is perpendicular to the first horizontal direction after formation of the electrically conductive layers, wherein the multiple bit lines are electrically connected to a respective subset of drain regions in the memory opening fill structures.
